(19) United States
(12) Patent Application Publication
(10) Pub. No.: US 2026/0320267 A1
(43) Pub. Date: Oct. 15, 2026

(54) SYSTEM AND METHOD FOR MICROMECHANICS SIMULATION

(71) Applicants: Mohamed Hamza, Tempe, AZ (US); Aditi Chattopadhyay, Chandler, AZ (US); Hyeonho Hwang, Scottsdale, AZ (US); Trae Nelson, Scottsdale, AZ (US)

(72) Inventors: Mohamed Hamza, Tempe, AZ (US); Aditi Chattopadhyay, Chandler, AZ (US); Hyeonho Hwang, Scottsdale, AZ (US); Trae Nelson, Scottsdale, AZ (US)

(73) Assignee: Arizona Board of Regents on behalf of Arizona State University, Scottsdale, AZ (US)

(21) Appl. No.: 19/644,576

(22) Filed: Apr. 10, 2026

Related U.S. Application Data
(60) Provisional application No. 63/787,348, filed on Apr. 11, 2025.

(51) Int. Cl. G06F 30/28; G06N 3/045; G06N 3/0464; G06N 3/0475; G06V 10/26; G06V 10/766; G06V 10/82; G06V 20/69

(52) U.S. Cl. CPC G06F 30/28; G06N 3/045; G06N 3/0464; G06N 3/0475; G06V 10/26; G06V 10/766; G06V 10/82; G06V 20/695

(57) ABSTRACT

A micromechanics simulation framework has the steps of collecting one or more images of at least one composite material, providing, to a first neural network, an input including the one or more images, segmenting one or more microstructures in the one or more images, quantifying one or more physical descriptors of one or more segmented microstructures, passing an output including the one or more segmented microstructures and one or more quantified physical descriptors to one of: a statistical-based module using descriptor-driven stochastic construction routines with periodic boundary conditions, or a second deep generative neural network, and generating one or more stochastic representative volume element (SRVE) ensembles based on the one or more segmented microstructures and one or more quantified physical descriptors. A micromechanics simulation system is also disclosed for computing the homogenized elastic properties and the time-dependent response of composites in high-temperature environments.

### CROSS-REFERENCE TO RELATED APPLICATIONS

This application claims priority to U.S. Provisional Application No. 63/787,348 filed on Apr. 11, 2025, incorporated herein by reference in its entirety.

### STATEMENT REGARDING FEDERALLY SPONSORED RESEARCH OR DEVELOPMENT

This invention was made with government support under Grant Number DEFE0031759 awarded by the Department of Energy, under Award Number W911NF-22-2-0237 awarded by the Army Research Office, and under Award Number FA9550-23-1-0460 awarded by the Air Force Office of Scientific Research. The government has certain rights in the invention.

### BACKGROUND OF THE INVENTION

Accurate prediction of the response of heterogeneous composite materials, including damage and degradation of the constituents, requires careful consideration of microstructural characteristics, inherent defect morphology, and scale-specific architectural variability. The traditional approach is to perform several experimental characterization studies and use statistical tools to determine the critical features and their associated variability to generate representative volume elements (RVEs) that are suitable for multiscale homogenization and prediction of effective properties. In ceramic matrix composites (CMCs), in addition to microstructural variability, the presence of defects in the as-received material creates complexities in defining a suitable RVE. While there has been a significant effort in developing multiscale models to predict the CMC constitutive response [Borkowski & Chattopadhyay, Compos Struct, 2015; Skinner & Chattopadhyay, Compos Struct, 2021; Liu et al., J Aerosp Eng, 2011], a vast majority of them assume idealized RVEs. Significantly missing from the literature is a robust methodology for constructing 3D stochastic representative volume elements (SRVEs) that capture the scale-dependent material and architectural variability and the resulting pre-damage state to accurately predict the time and temperature dependent material response. It is important to note that when a single SRVE is used to study a deformation mechanism of interest, it is assumed that the SRVE follows the ergodic hypothesis [Bostanabad et al., Prog Mater Sci, 2018]. However, to satisfy this condition, periodic boundary condition (PBC) may be applied to ensure that the SRVE can represent the response of larger systems, thereby enhancing the computational efficiency while analyzing complex nonlinear and time-dependent problems.

Traditional approaches in constructing SRVEs can lead to considerable cost and reduce model fidelity by overlooking potentially critical information. Standard statistical algorithms are successful in generating idealized SRVEs (defect-free). However, techniques such as two-point statistics cannot fully reconstruct highly inhomogeneous microstructures (non-eigen microstructures) where the state space is allowed to be continuous [Fullwood et al., Acta Mater, 2008]; the degeneracy can lead to unrealistic results [Kench & Cooper, Nat Mach Intell, 2021; Gommes et al., Phys Rev E Stat Nonlin Soft Matter Phys, 2012]. Cang et al. showed that statistical microstructure reconstruction methods are not universally applicable, especially for microstructures with complex morphology, where matching SRVEs in the representation space does not necessarily indicate a better match in the microstructure space [Cang et al., Comput Mater Sci, 2018]. Additionally, computer vision (CV)-based techniques require manual tuning of image masks, resulting in inconsistent microstructure quantification with a limited number of microstructure features [Khafagy et al., J Compos Mater, 2021]. Cutting-edge methods such as deep learning (DL) algorithms are beneficial in generating high-fidelity SRVEs that explicitly mimic the microstructure characteristics in a multiscale setting. With the vast improvement in computer vision and DL, an automated algorithm can be developed to extract essential microstructure features from several optical and electron micrographs of the material, with minimal human intervention. The DL-based algorithms span the taxonomy of microstructure analyses, including segmentation of constituents, matrix/fiber interface, defects, and quantifying the microstructure variability in terms of probability distributions.

Various DL algorithms have been developed to automatically segment microstructures based on convolutional neural networks (CNNs) [Badran et al., J Mater Sci, 2020]. Holm et al. [Holm et al., Metall Mater Trans A Phys Metall Mater Sci, 2020] developed a deep regression model to compute the grain size of polycrystalline micrographs and perform feature extraction of ultrahigh carbon steel. While Jung et al. [Jung et al., NPJ Comput Mater, 2021] developed a deep super-resolution neural network (NN) to increase the fidelity of a given micrograph. The traditional microstructure analysis capabilities can be further enhanced by implementing generative models which perform tailorable microstructure reconstruction with enforced geometrical constraints. The use of generative adversarial networks (GANs) for microstructure reconstruction of a wide variety of materials has been reported in recent years [Kench & Cooper, Nat Mach Intell, 2021; Yang et al., Journal of Mechanical Design, 2018; Hsu et al., JOM, 2021], where most of these networks are trained on open-access training data [Gratia et al., ACS Energy Lett, 2017; Hsu et al., J Power Sources, 2018]. Gayon-Lombardo et al. [Gayon-Lombardo et al., NPJ Comput Mater, 2020] used GAN to generate microstructures for multi-phase electrode, where the generator was modified upon training to produce periodic structures. However, a DL framework coupling the microstructure segmentation and variability quantification with generative algorithms for periodic SRVEs generation has not been reported.

More recently, denoising diffusion probabilistic models (DDPMs) have been adapted for microstructure generation and have shown improved robustness and distributional fidelity [Lee & Yun, Mechanics of Advanced Materials and Structures, 2024; Lyu & Ren, Scientific Reports, 2024; Lee et al., Engineering Applications of Artificial Intelligence, 2024]. Diffusion models are latent-variable generative frameworks rooted in nonequilibrium statistical physics, in which a parameterized Markov chain is trained via variational objectives to learn the reverse of a progressive noising process and thereby sample from the data distribution after a finite number of steps [Sohl-Dickstein et al., International Conference on Machine Learning, 2015; Ho et al., Adv Neural Inf Process Syst, 2020]. This formulation has proven effective for representing heterogeneous microstructures, including sparse or rare morphological features such as locally clustered pores and nonuniform fiber packing, and it naturally supports conditioning through scalar descriptors, vector embeddings, or spatial fields. Across comparative studies, diffusion-based approaches have demonstrated improved agreement with both image-space and descriptor-space statistics relative to variational autoencoder (VAE)- and GAN-based methods, as well as improved generalization to unseen conditions, making them well-suited for microstructure-inspired SRVE generation [Dhariwal & Nichol, Adv Neural Inf Process Syst, 2021; Dureth et al., Materials Today Communications, 2023; Azqadan et al., Acta Materialia, 2023].

Hybrid and task-coupled generative frameworks have been proposed that combine complementary strengths by integrating VAE-style latent structuring with adversarial, decoder-based, or diffusion-based formulations, enabling probabilistic process-structure-property (PSP) modeling and inverse design under physics-based constraints [Zhang et al., Computational Materials Science, 2024; Lyu & Ren, Materials Today Communications, 2025]. These hybrid approaches facilitate conditioning on either microstructural descriptors or surrogate-predicted properties for targeted and multi-objective sampling. However, most conditional deep generative models reported in the literature are trained on large open-source datasets [Hsu et al., Journal of Power Sources, 2018; Wang et al., Computer Methods in Applied Mechanics and Engineering, 2020; Prifling et al., Frontiers in Materials, 2021], and/or employ conditioning variables primarily to generate microstructures that target prescribed properties, consistent with typical inverse-design formulations. A methodology that instead leverages conditioning to reconstruct physically admissible microstructures from limited in-house experimental datasets, while preserving the aleatoric variability inherent to the parent material, has not been reported.

Thus, there is a need in the art for deep learning systems and methods for SRVE generation that leverage uncertainty-aware microstructural descriptors as conditioning signals to constrain the generative process toward physically admissible regions of microstructure space, preserve aleatoric variability inherent to the parent material, and serve as an inductive bias that stabilizes training and improves reconstruction fidelity under data-scarce conditions. The present invention satisfies that need.

### SUMMARY OF THE INVENTION

A micromechanics simulation method having the steps of collecting one or more images of at least one composite material, providing, to a first neural network, an input comprising the one or more images, segmenting one or more microstructures in the one or more images, quantifying one or more physical descriptors of one or more segmented microstructures, passing an output comprising the one or more segmented microstructures and one or more quantified physical descriptors to a second neural network, and generating one or more stochastic representative volume elements (SRVEs) based on the one or more segmented microstructures and one or more quantified physical descriptors with the second neural network.

In some embodiments, the method further includes the steps of providing, to the first neural network, an input comprising one or more generated SRVEs, comparing the one or more generated SRVEs with the one or more quantified physical descriptors, and predicting one or more physical descriptors for the one or more generated SRVEs.

In some embodiments, the method further includes the steps of characterizing one or more features of the one or more segmented microstructures with the first neural network, passing an output comprising the one or more characterized features to the second neural network, and generating the one or more SRVEs further based on the one or more characterized features. In some embodiments, the one or more features of the segmented microstructures are selected from the group consisting of one or more phases, one or more distributions, and one or more defects.

In some embodiments, the method further includes the steps of outputting data comprising one or more generated SRVEs to a micromechanics simulation module, and processing, with the micromechanics simulation module, the one or more generated SRVEs to compute at least one selected from the group consisting of composite homogenized elastic properties, longitudinal properties, transverse properties, in-plane properties, out-of-plane properties, local composite deformation, global composite deformation, time dependent responses, temperature dependent responses, time and temperature dependent responses, matrix and fiber damage, fiber/matrix interphase damage, creep response, and creep-fatigue response.

In some embodiments, the method further includes the step of before the processing step, applying one or more periodic boundary conditions (PBCs) to the one or more generated SRVEs. In some embodiments, the at least one composite material comprises at least one of a CMC, a polymer matrix composite (PMC), a fiber-reinforced PMC, and a metal matrix composite (MMC). In some embodiments, the first neural network comprises a regression neural network, and the second neural network comprises a generative adversarial network.

In some embodiments, the one or more images comprise at least one selected from the group consisting of a scanning electron microscope (SEM) image, a confocal microscope image, micro-X-ray computed tomography (micro-CT), and Energy-dispersive X-ray spectroscopy (EDS). In some embodiments, the one or more physical descriptors comprise at least one selected from the group consisting of fiber radii, fiber packing, fiber volume fraction, porosity, and fiber/matrix interphase thickness.

In some embodiments, the method further includes the step of quantifying one or more spatial descriptors of one or more segmented microstructures, wherein the one or more spatial descriptors comprise at least one selected from the group consisting of intra-tow spacing, fiber nearest-neighbor orientation, distance difference, angle difference, two-point correlation and three-point correlation. In some embodiments, the second neural network comprises a conditional discrete diffusion model configured to generate one or more SRVEs conditioned on a microstructural descriptor vector extracted from the one or more segmented microstructures.

In some embodiments, the microstructural descriptor vector comprises one or more physical descriptors comprising at least one of fiber volume fraction and porosity, and one or more spatial descriptors comprising at least one of intra-tow spacing, distance difference, nearest-fiber orientation, and angle difference, and wherein each spatial descriptor is parameterized by its mean, standard deviation, and quartiles to form a fixed-length conditioning vector.

In some embodiments, the conditional discrete diffusion model comprises a forward process defined by a categorical transition kernel that progressively replaces pixel-wise phase labels with uniformly random categories according to a time-dependent noising schedule, and a learned reverse process that iteratively restores the original categorical state toward a reconstructed segmentation conditioned on the microstructural descriptor vector.

In some embodiments, the conditional discrete diffusion model is implemented using a U-Net backbone comprising one or more down-sampling and up-sampling stages connected through residual blocks and skip connections, wherein timestep embeddings and microstructural descriptor embeddings are injected into the residual blocks and enforced through multi-head cross-attention blocks.

In some embodiments, the conditional discrete diffusion model is trained using an objective function combining a variational lower bound term and an auxiliary categorical cross-entropy term, wherein the cross-entropy term provides an enhanced supervision signal for minority phases such as pores, and wherein the descriptor vector is embedded as a conditioning signal that constrains the generative process toward physically admissible regions of microstructure space while preserving aleatoric variability.

In some embodiments, the method further includes the steps of extracting and parameterizing one or more microstructural descriptors from the one or more segmented microstructures using a statistical-based module, and synthesizing one or more SRVEs directly from the extracted descriptors using descriptor-driven stochastic construction routines.

In some embodiments, the statistical-based module performs a Dirichlet tessellation of fiber center coordinates to characterize polygonal cell geometry and quantify the degree of quasi-hexagonal fiber packing, and the resulting tessellation statistics are compared against a Poisson point process representing complete spatial randomness to identify clustering tendencies in the composite microstructure of the composite material.

In some embodiments, the statistical-based module generates one or more SRVEs using a periodic quasi-hexagonal generation algorithm and includes the steps of generating and relaxing seed points via Lloyd's relaxation to achieve a target fraction of six-sided Voronoi cells, sampling fiber center locations from the relaxed seed points, applying microstructure-informed centroid perturbations derived from statistical analysis of the one or more images to reproduce experimentally observed fiber clustering, and enforcing periodic boundary conditions by tracking fiber positions in angular coordinates such that fibers crossing SRVE boundaries are mapped to the opposite edge.

In some embodiments, the statistical-based module places matrix porosity within the generated SRVEs by sampling pore volume fractions from a mixture distribution and applying a distance-dependent placement probability that decays exponentially with increasing pore-to-fiber separation, thereby reproducing the spatial pore clustering near fiber surfaces observed in the one or more images.

A micromechanics simulation system having a computing device comprising one or more processors comprising at least one central processing unit (CPU) and one or more graphics processing units (GPUs) for parallel computing during neural network training and inference, and a non-transitory computer readable medium with instructions stored thereon, which when executed by the processor perform any steps of any disclosed methods.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is a diagram of an exemplary stochastic representative volume element (SRVE) generation framework for high-fidelity micromechanics simulations;

FIG. 2 is a diagram of an exemplary vanilla regression network;

FIG. 3 is a schematic of an exemplary microstructure generative framework;

FIG. 4 is a plot showing vanilla regression loss variation with training steps (epochs);

FIG. 5A and FIG. 5B are a set of plots showing Vanilla regression (Deep Learning) predictions on synthetic microstructures for (FIG. 5A) fiber volume fraction (V_{f}), and (FIG. 5B) porosity;

FIG. 6A through FIG. 6H are a series of images showing class activation maps (CAMs) prediction of vanilla regression tested on real C/SiNC and SiC/SiNC micrographs; FIG. 6A is an S400N C/SiNC SEM intra-tow micrograph; FIG. 6B is an image of a kernel capturing C/SiNC matrix, fiber and fiber damage; FIG. 6C is an image of a kernel capturing C/SiNC porosity at different fiber-matrix interface locations; FIG. 6D is an image of a kernel highlighting C/SiNC fiber-matrix interface; FIG. 6E is an S200H SiC/SiNC confocal micrograph; FIG. 6F and FIG. 6G are images showing kernels capturing SiC/SiNC fiber, matrix, matrix secondary phases and fiber-matrix interface; FIG. 6H is an image of kernels focusing on porosity at fiber interface as well as matrix microcrack;

FIG. 7 is a plot showing discriminator and generator loss function variation with generative adversarial network (GAN) training steps (epochs);

FIG. 8 is a plot showing average discriminator probabilities on real and generated microstructures, denoted as D(X) and D(G(Z)), respectively, with GAN training steps (epochs);

FIG. 9 is a plot showing average critic scores on real and generated microstructures, denoted as C(X) and C(G(Z)), respectively, as well as the gradient penalty term, with Wasserstein GAN (WGAN) training steps (epochs);

FIG. 10 is a plot showing inception score (IS) variation at 95% confidence interval (CI) with GAN/WGAN training steps (epochs);

FIG. 11A and FIG. 11B are a series of images showing generated microstructures using GAN for (FIG. 11A) non-periodic structure, (FIG. 11B) sample of periodic structure;

FIG. 12A through FIG. 12D are a set of plots showing homogenized elastic properties for C fiber/SiNC matrix CMC for baseline (pristine) and porosity SRVEs; FIG. 12A is a plot showing longitudinal Young's modulus; FIG. 12B is a plot showing transverse Young's modulus; FIG. 12C is a plot showing in-plane shear modulus; FIG. 12D is a plot showing out-of-plane shear modulus;

FIG. 13A through FIG. 13D are a set of plots showing homogenized elastic properties for SiC fiber/SiNC matrix CMC for baseline (pristine) and porosity SRVEs; FIG. 13A is a plot showing longitudinal Young's modulus; FIG. 13B is a plot showing transverse Young's modulus; FIG. 13C is a plot showing in-plane shear modulus; FIG. 13D is a plot showing out-of-plane shear modulus;

FIG. 14A through FIG. 14C are a set of plots showing the time-dependent deformation response of SiC/SiNC at 1200° C.; FIG. 14A is a plot showing total longitudinal strain; FIG. 14B is a plot showing constituent longitudinal stress; FIG. 14C is a plot showing creep mismatch ratio for baseline (pristine) and porosity SRVE;

FIG. 15A and FIG. 15B are a set of plots showing the time-dependent deformation response of SiC/SiNC at 800° C. and 1200° C. for the porosity SRVEs; FIG. 15A is a plot showing total longitudinal strain; FIG. 15B is a plot showing constituent longitudinal stress;

FIG. 16 is a diagram of an exemplary micromechanics simulation method;

FIG. 17 is a diagram of an exemplary computing environment;

FIG. 18 is a schematic of an exemplary software-implemented system and method for micromechanics simulation based on stochastic representative volume element generation;

FIG. 19 is a diagram illustrating exemplary fiber spatial descriptors, including nearest-neighbor distances and their angular orientations;

FIG. 20 is a diagram illustrating an exemplary algorithm for generating periodic quasi-hexagonal stochastic representative volume elements (SRVEs);

FIG. 21A and FIG. 21B are a set of images showing an exemplary unwrapped torus visualization for periodic boundary enforcement, including (FIG. 21A) projected circles on a torus and (FIG. 21B) projected circles unwrapped in an angular coordinate system;

FIG. 22 is an image showing a Dirichlet tessellation overlaid on an exemplary SEM micrograph of a SiC/BN/SiNC composite microstructure;

FIG. 23A through FIG. 23C are a set of images showing cross-sections of (FIG. 23A) an exemplary SiC/BN/SiNC microstructure with fibers, pores, and boron nitride (BN) interphase with examples of quasi-hexagonal packing outlined, (FIG. 23B) an exemplary simulated microstructures generated using the quasi-hexagonal method with quasi-hexagonal packing examples outlined, and (FIG. 23C) exemplary simulated microstructures generated using the random method;

FIG. 24A through FIG. 24C are a set of plots showing radially averaged two-point correlation comparisons with 95% confidence intervals between a full microstructure and generated SRVEs: (FIG. 24A) fiber-fiber autocorrelation, (FIG. 24B) porosity-porosity autocorrelation, and (FIG. 24C) fiber-porosity cross-correlation;

FIG. 25A through FIG. 25C are a set of images showing cross-sections of porosity damage contours for exemplary quasi-hexagonal (top) and random SRVEs (bottom) under longitudinal creep loading, shown after (FIG. 25A) 15 minutes, (FIG. 25B) 45 minutes, and (FIG. 25C) 240 minutes;

FIG. 26A through FIG. 26C are a set of images showing cross-sections of longitudinal Cauchy stress contours for exemplary quasi-hexagonal (top) and random SRVEs (bottom) under longitudinal creep loading, shown after (FIG. 26A) 1 minute, (FIG. 26B) 45 minutes, and (FIG. 26C) 240 minutes;

FIG. 27A through FIG. 27C are a set of images showing cross-sections of longitudinal creep strain contours for exemplary quasi-hexagonal (top) and random SRVEs (bottom) under longitudinal creep loading, shown after (FIG. 27A) 15 minutes, (FIG. 27B) 45 minutes, and (FIG. 27C) 240 minutes;

FIG. 28A is a diagram showing an exemplary U-Net backbone architecture used in the conditional discrete diffusion model; FIG. 28B is a diagram of an exemplary residual block;

FIG. 29 is a schematic of an exemplary circular padding strategy used to enforce periodic boundary continuity during the reverse diffusion process for SRVE generation;

FIG. 30A and FIG. 30B are a set of plots showing exemplary conditional diffusion model training results, including (FIG. 30A) evolution of the variational lower bound and categorical cross-entropy losses together with representative generated samples at selected epochs, and (FIG. 30B) Fréchet inception distance and inception score evolution demonstrating convergence and improved distributional fidelity;

FIG. 31A through FIG. 31F are a set of plots showing probability density distributions of microstructural descriptors for exemplary 65 μm SEM segments and SRVEs generated by a conditional diffusion model: (FIG. 31A) fiber volume fraction, (FIG. 31B) porosity, (FIG. 31C) intra-tow spacing, (FIG. 31D) distance difference, (FIG. 31E) nearest-fiber orientation, and (FIG. 31F) angle difference;

FIG. 32A through FIG. 32F are a set of plots showing probability density distributions of microstructural descriptors for exemplary 65 μm SEM segments and SRVEs generated by an unconditional diffusion model: (FIG. 32A) fiber volume fraction, (FIG. 32B) porosity, (FIG. 32C) intra-tow spacing, (FIG. 32D) distance difference, (FIG. 32E) nearest-fiber orientation, and (FIG. 32F) angle difference;

FIG. 33A through FIG. 33E are a set of images and plots showing three-dimensional extension and statistical validation of descriptor-aware SRVEs, including (FIG. 33A) an exemplary 3D SRVE showing fiber, matrix, and pore phases, (FIG. 33B) an isosurface visualization of the pore phase, (FIG. 33C) a comparison of porosity distributions between a 2D SRVE generated by the conditional diffusion model and the corresponding 3D SRVE, (FIG. 33D) pore autocorrelation, and (FIG. 33E) fiber-pore cross-correlation comparing 2D and 3D SRVEs with 95% confidence interval bands; and

FIG. 34 is a schematic of an exemplary stochastic multiscale modeling framework illustrating propagation of microstructural variability to higher length scales using bottom-up hierarchical and synergistic approaches.

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

The disclosed technology is directed towards a system and method that provides a multi deep learning-based framework for efficient, automated microstructure reconstruction and generation of stochastic representative volume elements (SRVEs) with periodic boundary conditions (PBCs) for accurate modeling of ceramic matrix composite (CMC) response. In some embodiments, the disclosed system and method comprise a convolutional neural network coupled with regression layers to act as a vanilla regression network for semantic segmentation of the microstructure, allowing accurate characterization of microstructure phases and their distributions at the microscale. In some embodiments, a scanning electron microscope and confocal microscope are used to obtain C/SiNC and SiC/SiNC CMCs micrographs for vanilla regression testing.

In one aspect, a DL vanilla regression network is used to semantically segment C/SiNC and SiC/SiNC micrographs and quantify variability of the physical descriptors, specifically fiber volume fraction V_{f} and porosity. In some embodiments, a generative adversarial network (GAN) and variants thereof are designed to generate periodic SRVEs during training. A subset of the generated SRVEs is then selected to conform to the predictions of physical descriptors.

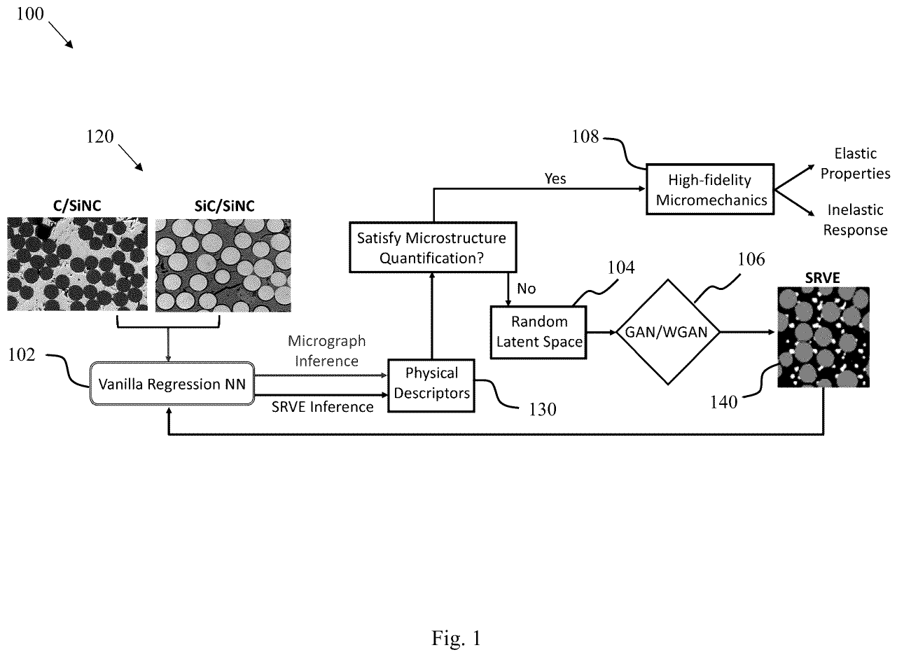

Multi DL Framework: Disclosed herein is a comprehensive multi-DL framework for automated segmentation, variability quantification, and subsequent reconstruction of microstructures to accurately simulate the mechanical response of CMCs. The disclosed system and method facilitate efficient microstructure analysis through a vanilla regression network, comprising a series of convolutional layers coupled with a linear regression output layer. In some embodiments, GANs equipped with a circular padding (CP) algorithm within the generator network's architecture are employed to produce high-fidelity periodic SRVEs. FIG. 1 shows a schematic of an exemplary SRVE generation framework for high-fidelity micromechanics simulations, referred to herein as system 100. A summary of system 100 is presented in FIG. 1, where one or more images 120 (e.g., CMC micrographs) are passed through a first neural network 102 (e.g., a vanilla regression NN) in order to implicitly segment one or more microstructures contained in the plurality of images 120. System 100 further quantifies the microstructure uncertainties in terms of physical descriptors 130. In some embodiments, the physical descriptors comprise fiber volume fraction (V_{f}) and porosity. In some embodiments, a second neural network 106 (e.g., a GAN, or a WGAN) is used to generate SRVEs 140 based on the results of the first neural network 102 and a prior random latent space 104 distribution. Thereafter, the first neural network 102 (e.g., vanilla regression NN) takes the SRVEs 140 as input to check against the quantified physical descriptors 130. If the GAN generated SRVEs 140 satisfy the quantification results, the SRVEs 140 are processed through high-fidelity micromechanics simulations 108 to compute, for example, the composite elastic and time-dependent responses.

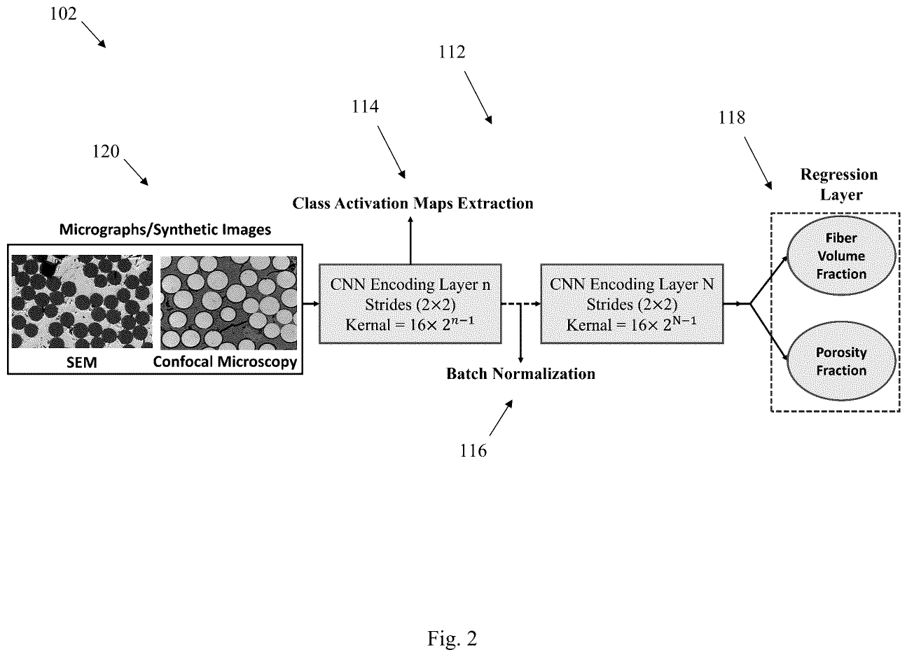

Vanilla regression network: FIG. 2 shows an exemplary architecture of the first neural network 102 (e.g., vanilla regression network). The first neural network 102 operates in a feedforward regime, with its architecture illustrated in FIG. 2. First, the input 224×224 grayscale microstructure image of the plurality of images 120 is augmented through affine transformations to increase the training set size, which is then processed through a network 112 (e.g., a convolutional neural network (CNN)) comprising N layers, each equipped with (2×2) strided convolutions [Krizhevsky et al., Adv Neural Inf Process Syst, 2012]. This process decreases the image resolution by half at each layer (n), while increasing the image depth by applying different filters (e.g., image encoding). The first CNN layer has a base number of kernels, which simply refers to the number of filters applied to the image (i.e., kernel size for RGB image is three). The weights of these filters are updated during training to encode the primary microstructure features which mostly contribute to the microstructure regression output quantity. The kernel number is doubled with every halving of the image throughout the CNN layers, resulting in an increased number or abundance of learning kernels while maintaining computational feasibility. The 4×4 kernel size implies that each kernel applied to the input image of plurality of images 120 (or feature maps from previous layer) has a height and width of four pixels. This defines the window that the filter will cover and compute features as it convolves. In some embodiments, the depth of the CNN layers comprises a total of four layers providing the necessary feature extraction capability while maintaining computational efficiency during model training.

Analogous to DL classification problems, the kernels can be considered as class activation maps (CAMs) which implicitly segment each pixel of the image resulting in semantic segmentation. The segmentation is referred to as implicit since the main objective of the network 112 is to predict microstructure quantities, however the learning filters at the first CNN layer are leveraged as CAMs 114 for further functionality of the network. This results in identifying different microstructure phases for a given CMC microstructure image, as well as predicting useful scalar values that may be used to constrain the microstructure generation output. Batch normalization 116 [Ioffe & Szegedy, International Conference on Machine Learning, 2015] is applied to the output of each CNN layer to maintain the same output distribution; when this condition is violated, the first neural network 102 is said to suffer from internal covariate shift. Consequently, this enhances the training convergence rate during optimizing the loss function as well as avoiding modal collapse [Chong et al., Proceedings of the International Joint Conference on Neural Networks, 2020]. Rectified linear unit (ReLU) activation function [Dubey & Jain, Applications of Computing, Automation and Wireless Systems in Electrical Engineering, 2019] is applied to the output of each batch normalization operation to introduce model nonlinearities. Note that the sequence of applying batch normalization and ReLU activation function to the output of the CNN layer is variable, as discussed herein. Finally, the output of the last CNN layer is flattened and passed through the output linear regression layer 118 to predict V_{f} and porosity.

In some embodiments, the disclosed regression models use mean square error (MSE), mean absolute error (MAE) and mean squared logarithmic error (MSLE) [Borkowski et al., Compos Struct, 2023] as continuous and differentiable loss functions that can be minimized/maximized to solve for optimum NN weights and biases at one of the loss function local minima. The disclosed vanilla regression model has ~220,000 trainable parameters, which results in an efficient relatively small model to optimize during training. In the example disclosed below, the vanilla regression network is minimized using MSE as the loss function between the labeled and predicted microstructure quantities. The loss function minimization requires first-order optimization algorithms such as mini-batch stochastic gradient descent (SGD)-based optimizers to introduce noise during training and help mitigate overfitting. Adam [Kingma & Ba, ArXiv Preprint, 2014] which is an efficient adaptive SGD is selected with initial learning rate of 2×10⁻⁴, and β₁ set to 0.5 which is a hyperparameter controlling the exponential decay of the first moment of the gradient. The rest of the optimizer hyperparameters are set to default values as per the TensorFlow documentation [TensorFlow, API Documentation, 2023]. The model is built using TensorFlow 2.12 package and python 3.9.16, and it is trained on GPU, Nvidia RTX 3090 for parallel computations.

Training data acquisition comprises using featured-based representation CV and a structured orthogonal mesh-based generator [Khafagy et al., J Compos Mater, 2021] which tends to concentrate porosity around matrix/fiber interface. Monte Carlo simulations are then applied by introducing stochasticity in the generator hyperparameters, thus generating a pool of synthetic labeled training/validation microstructure images that has a subset representing the CMC microstructure space. Each synthetic input microstructure is in grayscale (i.e., 0-255 pixel value) and labeled with the corresponding V_{f} and porosity values as shown in FIG. 2. The difference in the scale of labels values can represent a challenge in model convergence and accuracy, hence standard normal scaling is used to bring all the values to a similar range during model training. The mean and standard deviation of the synthetic image population is stored for inverse scaling during final model predictions. The training/validation microstructure images are selected to be in grayscale, so that the optimized vanilla regression can be tested on real CMC micrographs. The total number of synthetic images generated are ~3,500 images, the images are divided into training and validation datasets using 80%/20% split. Multiple split ratios are investigated and it is determined that the selected split ratio is sufficient to prevent overfitting (i.e., no divergence in the validation loss), while maintaining a stable monotonic decrease of the training loss. Additionally, training on synthetic microstructures is proven to be sufficient in characterizing the actual CMC micrographs obtained using a scanning electron microscope (SEM) and a confocal microscope (CM) as discussed further in the example below. It is important to note that the primary advantage of DL-based CV over feature-based CV is the modularity and accuracy of the algorithm. The applied filters in DL-based CV are learned from solving an optimization problem, while the applied filters in feature-based CV are less efficient and need human expertise intervention.

Generative algorithms: GAN is selected to provide flexibility in generating any desired structure as it depends on minmax game theory using two deep CNNs which are called the discriminator and generator NNs [Goodfellow et al., Adv Neural Inf Process Syst, 2014]. Both networks, also referred to herein as “agents”, compete during training and the loss functions are optimized in an adversarial way. The disclosed framework overcomes the gradient approximations of previous methods and results in a powerful generator that is guided by the discriminator NN gradient updates.

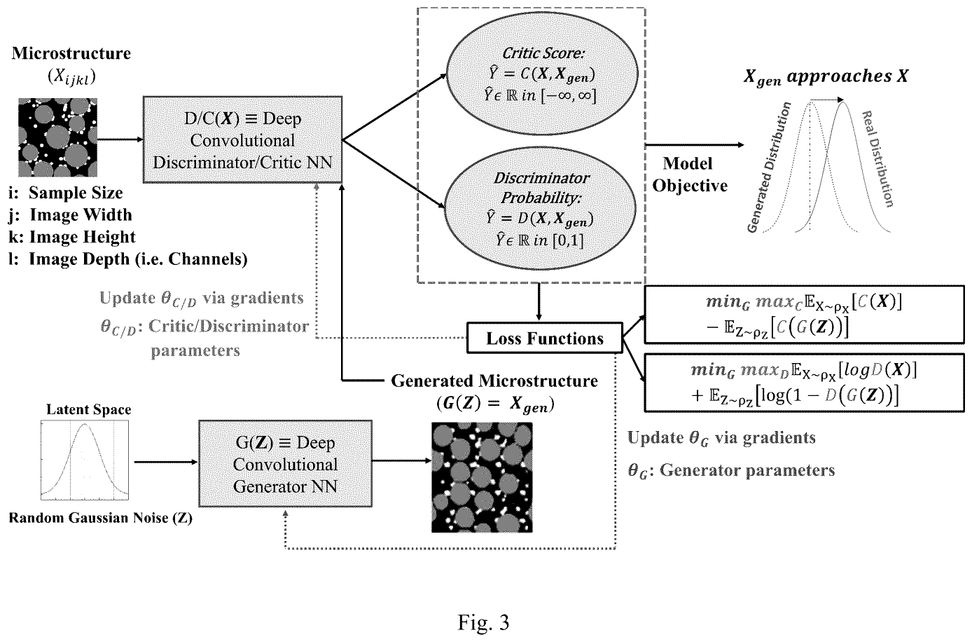

FIG. 3 is a schematic of exemplary microstructure generative frameworks. GAN is challenging to train and stabilize and requires various improvements to achieve rapid training convergence and high-fidelity microstructures generation. Another variant of the GAN is the Wasserstein GAN (WGAN) [Arjovsky et al., International Conference on Machine Learning, 2017], which comprises two deep CNNs called the critic and the generator, and operates in the same minmax setup during training. However, WGAN focuses on minimizing the earth mover (EM) distance between the actual and generated microstructures distributions. Careful design of the DL networks, and selecting the training learning rates and balancing between the two CNNs during gradient updates are vital in achieving satisfactory results. FIG. 3 shows a schematic of the generative frameworks.

Training of the GAN depends on optimizing the binary cross entropy [Yang et al., Journal of Mechanical Design, 2018] for both the discriminator and generator NNs, however this algorithm is sensitive to the network's design, and for certain distributions it can lead to saturation of the learning parameters (vanishing gradients) due to the logarithmic nature of the loss function. Loss function formulation based on EM distance is a more robust formulation where EM represents the minimum energy required to move the generated distribution to the actual distribution. Wasserstein distance used in WGAN is an approximation of EM [Gulrajani et al., Adv Neural Inf Process Syst, 2017]. The main drawback of the WGAN formulation is that the critic NN should satisfy 1-Lipschitz continuity for Wasserstein distance to be valid. In particular the critic NN should result in a function where the L2-norm of the function gradient with respect to any input image should not exceed one. This was addressed by Gulrajani et al. [Gulrajani et al., Adv Neural Inf Process Syst, 2017] through penalty regularization, where the deviation of the 1-Lipschitz continuity will increase a gradient regularization term and hence will penalize the loss function during training. This implicitly results in an optimized model that approximately satisfies the penalty constraint. In order to ensure that the constraint is applied to all real and generated microstructure spaces while maintaining computational efficiency, both real and generated images are merged through an interpolation function, and the gradient of the critic is computed with respect to the new interpolated images. The interpolated microstructure image \hat{X} is formulated in Eq. 1 in the example below, where X is the real microstructure tensor of images that has been drawn from the real microstructure space distribution (ρ_{X}), Z is a latent space vector resembling an input noise which follows a prior probability distribution (ρ_{Z}), ϵ is an interpolation coefficient tensor and I is an identity tensor. ϵ controls the contribution of the generated image to \hat{X}, as well as introduces noise into the real microstructure. It is selected to follow a uniform distribution [0,1], hence stochastic interpolated image is created during each training step. This provides wide space of images that approximately accommodate the microstructure spaces and maintain the validity of the Wasserstein distance computation. Although this approach avoids the computational expense of calculating the critic's gradients with respect to all images, it remains less efficient than traditional GAN. This inefficiency arises from the incorporation of first-order derivatives in the penalty term and consequently results in second-order derivative computations during loss function optimization.

Adversarial network design: In some embodiments, the GAN framework comprises the following components: first, the discriminator NN, which includes five CNN layers with (2×2) strided convolutions, similar to the vanilla regression. Batch normalization is directly applied to each CNN layer output to avoid internal covariate shift and speed up the convergence. Additionally, batch normalization acts as a regularization technique to avoid NNs overfitting. The nonlinear activation function is selected to be LeakyReLU [Dubey & Jain, Applications of Computing, Automation and Wireless Systems in Electrical Engineering, 2019] with negative slope coefficient set to 0.2. This will allow some negative values to be activated in the CNN layer that can also mitigate the vanishing gradients problem. Zero padding is applied during convolutions, so that the output of each CNN layer is exactly half the input size. The choice of convolutional setup along with sufficient number of kernels are critical in enhancing the capability of GAN in generating realistic structures. Additionally, a CNN layer is added with non-zero padding and a sigmoid activation function to predict a label in the range of zero and one given a discriminator input image. Meanwhile, WGAN's critic NN has a similar design to GAN's discriminator; however, the last CNN layer has a linear activation function. Second, the GAN/WGAN generator NN is designed to be a mirror of the discriminator/critic NN [Hsu et al., JOM, 2021; Li et al., International Design Engineering Technical Conferences and Computers and Information in Engineering Conference, 2018], however the last generator layer is a CNN with softmax activation function to predict the probability of finding a certain microstructure phase such as matrix, fiber and porosity at each generated image pixel. The model is built using the same DL packages and GPU architecture discussed above and shown in FIG. 2.

Aspects of the disclosure relate to a software-implemented system and method for micromechanics simulation, in which SRVE generation is integrated with micromechanical solvers to predict composite thermomechanical response while preserving statistically quantified microstructural variability. An SRVE ensemble reproduces, in a statistical sense, the effective response of a parent microstructure. In some embodiments, the system includes: (i) a microstructure characterization module that receives microscopy images and performs semantic segmentation and feature regression using computer-vision and deep regression models to identify constituents and manufacturing-induced defects; (ii) a statistical-based module that extracts and parameterizes microstructural descriptors, including constituent and defect volume fractions, spatial-distribution measures, and higher-order point statistics, and that optionally synthesizes SRVEs from such descriptors using descriptor-driven stochastic construction routines, including tessellation-based and Voronoi/Dirichlet-based placement with periodic-boundary enforcement; (iii) a deep generative module comprising a generative adversarial network submodule and a conditional diffusion submodule, each configured to generate SRVEs conditioned on the extracted descriptors, wherein descriptor constraints guide the generative process toward a subset of microstructural space consistent with measured variability and improve training stability and generation fidelity; and (iv) a micromechanics module that evaluates the generated SRVEs using homogenization and nonlinear thermomechanical and creep-response solvers to output effective properties and time-dependent material responses. The framework is modular and applicable to multiple composite classes, including ceramic matrix composites and high-temperature polymer matrix composites, and enables uncertainty-aware simulation across relevant length scales.

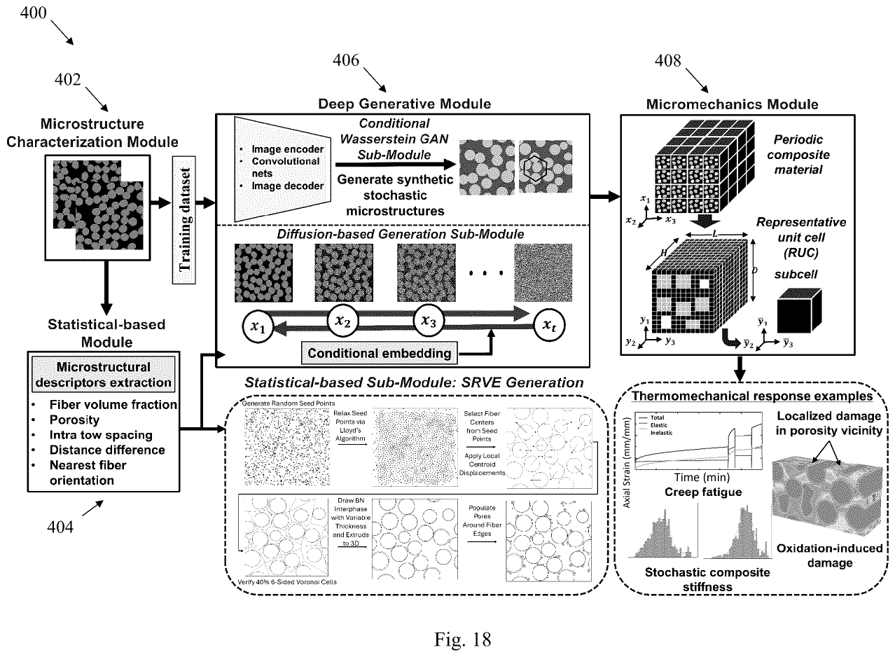

FIG. 18 illustrates an exemplary software-implemented system and method for micromechanics simulation based on stochastic representative volume element generation, referred to herein as system 400. It should be appreciated that system 400 may comprise and/or functionally connect with any of the components or aspects of any disclosed systems (e.g., system 100) and methods. As shown in FIG. 18, system 400 comprises a plurality of integrated modules as described herein. In some embodiments, a first module is a microstructure characterization module 402 that receives one or more microscopy images, including SEM, confocal microscope, micro-CT, or EDS images, and performs semantic segmentation using convolutional neural network-based computer-vision models and physical descriptor quantification using deep regression models, to identify constituent phases including fiber, matrix, and fiber/matrix interphase, as well as manufacturing-induced defects including porosity and matrix microcracks. In some embodiments, a second module is a statistical-based module 404 that extracts and parameterizes a set of physical descriptors including fiber volume fraction, porosity, fiber diameter, and interphase thickness, and spatial descriptors including intra-tow nearest-neighbor spacing and orientation statistics, and that synthesizes one or more SRVEs from such descriptors using descriptor-driven stochastic construction routines, specifically Dirichlet tessellation-based fiber placement with Lloyd's relaxation, microstructure-informed centroid perturbations, an exponential decay-based pore placement model, and angular coordinate-based periodic boundary enforcement analogous to an unwrapped torus surface. In some embodiments, a third module is a deep generative module 406 comprising a generative adversarial network submodule, including GAN and WGAN variants with circular padding-based periodic boundary enforcement during training, and a conditional discrete diffusion submodule implementing a U-Net backbone with sinusoidal timestep embeddings, multilayer perceptron (MHLP)-projected descriptor conditioning, and multi-head cross-attention enforcement, each configured to generate one or more SRVEs conditioned on the extracted microstructural descriptor vector, wherein descriptor embedding guides the generative process toward physically admissible regions of microstructure space consistent with measured variability while improving training stability and generation fidelity under data-scarce conditions. In some embodiments, a fourth module is a micromechanics module 408 that evaluates the generated SRVEs using the high-fidelity generalized method of cells (HFGMC) homogenization solver and nonlinear thermomechanical and creep-response solvers incorporating a time-hardening viscoplastic constitutive model with Arrhenius temperature dependence, to output effective composite elastic stiffness properties and time-dependent constituent-level stress, strain, and damage responses. The modular architecture of system 400 enables each submodule to operate independently or in combination, and the framework is applicable to multiple composite material classes including ceramic matrix composites and polymer matrix composites across relevant length scales.

In some embodiments, statistical-based module 404 is configured to extract and parameterize microstructural descriptors from the one or more segmented microstructures and to synthesize one or more SRVEs directly from such descriptors using descriptor-driven stochastic construction routines. The statistical-based module receives as inputs the mean and standard deviation of physical descriptors including fiber volume fraction, porosity, fiber/matrix interphase thickness, and fiber diameter, as retrieved from quantitative analysis of the one or more images.

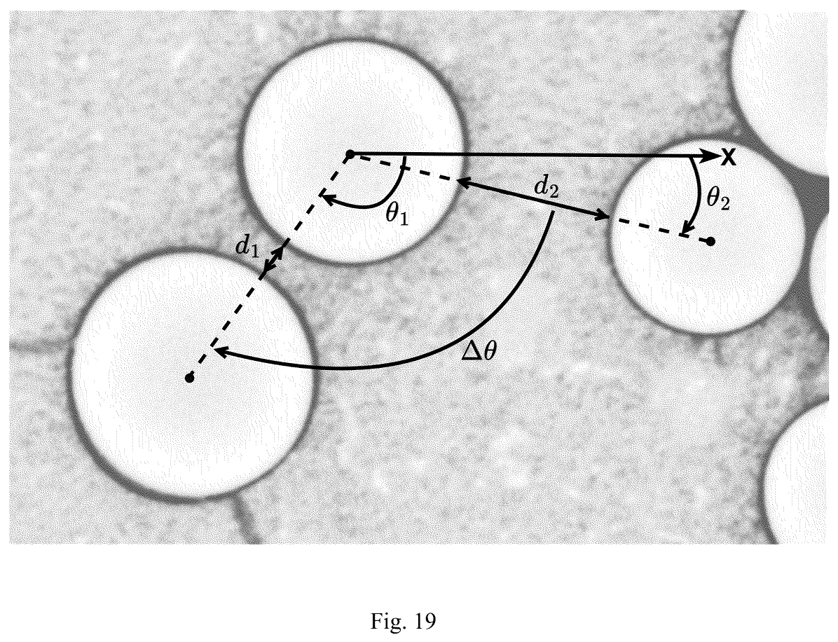

FIG. 19 is a diagram illustrating exemplary fiber spatial descriptors, including nearest-neighbor distances and their angular orientations. In some embodiments, the microstructural descriptor vector comprises the scalar physical descriptors and parameterized spatial descriptor distributions illustrated in FIG. 19, including fiber volume fraction and porosity as physical descriptors, and intra-tow spacing, distance difference, nearest-fiber orientation, and angle difference as spatial descriptors. Because spatial descriptors are computed over fiber pairs within each image and yield variable-length vectors, each distribution is summarized by its mean, standard deviation, and quartiles at the 25^{th}, 50^{th}, and 75^{th} percentiles, yielding a total of five statistical parameters per spatial descriptor. Combined with the two scalar physical descriptors, this parameterization produces a fixed-length 17-dimensional conditioning vector per microstructure. This statistics-based vector is normalized using dataset-level mean and standard deviation and projected through an MLP to obtain a compact conditional embedding. While these descriptors are not intended to provide a complete basis for direct microstructure reconstruction, embedding them as conditioning inputs provides microstructure-inspired constraints that improve diffusion-model training stability and convergence under data-scarce conditions, by confining the generative process to a physically admissible subset of the microstructural space consistent with the measured descriptor variability.

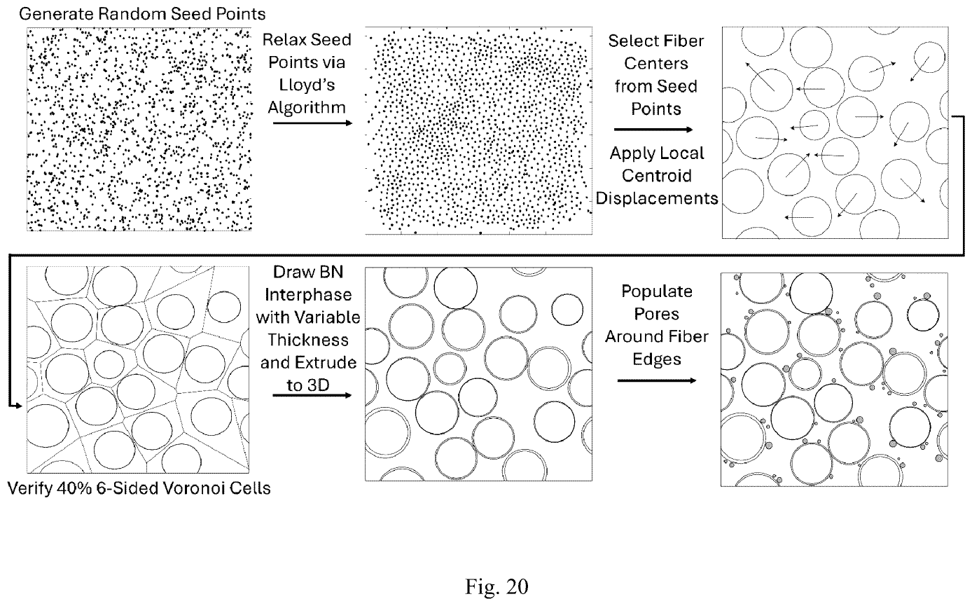

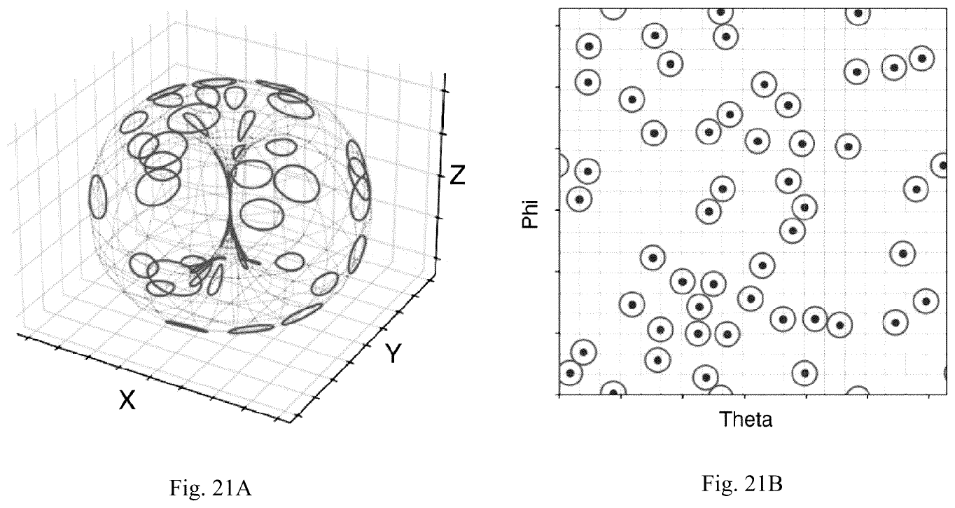

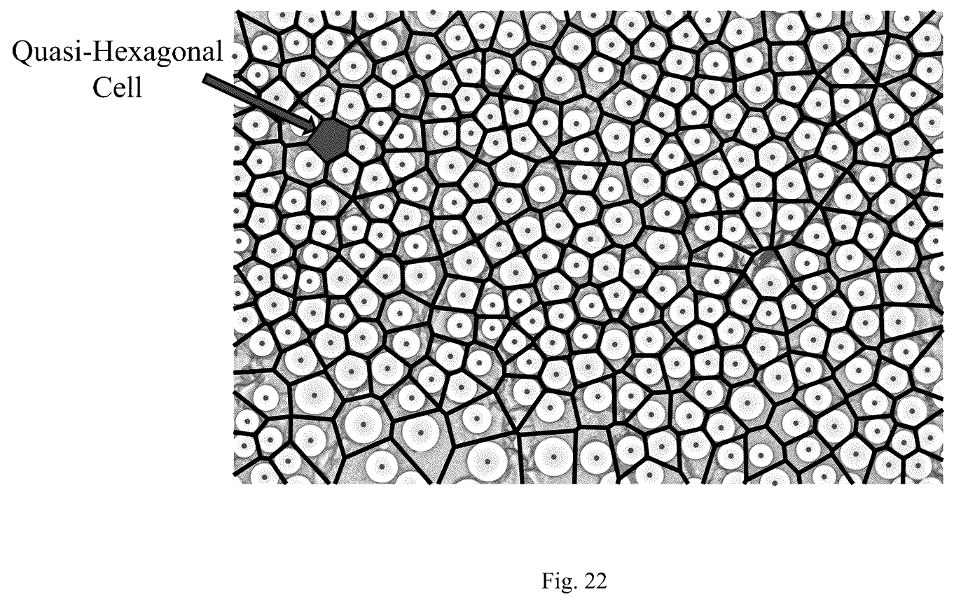

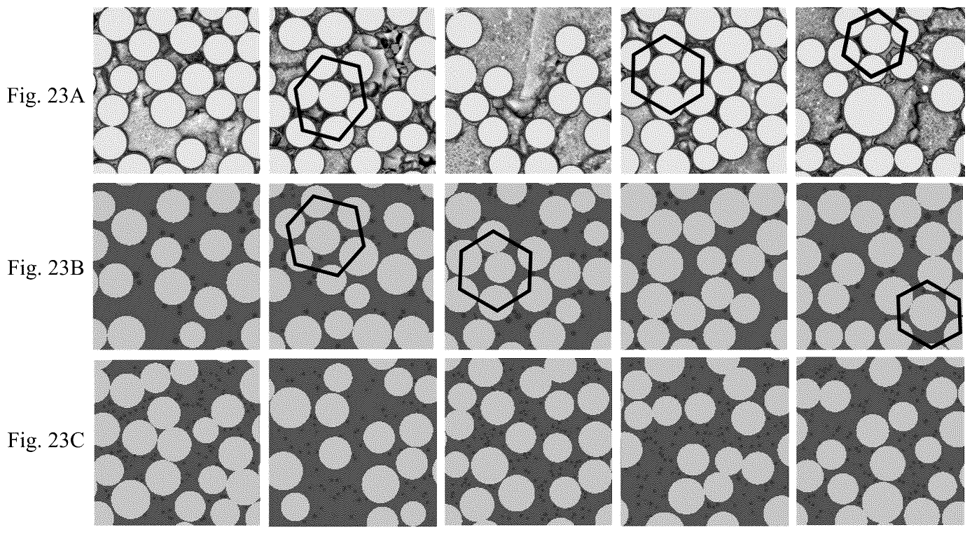

FIG. 20 is a diagram illustrating an exemplary algorithm for generating periodic quasi-hexagonal stochastic representative volume elements (SRVEs). FIG. 21A and FIG. 21B are a set of images showing an exemplary unwrapped torus visualization for periodic boundary enforcement, including (FIG. 21A) projected circles on a torus and (FIG. 21B) projected circles unwrapped in an angular coordinate system. FIG. 22 is an image showing a Dirichlet tessellation overlaid on an exemplary SEM micrograph of a SiC/BN/SiNC composite microstructure.

In some embodiments, the statistical-based module 404 performs a Dirichlet tessellation of fiber center coordinates extracted from the segmented microstructures to characterize polygonal cell geometry and quantify the degree of quasi-hexagonal fiber packing. The tessellation partitions the spatial domain based on proximity using Euclidean distance along with Voronoi regions or cells to analyze the patterns among fiber center points. The resulting tessellation statistics are compared against a Poisson point process representing complete spatial randomness (CSR) to identify clustering tendencies in the composite microstructure, as shown in FIG. 22. In some embodiments, the percentage of six-sided polygonal cells in the experimental fiber distribution is evaluated and compared to that of the Poisson distribution to quantify the degree of quasi-hexagonal packing, which is then used as a target criterion during SRVE generation.

Periodic Quasi-Hexagonal Generation: In some embodiments, the statistical-based module 404 generates one or more SRVEs using a periodic quasi-hexagonal generation algorithm. The general workflow of this algorithm is illustrated in FIG. 20. The algorithm begins by generating a large number of seed points randomly distributed across a bounded domain. The seed points are then modified using Lloyd's relaxation to shift each point to the centroid of its respective Voronoi cell, thereby increasing the likelihood of six-sided cells. A Dirichlet tessellation is subsequently applied to the relaxed seed points to spatially partition the domain based on proximity. The number of Voronoi bounded cells with exactly six edges is then counted to determine the percentage of quasi-hexagonal structures. This process is repeated iteratively until the percentage of quasi-hexagonal Voronoi cells converges to a target value within a specified tolerance.

In some embodiments, once the tessellation criterion is satisfied, fiber center locations are sampled from the relaxed seed points. Before placing each fiber, the algorithm verifies that its center lies within the SRVE boundaries and avoids overlap with existing fibers by calculating the Euclidean distance between centers, accounting for variability in fiber radii. If an overlap is detected, the fiber is repositioned randomly until either a non-overlapping placement is identified or a maximum number of attempts is reached. This process continues until a target fiber volume fraction is achieved.

In some embodiments, microstructure-informed centroid perturbations are applied to shift the fibers toward the actual spatial patterns observed in the one or more images. The fiber nearest-neighbor orientation distribution of the experimental data is compared with that of the unperturbed Dirichlet tessellation, and each centroid is displaced by an angular shift randomly selected within a prescribed interval toward the experimentally observed alignment. This perturbation is applied across an ensemble of SRVEs to provide statistically robust convergence of the resulting quasi-hexagonal patterns. The approach introduces microstructurally consistent bias observed in the real microstructure while maintaining computational efficiency, reproducibility, and statistical consistency.

In some embodiments, the statistical-based module 404 enforces periodic boundary conditions by tracking fiber positions using angular coordinates such that fibers crossing SRVE boundaries are mapped to the opposite edge, simulating periodic boundary conditions and maintaining spatial continuity analogous to an unwrapped torus surface, as shown in FIG. 21A and FIG. 21B. A Dirichlet tessellation is again performed after fiber perturbation to evaluate the percentage of six-sided cells. If the fraction of quasi-hexagonal cells falls below the target, the algorithm continues to resample from the relaxed seed points. This iterative sampling and evaluation process repeats until an SRVE satisfying both the desired fiber volume fraction and the perturbed Voronoi criterion is generated.

In some embodiments, the statistical-based module 404 extrudes the generated two-dimensional fiber arrangement into a three-dimensional SRVE of specified thickness. Matrix porosity is subsequently placed within the three-dimensional SRVE by sampling pore volume fractions from a mixture of two truncated normal distributions. A primary distribution is defined by the mean and standard deviation extracted from the one or more images, and a secondary distribution is introduced to reproduce skewness observed in the experimental porosity distribution. Pore volume fractions are sampled from the mixture, and spherical pores are inserted into the matrix phase until the target porosity volume is achieved. To ensure that no pores overlap with fibers, the Euclidean distance between candidate pore locations and the fiber structure is calculated, and only pores maintaining a minimum distance from fibers are accepted. In some embodiments, a distance-dependent placement probability is applied such that the probability of placing a pore decays exponentially with increasing pore-to-fiber separation, thereby reproducing the spatial pore clustering near fiber surfaces observed in the one or more images. In some embodiments, pores are additionally restricted from touching SRVE boundaries to preserve periodicity.

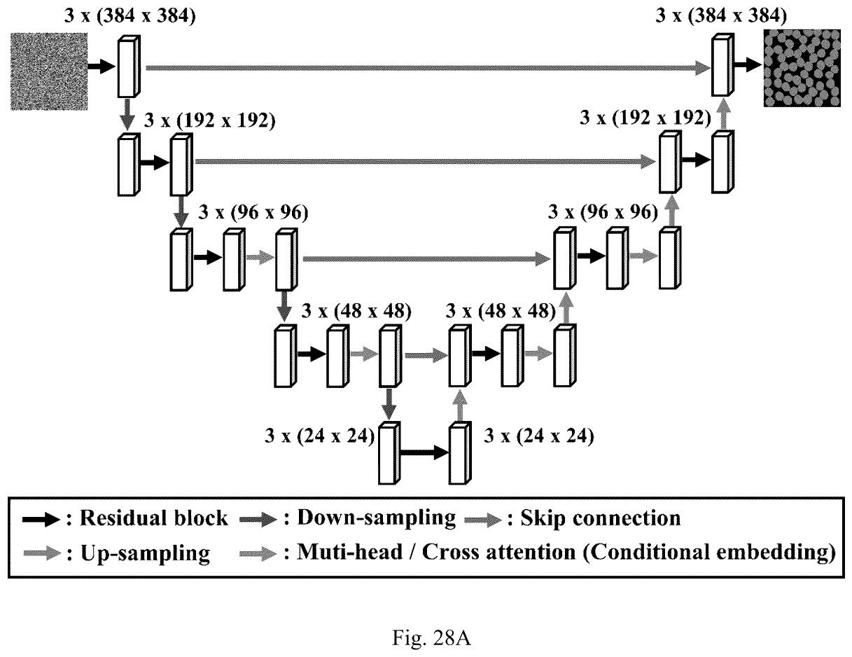

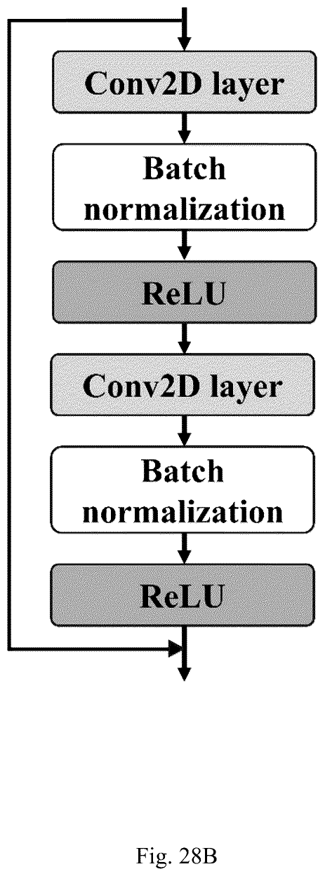

FIG. 28A is a diagram showing an exemplary U-Net backbone architecture used in the conditional discrete diffusion model. FIG. 28B is a diagram of an exemplary residual block. In some embodiments, the second neural network 106 comprises a conditional discrete diffusion model configured to generate one or more SRVEs conditioned on a microstructural descriptor vector extracted from the one or more segmented microstructures. FIG. 28A and FIG. 28B illustrate the U-Net backbone architecture used in the conditional discrete diffusion model and the residual block. Prior to training, segmented SEM micrographs are resized to match the down-sampling and up-sampling factors of the backbone architecture and augmented using a set of geometric transformations including rotations and flips to expand the training dataset and enhance statistical diversity. Each augmented image is paired with its corresponding conditional microstructural descriptor vector in a one-to-one supervised mapping, enabling the model to learn an implicit relationship between the physical and spatial features and the underlying microstructure.

In some embodiments, the microstructural descriptor vector comprises the scalar physical descriptors and parameterized spatial descriptor distributions defined above and illustrated in FIG. 19, including fiber volume fraction, porosity, intra-tow spacing, distance difference, nearest-fiber orientation, and angle difference. Because spatial descriptors are computed over fiber pairs within each image and yield variable-length vectors, each distribution is summarized by its mean, standard deviation, and quartiles to form a fixed-length conditioning vector. This statistics-based vector is normalized using dataset-level mean and standard deviation and projected through a multilayer perceptron (MLP) to obtain a compact conditional embedding. While these descriptors are not intended to provide a complete basis for direct microstructure reconstruction, embedding them as conditioning inputs provides microstructure-inspired constraints that improve diffusion-model training stability and convergence under data-scarce conditions.

Diffusion Process: In some embodiments, the forward diffusion process, reverse denoising process, U-Net backbone architecture, and conditional embedding mechanism are as described above and illustrated in FIG. 28A and FIG. 28B. The timestep and conditional embeddings are summed to modulate the residual blocks, while conditioning is additionally enforced through multi-head cross-attention blocks within the U-Net, as described in the preceding embodiments.

Training Objective: In some embodiments, the conditional discrete diffusion model is trained using an objective function combining a variational lower bound (VLB) term and an auxiliary categorical cross-entropy (CE) term. The VLB term enforces probabilistic consistency of the reverse diffusion transitions by quantifying the Kullback-Leibler divergence between the true reverse posteriors of the forward diffusion process and the model reverse transitions across timesteps. Although the VLB already contains a categorical negative log-likelihood component, relying on the VLB objective alone may provide insufficient learning signal for minority phases such as pore regions, which occupy a small global volume fraction in the microstructure. Accordingly, an explicit pixel-wise CE term is included as an auxiliary objective to provide a stronger supervision signal, improve training stability and convergence in the early training stages, and enhance the reconstruction of minority phases over subsequent epochs. A weighting coefficient controls the relative contribution of the CE and VLB components to provide a trade-off between optimization stability and accurate recovery of microstructural features.

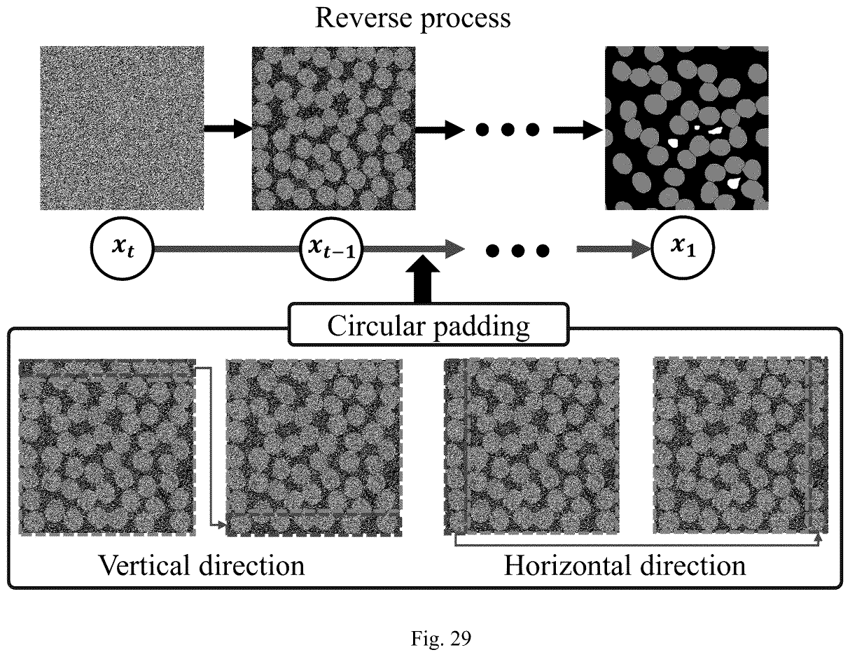

Periodic Boundary Enforcement: FIG. 29 is a schematic of an exemplary circular padding strategy used to enforce periodic boundary continuity during the reverse diffusion process for SRVE generation. In some embodiments, a circular padding strategy is applied during the reverse diffusion process to enforce periodic boundary continuity during SRVE generation, as illustrated in FIG. 29. This strategy ensures that the generated SRVEs satisfy the periodicity requirements necessary for compatibility with micromechanics-based homogenization simulations. In some embodiments, the descriptor vector is embedded as a conditioning signal that constrains the generative process toward physically admissible regions of microstructure space while preserving aleatoric variability inherent to the parent material, thereby acting as an inductive bias that stabilizes training and improves reconstruction fidelity under data-scarce conditions.

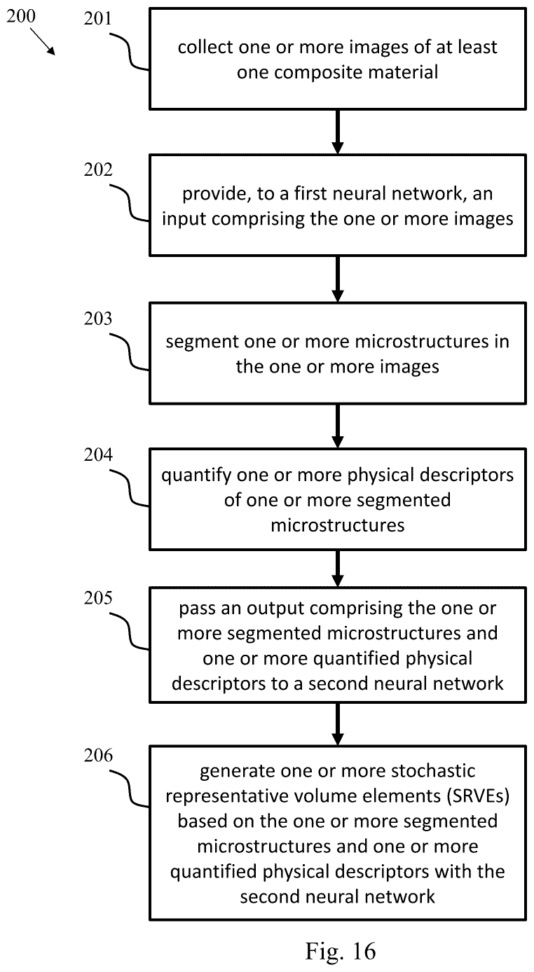

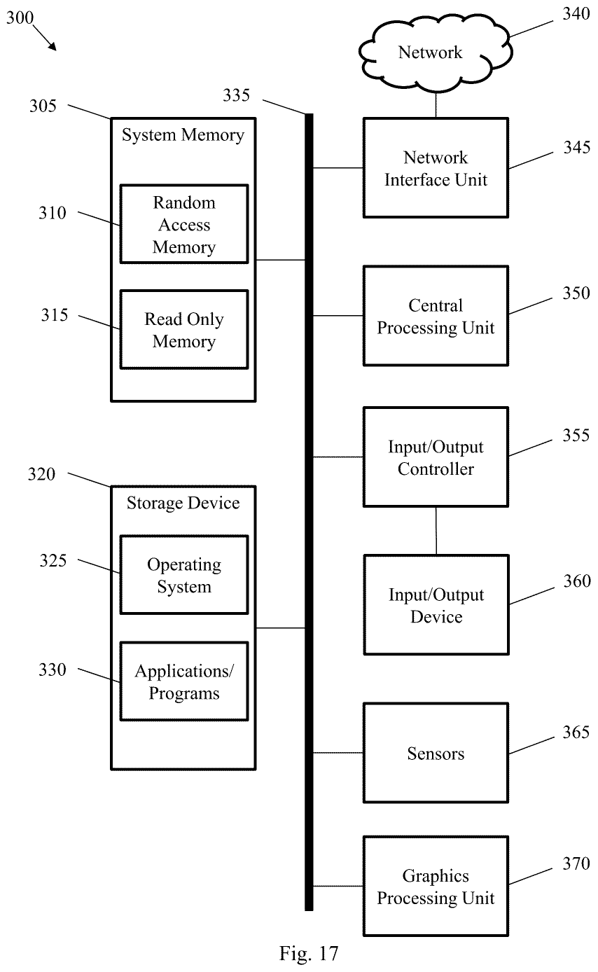

Aspects of the present invention relate to a micromechanics simulation method. Referring now to FIG. 16, an exemplary micromechanics simulation method 200 is shown. In some embodiments, method 200 comprises the steps of: 201 collecting one or more images of at least one composite material; 202 providing, to a first neural network, an input comprising the one or more images; 203 segmenting one or more microstructures in the one or more images; 204 quantifying one or more physical descriptors of one or more segmented microstructures; 205 passing an output comprising the one or more segmented microstructures and one or more quantified physical descriptors to a second neural network; and 206 generating one or more stochastic representative volume elements (SRVEs) based on the one or more segmented microstructures and one or more quantified physical descriptors with the second neural network. In some embodiments, the at least one composite material comprises at least one of a CMC, a polymer matrix composite (PMC), a fiber-reinforced PMC, and a metal matrix composite (MMC).

Various networks (e.g., neural networks) may be used with the disclosed system and method as discussed further herein. For example, in some embodiments, the first neural network comprises a regression neural network, and the second neural network comprises a generative adversarial network. Imaging of materials (e.g., ceramics, CMCs) may be provided to the disclosed system and method from any appropriate source. In some embodiments, the one or more images comprise at least one of a scanning electron microscope (SEM) image, a confocal microscope image, micro-X-ray computed tomography (micro-CT), and Energy-dispersive X-ray spectroscopy (EDS).

The disclosed micromechanics simulation method may also be used to predict physical descriptors of ceramics, CMCs and/or SRVEs thereof. In some embodiments, method 200 further comprises the steps of providing, to the first neural network, an input comprising one or more generated SRVEs; comparing the one or more generated SRVEs with the one or more quantified physical descriptors; and predicting one or more physical descriptors for the one or more generated SRVEs. In some embodiments, the one or more physical descriptors comprise at least one of fiber radii, fiber packing, fiber volume fraction (V_{f}), porosity, fiber/matrix interphase thickness, intra-tow spacing (i.e., fiber nearest-neighbor spacing), fiber nearest-neighbor orientation, and two- and three-point correlations. It should be appreciated that the descriptors provide quantitative information about microstructural features and their variability. As used herein, all of the foregoing are physical descriptors; however, intra-tow spacing, fiber nearest-neighbor orientation, and two- and three-point correlations may also be referred to as spatial descriptors, as they characterize the spatial arrangement and correlation of microstructural features.

The disclosed micromechanics simulations method may also be used to characterize features such as phases and distributions of ceramics, CMCs, and/or SRVEs thereof. In some embodiments, method 200 further comprises the steps of characterizing one or more features of the one or more segmented microstructures with the first neural network; passing an output comprising the one or more characterized features to the second neural network; and generating the one or more SRVEs further based on the one or more characterized features. In some embodiments, the one or more features of the segmented microstructures comprise any of one or more phases, one or more distributions, one or more defects, fiber packing, variability in fiber radii, porosity distribution, porosity distribution around the fiber periphery, matrix microcracks, and fiber/matrix interphase thickness. It should be appreciated that in some embodiments, the second neural network (i.e., the generative network) will generate periodic SRVEs incorporating these microstructural characteristics.

The disclosed micromechanics simulations system and method may be operatively and/or communicatively connected to a micromechanics simulations module comprising any known mechanics simulations software known by one of normal skill in the art. Using the simulation module, various computations may be performed, and various properties and responses of ceramics, CMCs and the SRVEs thereof may be calculated. In some embodiments, method 200 further comprises the steps of outputting data comprising one or more generated SRVEs to a micromechanics simulation module; and processing, with the micromechanics simulation module, the one or more generated SRVEs to compute at least one of composite homogenized elastic properties (e.g., longitudinal, transverse, in-plane, and out-of-plane properties), local and global composite deformation, time-dependent responses, temperature dependent responses, time and temperature dependent responses, matrix and fiber damage, fiber/matrix interphase damage, creep response, and creep-fatigue response.

The disclosed micromechanics simulation method has the benefit of applying periodic boundary conditions to the generated SRVEs to refine the reconstruction and representation of the ceramic or CMC. For example, in some embodiments, method 200 further comprises the step of applying one or more periodic boundary conditions (PBCs) to the one or more generated SRVEs. It should be appreciated that the PBCs may be applied to the SRVEs before processing with the simulations module, or they may be applied after a first processing to further refine the model. In some embodiments, the application of PBCs occurs during the training of the deep generative network (e.g., the second neural network), thus eliminating any postprocessing steps and preserving the integrity of the generated SRVEs (i.e., stochastic periodic microstructures).

In some embodiments, the second neural network comprises a conditional discrete diffusion model configured to generate one or more SRVEs conditioned on a microstructural descriptor vector extracted from the one or more segmented microstructures. In some embodiments, the microstructural descriptor vector comprises one or more physical descriptors including fiber volume fraction and porosity, and one or more spatial descriptors including intra-tow spacing, distance difference, nearest-fiber orientation, and angle difference, wherein each spatial descriptor distribution is parameterized by its mean, standard deviation, and quartiles to form a fixed-length conditioning vector.

In some embodiments, the conditional discrete diffusion model comprises a forward process defined by a categorical transition kernel that corrupts pixel-wise phase labels according to a time-dependent noising schedule, and a learned reverse process that iteratively denoises a corrupted categorical state toward a reconstructed segmentation conditioned on the microstructural descriptor vector.

In some embodiments, the conditional discrete diffusion model is implemented using a U-Net backbone [Dhariwal & Nichol, Adv Neural Inf Process Syst, 2021] comprising one or more down-sampling and up-sampling stages connected through residual blocks and skip connections, wherein timestep embeddings and microstructural descriptor embeddings are injected into the residual blocks and enforced through multi-head cross-attention blocks.

In some embodiments, the conditional discrete diffusion model is trained using an objective function combining a variational lower bound term [Austin et al., Adv Neural Inf Process Syst, 2021] and an auxiliary categorical cross-entropy term, wherein the cross-entropy term provides an enhanced supervision signal for minority phases such as pores, and wherein the descriptor vector is embedded as a conditioning signal that constrains the generative process toward physically admissible regions of microstructure space while preserving aleatoric variability.

In some embodiments, the second neural network is preceded by or operates in conjunction with a statistical-based module configured to extract and parameterize microstructural descriptors from the one or more segmented microstructures and to synthesize one or more SRVEs directly from such descriptors using descriptor-driven stochastic construction routines.

In some embodiments, the statistical-based module performs a Dirichlet tessellation [Green & Sibson, The Computer Journal, 1978] of fiber center coordinates to characterize polygonal cell geometry and quantify the degree of quasi-hexagonal fiber packing, wherein the resulting tessellation statistics are compared against a Poisson point process representing complete spatial randomness (CSR) [Ripley, Journal of the Royal Statistical Society: Series B, 1977] to identify clustering tendencies in the composite microstructure.

In some embodiments, the statistical-based module generates one or more SRVEs using a periodic quasi-hexagonal generation algorithm comprising: generating and relaxing seed points via Lloyd's relaxation [Xiao, University of South Carolina, 2010] to achieve a target fraction of six-sided Voronoi cells; sampling fiber center locations from the relaxed seed points; applying microstructure-informed centroid perturbations derived from statistical analysis of the one or more images to reproduce experimentally observed fiber clustering; and enforcing periodic boundary conditions by tracking fiber positions in angular coordinates such that fibers crossing SRVE boundaries are mapped to the opposite edge.

In some embodiments, the statistical-based module places matrix porosity within the generated SRVEs by sampling pore volume fractions from a mixture distribution and applying a distance-dependent placement probability that decays exponentially with increasing pore-to-fiber separation, thereby reproducing the spatial pore clustering near fiber surfaces observed in the one or more images.

Accordingly, the aforementioned systems may include computing devices communicatively and/or operatively connected to the systems for performing one or more steps of any of the disclosed methods. For example, in some embodiments, the computing devices enable deep learning, machine learning and/or artificial intelligence with various networks (e.g., neural networks, adversarial networks) for micromechanics simulations. In some aspects of the present invention, software executing the instructions provided herein may be stored on a non-transitory computer-readable medium, wherein the software performs some or all of the steps of the present invention when executed on a processor.

Aspects of the invention relate to algorithms executed in computer software. Though certain embodiments may be described as written in particular programming languages, or executed on particular operating systems or computing platforms, it is understood that the system and method of the present invention is not limited to any particular computing language, platform, or combination thereof. Software executing the algorithms described herein may be written in any programming language known in the art, compiled or interpreted, including but not limited to C, C++, C#, Objective-C, Java, JavaScript, MATLAB, Python, PHP, Perl, Ruby, or Visual Basic. It is further understood that elements of the present invention may be executed on any acceptable computing platform, including but not limited to a server, a cloud instance, a workstation, a thin client, a mobile device, an embedded microcontroller, a television, or any other suitable computing device known in the art.

Parts of this invention are described as software running on a computing device. Though software described herein may be disclosed as operating on one particular computing device (e.g., a dedicated server or a workstation), it is understood in the art that software is intrinsically portable and that most software running on a dedicated server may also be run, for the purposes of the present invention, on any of a wide range of devices including desktop or mobile devices, laptops, tablets, smartphones, watches, wearable electronics or other wireless digital/cellular phones, televisions, cloud instances, embedded microcontrollers, thin client devices, or any other suitable computing device known in the art.

Similarly, parts of this invention are described as communicating over a variety of wireless or wired computer networks. For the purposes of this invention, the words “network”, “networked”, and “networking” are understood to encompass wired Ethernet, fiber optic connections, wireless connections including any of the various 802.11 standards, cellular WAN infrastructures such as 3G, 4G/LTE, or 5G networks, Bluetooth®, Bluetooth® Low Energy (BLE) or Zigbee® communication links, or any other method by which one electronic device is capable of communicating with another. In some embodiments, elements of the networked portion of the invention may be implemented over a Virtual Private Network (VPN).

FIG. 17 and the following discussion are intended to provide a brief, general description of a suitable computing environment in which the invention may be implemented. While the invention is described above in the general context of program modules that execute in conjunction with an application program that runs on an operating system on a computer, those skilled in the art will recognize that the invention may also be implemented in combination with other program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote memory storage devices.

FIG. 17 depicts an illustrative computer architecture for a computer 300 for practicing the various embodiments of the invention. The computer architecture shown in FIG. 17 illustrates a conventional personal computer, including a central processing unit 350 (“CPU”) and one or more graphics processing units 370 (“GPU”) for parallel computation during neural network training and inference, a system memory 305, including a random access memory 310 (“RAM”) and a read-only memory (“ROM”) 315, and a system bus 335 that couples the system memory 305 to the CPU 350. A basic input/output system containing the basic routines that help to transfer information between elements within the computer, such as during startup, is stored in the ROM 315. The computer 300 further includes a storage device 320 for storing an operating system 325, application/program 330, and data.

The storage device 320 is connected to the CPU 350 through a storage controller (not shown) connected to the bus 335. The storage device 320 and its associated computer-readable media provide non-volatile storage for the computer 300. Although the description of computer-readable media contained herein refers to a storage device, such as a hard disk or CD-ROM drive, it should be appreciated by those skilled in the art that computer-readable media can be any available media that can be accessed by the computer 300.

By way of example, and not to be limiting, computer-readable media may comprise computer storage media. Computer storage media includes volatile and non-volatile, removable and non-removable media implemented in any method or technology for storage of information such as computer-readable instructions, data structures, program modules or other data. Computer storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other medium which can be used to store the desired information and which can be accessed by the computer.

According to various embodiments of the invention, the computer 300 may operate in a networked environment using logical connections to remote computers through a network 340, such as TCP/IP network such as the Internet or an intranet. The computer 300 may connect to the network 340 through a network interface unit 345 connected to the bus 335. It should be appreciated that the network interface unit 345 may also be utilized to connect to other types of networks and remote computer systems.

The computer 300 may also include an input/output controller 355 for receiving and processing input from a number of input/output devices 360, including a keyboard, a mouse, a touchscreen, a camera, a microphone, a controller, a joystick, or other types of input device. Similarly, the input/output controller 355 may provide output to a display screen, a printer, a speaker, or other type of output device. The computer 300 can connect to the input/output device 360 via a wired connection including, but not limited to, fiber optic, Ethernet, or copper wire or wireless means including, but not limited to, Wi-Fi, Bluetooth, Near-Field Communication (NFC), infrared, or other suitable wired or wireless connections.

As mentioned briefly above, a number of program modules and data files may be stored in the storage device 320 and/or RAM 310 of the computer 300, including an operating system 325 suitable for controlling the operation of a networked computer. The storage device 320 and RAM 310 may also store one or more applications/programs 330. In particular, the storage device 320 and RAM 310 may store an application/program 330 for providing a variety of functionalities to a user. For instance, the application/program 330 may comprise many types of programs such as a word processing application, a spreadsheet application, a desktop publishing application, a database application, a gaming application, internet browsing application, electronic mail application, messaging application, and the like. According to an embodiment of the present invention, the application/program 330 comprises a multiple functionality software application for providing word processing functionality, slide presentation functionality, spreadsheet functionality, database functionality and the like.

The computer 300 in some embodiments can include a variety of sensors 365 for monitoring the environment surrounding and the environment internal to the computer 300. These sensors 365 can include a Global Positioning System (GPS) sensor, a photosensitive sensor, a gyroscope, a magnetometer, thermometer, a proximity sensor, an accelerometer, a microphone, biometric sensor, barometer, humidity sensor, radiation sensor, or any other suitable sensor.

Aspects of the invention relate to machine learning executed on a computing device, wherein the computing device may be computer 300. In some embodiments, the disclosed system and method utilize machine learning algorithms and models, including one or more neural networks, that may operate on at least one computing device (e.g., computer 300). The disclosed system may employ various types of neural networks known in the art, including but not limited to feedforward neural networks (FNNs), convolutional neural networks (CNNs), recurrent neural networks (RNNs), transformer networks, autoencoders, generative adversarial networks (GANs), Radial Basis Function Networks (RBFNs), extreme learning machines (ELMs), quantum neural networks (QNNs), and deep neural networks (DNNs).

Machine learning is a branch of artificial intelligence (AI) that enables systems to learn and improve from experience without being explicitly programmed. Machine learning models analyze data sets to identify patterns and correlations and then use those patterns to make predictions or decisions. Machine learning models can generally be categorized into three primary types: supervised learning, unsupervised learning, and semi-supervised learning.

Supervised learning involves training a model using labeled datasets to classify data or predict outcomes accurately. As input data is fed into the model, the model adjusts its internal parameters (e.g., weights) to minimize prediction errors. Common methods used in supervised learning include neural networks, naïve Bayes classifiers, linear regression, logistic regression, random forests, and support vector machines (SVMs).

Classification is a common task in supervised learning, where data inputs are categorized into distinct classes. Classification models may include binary classifiers (e.g., spam vs. non-spam) and multi-class classifiers (e.g., identifying different species of animals). A decision tree is a widely used classification method that applies a sequence of “if-then” conditions to narrow down possible outcomes.

Regression is another form of supervised learning where the output is a continuous variable rather than a discrete category. Linear regression predicts a continuous value based on a linear relationship between inputs and outputs, while logistic regression predicts categorical outcomes based on defined inputs.

Unsupervised learning involves analyzing unlabeled datasets to identify hidden patterns or groupings without human intervention. Principal component analysis (PCA) and singular value decomposition (SVD) are common techniques used to reduce data dimensionality and reveal underlying structures.

Clustering is a key unsupervised learning technique where data points are grouped based on shared features or proximity. K-means clustering is a widely used method where the number of clusters is defined by a variable “k,” and the algorithm iteratively adjusts cluster centroids to minimize variance within each cluster. Other clustering methods include hierarchical clustering and probabilistic clustering.

Semi-supervised learning combines elements of both supervised and unsupervised learning. A model is initially trained using a smaller labeled dataset, which then guides the classification and feature extraction from a larger unlabeled dataset. Semi-supervised learning is particularly useful when acquiring large amounts of labeled data is costly or impractical.

Deep learning is a subfield of machine learning that uses neural networks with multiple hidden layers to process and analyze complex data. Neural networks mimic the structure and function of the human brain, comprising layers of interconnected nodes (neurons). Each neuron receives input data, applies a transformation based on assigned weights, and passes the result to the next layer.

A typical neural network consists of: input layer—receives raw data inputs; hidden layer(s)—applies mathematical transformations using weighted connections; and output layer—generates the final prediction or classification.

Convolutional neural networks (CNNs) are a type of neural network particularly well-suited for processing image and spatial data. CNNs use convolutional layers to extract spatial features from input data, pooling layers to reduce dimensionality, and fully connected layers to generate output predictions.

Deep neural networks (DNNs) are composed of multiple hidden layers and are capable of learning complex patterns in large datasets. Recurrent neural networks (RNNs) are a type of deep learning network designed for sequential data, such as time series or natural language, where previous inputs influence future outputs. Long short-term memory (LSTM) networks are a specialized form of RNN that mitigates issues with long-term dependencies.

Generative adversarial networks (GANs) are a class of machine learning models in which two neural networks a generator and a discriminator are trained together in a competitive framework. The generator creates synthetic data (e.g., images, audio) from random noise, while the discriminator evaluates whether the generated data is real or fake. The generator improves its output by trying to fool the discriminator, while the discriminator becomes better at distinguishing real data from generated data. This adversarial process drives both networks to improve over time, leading to the generation of highly realistic data.

Types of GANs include: Vanilla GAN—The original GAN model, where the generator and discriminator are trained using a minimax loss function. Deep Convolutional GAN (DCGAN)—Uses convolutional layers instead of fully connected layers, improving the quality of generated images. Conditional GAN (cGAN)—Conditions the generation process on class labels or other input data, enabling targeted generation (e.g., generating images of specific objects). Wasserstein GAN (WGAN)—Introduces the Wasserstein distance (Earth Mover's distance) as the loss function, which improves training stability and reduces mode collapse (when the generator produces limited variations of data). WGAN-GP (Wasserstein GAN with gradient penalty)—Improves WGAN by adding a gradient penalty to enforce the Lipschitz constraint, further enhancing training stability. CycleGAN—Used for unpaired image-to-image translation (e.g., converting paintings to photos) by enforcing consistency between the forward and backward transformations. StyleGAN—Generates high-resolution and highly detailed images using a style-based generator architecture, allowing greater control over features like face shape and texture. GANs are widely used in fields such as computer vision, natural language processing, and creative design, but they can be difficult to train due to instability and mode collapse challenges that models like WGAN and WGAN-GP address effectively.

In some embodiments, the disclosed system may include an AI model trained using reinforcement learning, where an agent learns to make decisions through trial and error by interacting with an environment and receiving feedback in the form of rewards or penalties.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the system and method of the present invention. The following working examples therefore, specifically point out the exemplary embodiments of the present invention, and are not to be construed as limiting in any way the remainder of the disclosure.

### Example 1: Multi Deep Learning-Based Stochastic Microstructure Reconstruction and High-Fidelity Micromechanics Simulation of Time-Dependent Ceramic Matrix Composite Response

A multi deep learning-based framework was developed for efficient, automated microstructure reconstruction and generation of stochastic representative volume elements (SRVEs) with periodic boundary conditions (PBCs) for accurate modeling of ceramic matrix composite (CMC) response. The methodology comprises a convolutional neural network coupled with regression layers to act as a vanilla regression network for semantic segmentation of the microstructure, allowing accurate characterization of the phases and their distributions at the microscale. Scanning electron microscope and confocal microscope were used to obtain C/SiNC and SiC/SiNC CMCs micrographs for vanilla regression testing. Microstructure variability in terms of fiber volume fraction and porosity was quantified through the output regression layer, ensuring accurate representation of material variability in SRVE construction. Generative adversarial network (GAN) and its variants were designed to produce high-fidelity SRVE, spanning CMCs microstructure variability space. A circular padding algorithm was developed to generate SRVEs with PBCs during training of GANs. The accuracy of the generated SRVEs was established through micromechanics simulations, where an efficient formulation of the high-fidelity generalized methods of cells (HFGMC) approach was used to compute the effective mechanical properties. An iterative algorithm was implemented in the HFGMC solver to simulate time-dependent deformation of SiC/SiNC subjected to creep loading conditions.

In the disclosed example, a DL vanilla regression network was used to semantically segment C/SiNC and SiC/SiNC micrographs and quantify variability of the physical descriptors, specifically fiber volume fraction V_{f} and porosity. The GAN and its variants were designed to generate periodic SRVEs during training. A subset of the generated SRVEs was then selected to conform to the predictions of physical descriptors. A comprehensive investigation was conducted to provide insights about the GAN's architecture design, stability, and convergence during optimization, and training assessment metrics are provided herein. The generated microstructures' diversity, validity and accuracy were assessed through micromechanics simulations to fully evaluate the performance of the developed framework. Simulations were conducted using the generated SRVE, with PBC, to analyze the homogenized CMCs elastic properties, as well as the time-dependent deformation at elevated temperatures. Lastly, the impact of porosity and temperature on the deformation mechanisms is discussed herein and compared with literature.

FIG. 1 shows a schematic of an exemplary SRVE generation framework for high-fidelity micromechanics simulations.

Multi DL Framework: A comprehensive multi-DL framework was developed for automated segmentation, variability quantification, and subsequent reconstruction of microstructures to accurately simulate the mechanical response of CMCs. The methodology facilitates efficient microstructure analysis through a vanilla regression network, comprising a series of convolutional layers coupled with a linear regression output layer. The non-oxide CMC samples utilized in this study were S400N C/SiNC and S200H SiC/SiNC (obtained from COIC Inc., San Diego, California, USA). GANs equipped with a circular padding (CP) algorithm within the generator network's architecture were employed to produce high-fidelity periodic SRVEs. Assessment metrics to ensure diversity and realism across the generated SRVEs are discussed herein. A summary of the overall framework is presented in FIG. 1, where the CMC micrographs are passed through the vanilla regression NN in order to implicitly segment the microstructure, as well as quantify the microstructure uncertainties in terms of physical descriptors. GAN was used to generate SRVEs based on prior random latent space distribution. Thereafter, the vanilla regression NN took the SRVEs as input to check against the quantified physical descriptors. If the GAN generated SRVEs satisfied the quantification results, they were processed through high-fidelity micromechanics simulations to compute the composite elastic and time-dependent responses, as discussed further herein.

Vanilla regression network: The vanilla regression network operates in a feedforward regime, with its architecture illustrated in FIG. 2. First, the input 224×224 grayscale microstructure image was augmented through affine transformations to increase the training set size, which is then processed through a network comprising N layers, each equipped with (2×2) strided convolutions [Krizhevsky et al., Adv Neural Inf Process Syst, 2012]. This process decreases the image resolution by half at each layer (n), while increasing the image depth by applying different filters (image encoding). The first CNN layer has a base number of kernels, which simply refers to the number of filters applied to the image (i.e., kernel size for RGB image is three). The weights of these filters were updated during training to encode the primary microstructure features which mostly contribute to the microstructure regression output quantity. The kernel number was doubled with every halving of the image throughout the CNN layers, resulting in an abundance of learning kernels while maintaining computational feasibility. The 4×4 kernel size implies that each kernel applied to the input image (or feature maps from previous layer) has a height and width of four pixels. This defines the window that the filter will cover and compute features as it convolves. The depth of the CNN layers has been investigated, and it was determined that using a total of four layers provided the necessary feature extraction capability while maintaining computational efficiency during model training.

Analogous to DL classification problems, the kernels can be considered as class activation maps (CAMs) which can implicitly segment each pixel of the image resulting in semantic segmentation. The segmentation is referred to as implicit since the main objective of the network was to predict microstructure quantities, however the learning filters at the first CNN layer were leveraged as CAMs for further functionality of the network. This resulted in identifying different microstructure phases for a given CMC microstructure image, as well as predicting useful scalar values that were used to constrain the microstructure generation output. Batch normalization [Ioffe & Szegedy, International Conference on Machine Learning, 2015] was applied to the output of each CNN layer to maintain the same output distribution; when this condition is violated, the NN was said to suffer from internal covariate shift. Consequently, this enhances the training convergence rate during optimizing the loss function as well as avoiding modal collapse [Chong et al., Proceedings of the International Joint Conference on Neural Networks, 2020]. Rectified linear unit (ReLU) activation function [Dubey & Jain, Applications of Computing, Automation and Wireless Systems in Electrical Engineering, 2019] was applied to the output of each batch normalization operation to introduce model nonlinearities. Note that the sequence of applying batch normalization and ReLU activation function to the output of the CNN layer was subjected to experimentation and empirical investigation. As discussed by Ioffe et al. [Ioffe & Szegedy, International Conference on Machine Learning, 2015] in the original batch normalization formulation, applying it just before the nonlinear activation function is likely to produce activations with a stable distribution, yielding to improved training stability and speed. This is attributed to the non-sparse and symmetric nature of the convolutional layer output. Finally, the output of the last CNN layer was flattened and passed through the output linear regression layer to predict V_{f} and porosity.

Regression models usually use mean square error (MSE), mean absolute error (MAE) and mean squared logarithmic error (MSLE) [Borkowski et al., Compos Struct, 2023] as continuous and differentiable loss functions that can be minimized/maximized to solve for optimum NN weights and biases at one of the loss function local minima. The vanilla regression model has ~220,000 trainable parameters, which resulted in an efficient yet relatively small model to optimize during training. In this example, the vanilla regression network was minimized using MSE as the loss function between the labeled and predicted microstructure quantities. The loss function minimization requires first-order optimization algorithms such as mini-batch stochastic gradient descent (SGD)-based optimizers to introduce noise during training and help mitigate overfitting. Adam [Kingma & Ba, ArXiv Preprint, 2014] which is an efficient adaptive SGD was selected with initial learning rate of 2×10⁻⁴, and β₁ set to 0.5 which was a hyperparameter controlling the exponential decay of the first moment of the gradient. The rest of the optimizer hyperparameters were set to default values as per the TensorFlow documentation [TensorFlow, API Documentation, 2023]. The model was built using TensorFlow 2.12 package and python 3.9.16, and it is trained on GPU, Nvidia RTX 3090 for parallel computations.

Training data acquisition was accomplished using featured-based representation CV and a structured orthogonal mesh-based generator [Khafagy et al., J Compos Mater, 2021] which tends to concentrate porosity around matrix/fiber interface. Monte Carlo simulations were then applied by introducing stochasticity in the generator hyperparameters, thus generating a pool of synthetic labeled training/validation microstructure images that has a subset representing the CMC microstructure space. Each synthetic input microstructure was in grayscale (i.e., 0-255 pixel value) and labeled with the corresponding V_{f} and porosity values as shown in FIG. 2. The difference in the scale of labels values can represent a challenge in model convergence and accuracy, hence standard normal scaling was used to bring all the values to a similar range during model training. The mean and standard deviation of the synthetic image population was stored for inverse scaling during final model predictions. The training/validation microstructure images were selected to be in grayscale, so that the optimized vanilla regression could be tested on real CMC micrographs. The total number of synthetic images generated was ~3,500 images, the images were divided into training and validation datasets using 80%/20% split. Multiple split ratios were investigated, and it was determined that the selected split ratio was sufficient to prevent overfitting (i.e., no divergence in the validation loss), while maintaining a stable monotonic decrease of the training loss. Additionally, training on synthetic microstructures was proven to be sufficient in characterizing the actual CMC micrographs obtained using a scanning electron microscope (SEM) and a confocal microscope (CM) as discussed further herein. It is important to note that the primary advantage of DL-based CV over feature-based CV is the modularity and accuracy of the algorithm. The applied filters in DL-based CV were learned from solving an optimization problem, while the applied filters in feature-based CV were less efficient and needed human expertise intervention.

FIG. 2 shows an exemplary architecture of the vanilla regression network.

Generative algorithms: Traditional generative algorithms depend on maximizing the log likelihood such as the deep Boltzmann machine [Salakhutdinov & Hinton, Artificial Intelligence and Statistics, 2009]. However, such models usually suffer from intractable likelihood functions and necessitate approximations to the likelihood gradients, which limit their application in complex high dimensionality structure generation. Variational autoencoders (VAEs) and GANs are infamous in generating samples with arbitrary high dimensional density. Even though VAEs introduce stochasticity in its latent space, they share limitations with the traditional generative algorithms since they also depend on approximations of the log likelihood [Pu et al., Adv Neural Inf Process Syst, 2016]; this results in averaged microstructure features which can cause leakage in the microstructure variability and hence diminishing the generation quality. GAN on the other hand is flexible in generating any desired structure since it depends on minmax game theory using two deep CNNs which are called the discriminator and generator NNs [Goodfellow et al., Adv Neural Inf Process Syst, 2014]. Both networks, also referred to as “agents”, compete during training and the loss functions are optimized in an adversarial way. Such a framework overcomes the gradient approximations of the aforementioned methods and results in a powerful generator that will always be guided by the discriminator NN gradient updates.

GAN is challenging to train and stabilize and requires various improvements to achieve rapid training convergence and high-fidelity microstructure generation. Another variant of the GAN is the Wasserstein GAN (WGAN) [Arjovsky et al., International Conference on Machine Learning, 2017], which also consists of two deep CNNs called the critic and the generator, and operates in the same minmax setup during training. However, WGAN focuses on minimizing the earth mover (EM) distance between the actual and generated microstructures distributions. This can overcome some of the GAN training challenges as discussed herein. However, careful design of the DL networks, and selecting the training learning rates and balancing between the two CNNs during gradient updates are vital in achieving satisfactory results. FIG. 3 shows a schematic of the generative frameworks. Discussed herein are the two frameworks in detail which describe a systematic network design for generating periodic microstructures.

FIG. 3 is a schematic of exemplary microstructure generative frameworks.

Training of the GAN depends on optimizing the binary cross entropy [Yang et al., Journal of Mechanical Design, 2018] for both the discriminator and generator NNs, however this algorithm is sensitive to the network's design, and for certain distributions it can lead to saturation of the learning parameters (vanishing gradients) due to the logarithmic nature of the loss function. Loss function formulation based on EM distance is a more robust formulation where EM represents the minimum energy required to move the generated distribution to the actual distribution. Wasserstein distance used in WGAN is an approximation of EM [Gulrajani et al., Adv Neural Inf Process Syst, 2017]. The main drawback of the WGAN formulation is that the critic NN should satisfy 1-Lipschitz continuity for Wasserstein distance to be valid. In particular the critic NN should result in a function where the L2-norm of the function gradient with respect to any input image should not exceed one. This was addressed by Gulrajani et al. [Gulrajani et al., Adv Neural Inf Process Syst, 2017] through penalty regularization, where the deviation of the 1-Lipschitz continuity will increase a gradient regularization term and hence will penalize the loss function during training. This implicitly results in an optimized model that approximately satisfies the penalty constraint. In order to ensure that the constraint was applied to all real and generated microstructure spaces while maintaining computational efficiency, both real and generated images were merged through an interpolation function, and the gradient of the critic was computed with respect to the new interpolated images. The interpolated microstructure image \hat{X} was formulated as follows:

\hat{X}=X×∈+G(Z)×(I−∈) Equation 1
where X is the real microstructure tensor of images that has been drawn from the real microstructure space distribution (ρ_{X}), Z is a latent space vector resembling an input noise which follows a prior probability distribution (ρ_{Z}), ϵ is an interpolation coefficient tensor and I is an identity tensor. ϵ controls the contribution of the generated image to \hat{X}, as well as introduces noise into the real microstructure. It was selected to follow a uniform distribution [0,1], hence stochastic interpolated image was created during each training step. This provided wide space of images that approximately accommodate the microstructure spaces and maintain the validity of the Wasserstein distance computation. Although this approach avoids the computational expense of calculating the critic's gradients with respect to all images, it remains less efficient than traditional GAN. This inefficiency arose from the incorporation of first-order derivatives in the penalty term, and consequently results in second-order derivatives computations during loss function optimization.

Adversarial network design: The GAN framework comprises the following components: first, the discriminator NN, which includes five CNN layers with (2×2) strided convolutions, similar to the vanilla regression discussed previously. Batch normalization was directly applied to each CNN layer output to avoid internal covariate shift and speed up the convergence. Additionally, batch normalization acted as a regularization technique to avoid NNs overfitting. The nonlinear activation function was selected to be LeakyReLU [Dubey & Jain, Applications of Computing, Automation and Wireless Systems in Electrical Engineering, 2019] with negative slope coefficient set to 0.2. This allowed some negative values to be activated in the CNN layer that can also mitigate the vanishing gradients problem. Zero padding was applied during convolutions, so that the output of each CNN layer was exactly half the input size. The choice of convolutional setup along with sufficient number of kernels were critical in enhancing the capability of GAN in generating realistic structures. Additionally, a CNN layer was added with non-zero padding and a sigmoid activation function to predict a label in the range of zero and one given a discriminator input image. Meanwhile, WGAN's critic NN had a similar design to GAN's discriminator, however the last CNN layer had a linear activation function. Second, the GAN/WGAN generator NN was designed to be a mirror of the discriminator/critic NN [Hsu et al., JOM, 2021; Li et al., International Design Engineering Technical Conferences and Computers and Information in Engineering Conference, 2018], however the last generator layer was a CNN with softmax activation function to predict the probability of finding a certain microstructure phase such as matrix, fiber and porosity at each generated image pixel. The model was built using the same DL packages and GPU architecture mentioned previously.

The ground truth images for GAN/WGAN training were acquired using the synthetic microstructure generator, similar to vanilla regression training, where ~12,000 images were generated by varying the volume fractions, fiber radii and the spatial distribution of the microstructure phases. The stochastic parameters were chosen to cover the C/SiNC and SiC/SiNC microstructure spaces. The images were then one-hot encoded, where the matrix, fiber and porosity were encoded into a binary vector, such as for matrix the encoded vector is [1 0 0], fiber is [0 1 0], and porosity is [0 0 1]. The 2D image tensor was then expanded to 3D and each pixel was represented by the encoded vector instead of grayscale pixel values. After training, postprocessing was implemented to the predicted images where the phase with highest probability was set to one and others were set to zero to match the format of the input microstructure. This eliminates gradients in the generated image, which usually require human evaluation to remove any pixel outliers and preserve the microstructure coherency. Finally, for visualization, the generated images were decoded to a grayscale format.

Network optimization: Mini-batch SGD algorithm was used to optimize both NNs, however the generator NN task is relatively complex compared to the discriminator/critic NN, since it aims to perform microstructure reconstruction given a random Z vector. Hence, careful balance between the NNs training was critical in converging to ρ_{X}, where custom optimization profile has to be defined for each NN. Adam optimizer with initial learning rate

$$( {l}_{D / c}^{0} )$$

of 10⁻⁴ and β₁ of 0.5 was used for the discriminator/critic training. However, to prevent it from overpowering the generator as training proceeds (i.e., discriminator/critic is too powerful for the generator to compete in minmax setup), an exponential decay to the learning rate was applied to the discriminator/critic's optimizer as follows:

$${l}_{D / c}^{d e c a y} = {l}_{D / c}^{0} \times {k}_{d}^{⌊ \frac{s}{b \times {d}_{i}} ⌋} \qquad Equation 2$$

where

$${l}_{D / c}^{decay}$$

is the updated discriminator/critic learning rate, └·┘ is the floor operator, k_{d} is the decay coefficient, s is the training step, b is the number of mini-batches, and dᵢ is the decay interval. This resulted in a stepwise decay in the learning rate that was updated after every dᵢ. The generator's optimizer, on the other hand, was Adam optimizer with initial learning rate

$$( {l}_{G}^{0} )$$

of 10⁻³ and β₁ of 0.5. The higher initial learning rate for the generator allowed it to further keep up with the discriminator/critic especially during the early GAN/WGAN training stages. In addition to configuring the optimizer profiler, the training frequency of the generator was regulated. Initially, both NNs received equal training; however, after a predefined number of s training steps, the frequency at which the generator was trained was incremented by threefold that of the discriminator/critic for an additional s steps. These adjustments were maintained throughout the entirety of the training process (epochs), ensuring that the generator receives frequent updates, particularly when it encounters local minima. This strategy aided in preserving the dynamics of gradient updates. The determination of the generator training frequency was a critical hyperparameter and based on empirical assessment of training performance, specifically it depended on the quality of the generated images and the performance on the loss function evaluation.

Periodic boundary conditions: Enforcement of geometric PBCs in the generated microstructures was achieved through a CP algorithm in both vertical and horizontal directions as follows:

$${X}^{P} ( i , j ) = \{ \begin{matrix}X ( H , j ) ; i = 1 \\ X ( 1 , j ) ; i = H \\ X ( i , W ) ; j = 1 \\ X ( i , 1 ) ; j = W \\ X ( i , j ) ; otherwise\end{matrix} \qquad Equation 3$$

where X^{P} is the padded microstructure tensor, i and j represent the indexes of the height (H) and width (W) of the image pixels respectively (i.e., H is the last pixel row, and W is the last pixel column). The operations essentially move the last row to the top and vice versa, maintaining vertical continuity, while moving the last column to the left and vice versa, maintaining horizontal continuity. Consequently, CP simulates a wrap-around effect at the tensor edges while maintaining the overall image tensor size. The series of operations were implemented in a custom non-trainable layer in the generator NN which was placed right after the first CNN layer, preceding both batch normalization and activation function operations. The layer was also placed following the final CNN layer and prior to the softmax activation. This configuration aims to encourage the generator NN to capture the microstructure features while being constrained by edges continuity. Note that adding CP layer after every CNN layer will hinder the generator capability of learning the actual microstructure features and will be more focused on the boundary effects, hence the design choice of adding CP at the start and end of the deep NN was proven to be sufficient as discussed further herein. Gayon-Lombardo et al. [Gayon-Lombardo et al., NPJ Comput Mater, 2020] have briefly discussed CP, however it was being added to the generator upon training, and this tends to distort the relative distribution of the microstructure features, as well as it does not perfectly guarantee the periodicity in complex structures.

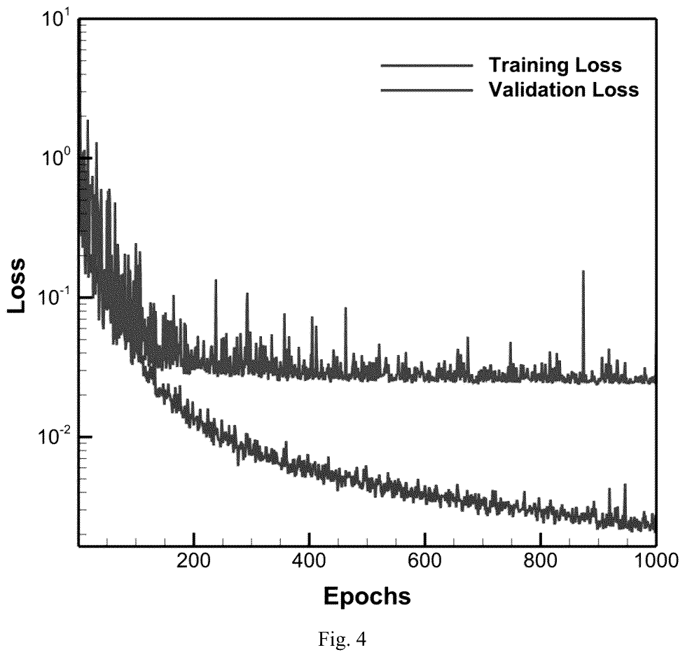

Generated microstructure analysis: Microstructure variability assessment: The vanilla regression network presented herein was trained on 2,800 and validated on 700 synthetic microstructure images. FIG. 4 shows the MSE training and validation loss with training steps (epochs), where the training loss decreases monotonically with small perturbations due to the mini-batch SGD-based optimizer. The validation loss decreases monotonically up to 200 epochs and then experiences minor variations around 0.6. Due to the stochastic nature of the training, spikes in validation loss occur at different intervals until it saturates, indicating that there was no sign of overfitting. After training, the model was scaled back using the standard normal distribution statistics stored before the training starts, so that V_{f} and porosity are predicted in their original scale.

FIG. 4 is a plot showing vanilla regression loss variation with training steps (epochs).

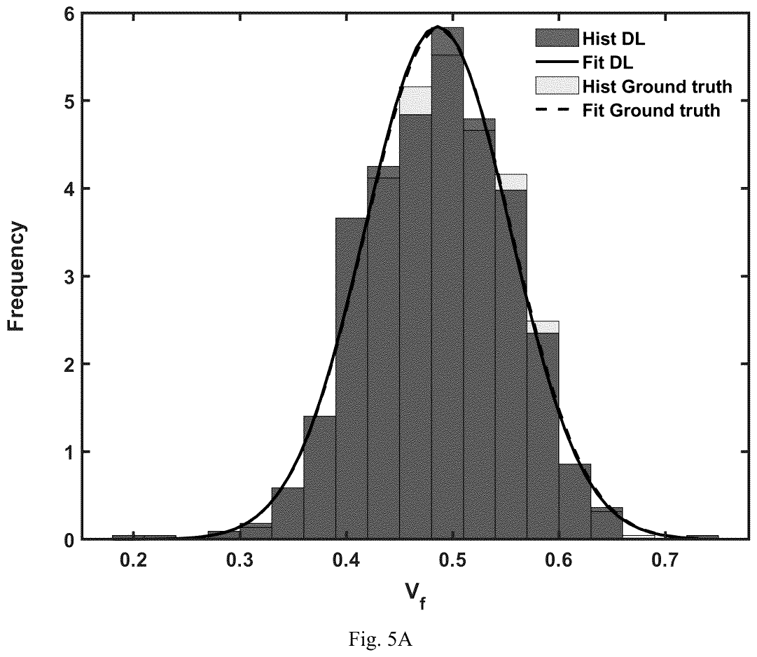

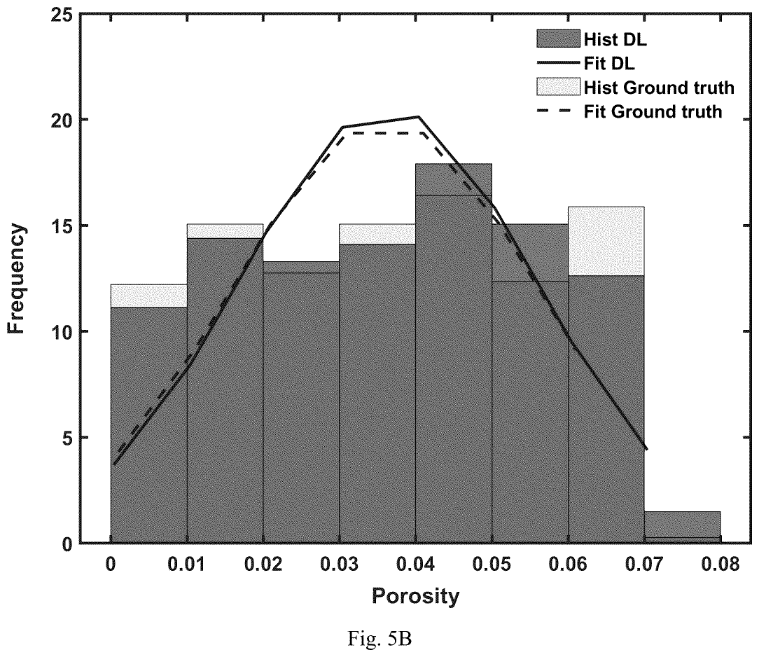

The optimized vanilla regression model was applied on a pool of synthetic images test data (700 images, same size as the validation dataset) where the model had not been trained on before. The ground truth of both V_{f} and porosity were plotted against the vanilla regression predictions as shown in FIG. 5A and FIG. 5B. The histograms and the normal fit of the predictions and ground truth data show good agreement across various microstructures which represent the C/SiNC and SiC/SiNC possible microstructure features distributions. Further model assessment was achieved through computing the coefficient of determination (R²) for each predicted feature as follows:

$${R}^{2} = 1 - \frac{{\sum }_{i = 1}^{n} {( {y}_{i} - {\hat{y}}_{i} )}^{2}}{{\sum }_{i = 1}^{n} {( {y}_{i} - \overline{y} )}^{2}} \qquad Equation 4$$

where i is the index of each model prediction, n is the total number of predictions, yᵢ and ŷᵢ are the ground truth and predicted values respectively, and y̅ is the mean of the ground truth values. As R² increases, this indicates a strong correlation between the ground truth and model predicted values. R² equals to ~0.98 for V_{f}, and equals to ~0.95 for porosity predictions. Hence, the disclosed model can accurately map the tested input microstructures to the microstructure property of interest. Note that enhancement can be made to the model so that the total training loss converges to the validation loss, however based on the predicted probability distributions, as shown in FIG. 5A and FIG. 5B and the R² values for each predicted feature, there was no need for further reduction of the validation loss. Additionally, the model was designed to be evaluated on real CMC microstructures, hence a degree of mismatch in the predictions with respect to the ground truth synthetic images was maintained for model generalization.

FIGS. 5A & FIG. 5B are a set of plots showing Vanilla regression (Deep Learning) predictions on synthetic microstructures for (FIG. 5A) fiber volume fraction (V_{f}), and (FIG. 5B) porosity

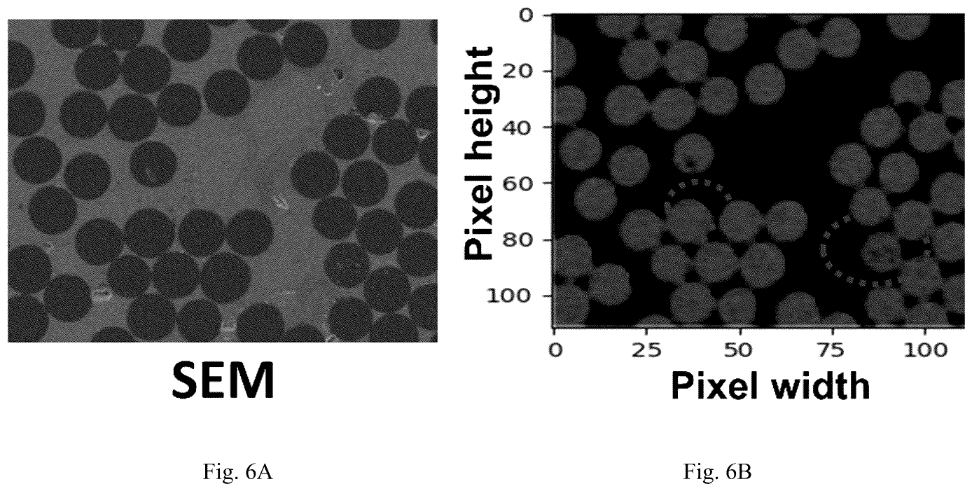

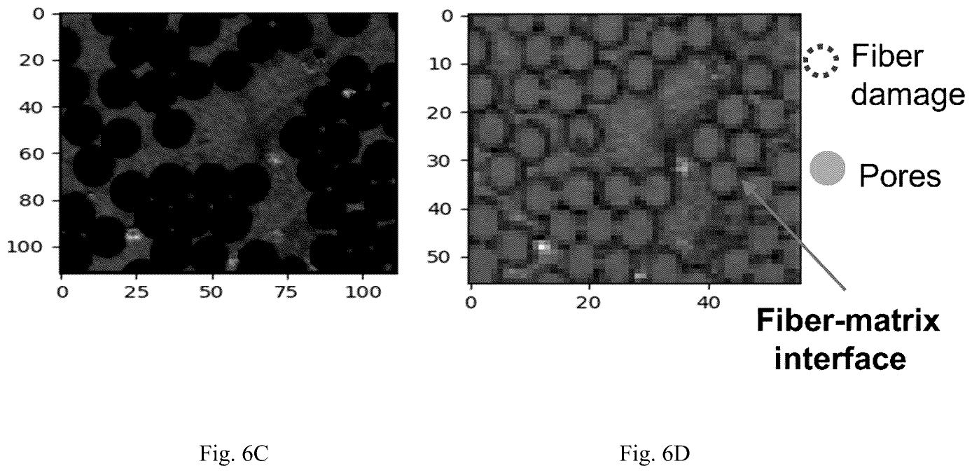

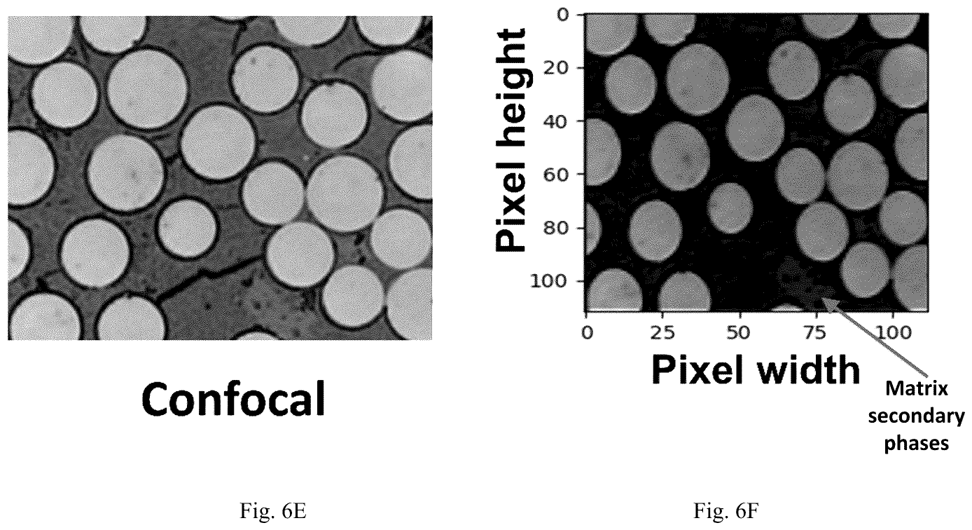

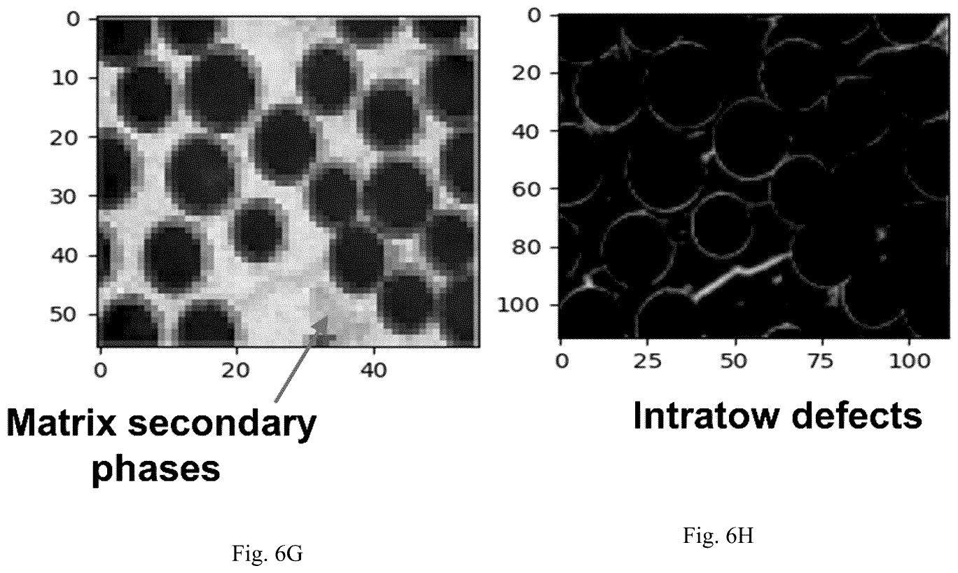

The model was now tested and validated on real CMCs microstructures. The studied C/SiNC and SiC/SiNC CMCs were manufactured using polymer infiltration and pyrolysis (PIP) technique [Bhatt & Kiser, J Eur Ceram Soc, 2021], where a preceramic polymer was converted to crystalline SiC matrix which has significant microcracks and porosity due to volume shrinkage. These defects must be characterized and included in the generated SRVEs for high-fidelity micromechanics simulations. Sample preparation, polishing and microscopy were performed to obtain high quality real micrographs. Thereafter, the images were sliced into 224×224 sub-images and converted to grayscale to match the input image tensor requirement of the vanilla regression model. CAMs were extracted from the first CNN layer during testing which act as sematic segmentation of the different microstructure phases as shown in FIG. 6A through FIG. 6F. First, the method was tested on C/SiNC CMCs. As shown in FIG. 6B, the model captures fiber distribution and manufacturing induced damage observed in C/SiNC SEM micrograph. The porosity phase and the fiber/porosity relative distribution within the intra-tow region were also captured, as shown in FIG. 6C. The porosity in C/SiNC can be further induced around the fiber during manufacturing due to mechanical properties and structural mismatch between T300 C fiber and the SiNC matrix [Halbig et al., Journal of the American Ceramic Society, 2008; Dang et al., J Eur Ceram Soc, 2024]. As shown in FIG. 6D the fiber/matrix interface, which is pyrolytic carbon, is also highlighted. The vanilla regression was then tested on SiC/SiNC confocal micrographs, and the results are shown in FIG. 6F and FIG. 6G. As seen in these figures, the matrix, fibers and their interface, as well as the secondary phases of the SiNC matrix were characterized. The segmented interface is boron nitride, which was used as fiber coating in high-temperature CMCs [Parthasarathy et al., Journal of the American Ceramic Society, 2018]. FIG. 6H shows the intra-tow defects including porosity distributed around the Hi-Nicalon™ fibers and matrix microcracks resulted from PIP process.

FIG. 6A through FIG. 6H are a series of images showing class activation maps (CAMs) prediction of vanilla regression tested on real C/SiNC and SiC/SiNC micrographs. FIG. 6A is an S400N C/SiNC SEM intra-tow micrograph. FIG. 6B is an image of a kernel capturing C/SiNC matrix, fiber and fiber damage. FIG. 6C is an image of a kernel capturing C/SiNC porosity at different fiber-matrix interface locations. FIG. 6D is an image of a kernel highlighting C/SiNC fiber-matrix interface. FIG. 6E is an S200H SiC/SiNC confocal micrograph. FIG. 6F and FIG. 6G are images showing kernels capturing SiC/SiNC fiber, matrix, matrix secondary phases and fiber-matrix interface. FIG. 6H is an image of kernels focusing on porosity at fiber interface as well as matrix microcrack.

The accuracy of the vanilla regression network in predicting the fiber and porosity volume fractions, as seen on the actual CMC micrographs, was investigated. As mentioned previously, the vanilla regression NN has a fixed input micrograph size of 224×224-pixel size, going beyond that size may result in computationally infeasible NN training. The CMC micrographs were sliced to match the vanilla regression input size. Slicing all the micrographs to 224×224 sub-images for testing had some challenges; some of the sliced micrographs may not be representative of the microstructure distribution such as slices that barely have any fiber distribution or slices zoomed-in on the matrix microcracking. Hence, the overall micrographs were compressed and resized to the vanilla regression input size for testing. The average C/SiNC and SiC/SiNC V_{f} was predicted as 0.52 (±0.04), while porosity is 0.042 (±0.013). These predictions agreed with the evaluation range reported in the literature for the investigated CMCs [Khafagy et al., J Compos Mater, 2021]. Note that, although the main segmented phases included in the ground truth training data were fiber, matrix, and porosity, CAMs learn to segment other unique microstructure features (i.e., fiber/matrix interface, and matrix microcracks) through its learnable kernels. This is a major advantage of using DL-based algorithms compared to traditional image segmentation methods. Hence, the representative sliced images were useful in classifying the different phases and defects using CAMs, while the overall micrographs can be used for quantifying the properties of interest.

Several studies [Drugan & Willis, J Mech Phys Solids, 1996; Heinrich et al., Model Simul Mat Sci Eng, 2012] have been conducted to compute the minimum size of the RVE which depicts the image slice size, based on V_{f}, as well as the elastic and thermal properties. Sanei et al. [Sanei & Fertig, Compos Sci Technol, 2015]proposed an uncorrelated volume element (UVE) extraction algorithm, where the adjacent microstructure slices are uncorrelated in terms of V_{f} and it eliminates the necessity of taking the covariance of adjacent microstructures into account. The developed vanilla regression can be used to evaluate the microstructure features generated using the different RVE extraction techniques. The methodology can also aid in the development and enhancement of UVE for different material systems since UVE algorithms rely on microstructure features evaluations.

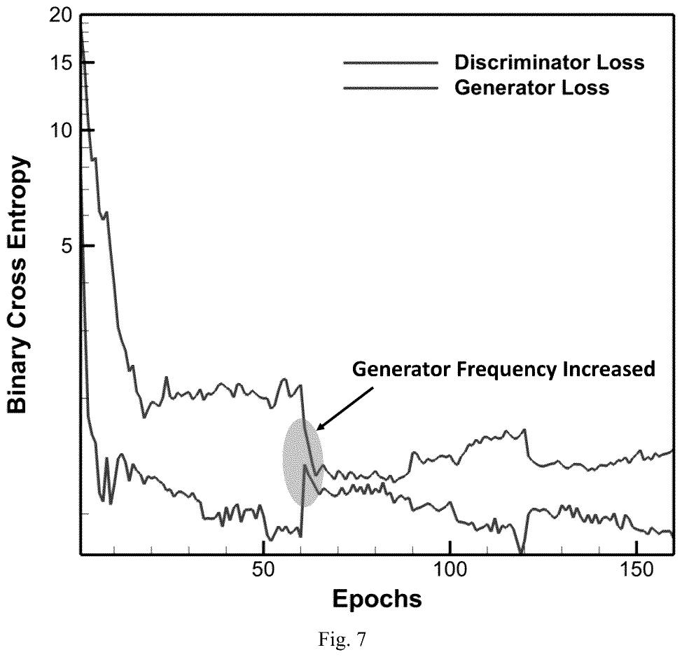

Microstructure reconstruction: The designed GAN model presented herein was trained on stochastic synthetic microstructures and the binary cross entropy loss function for discriminator and generator was minimized as shown in FIG. 7. Initially, the loss functions have rapid monotonic decrease indicating significant enhancement in the generated microstructures quality in the first few learning steps. As training proceeds, the discriminator loss function continues to drop while the generator loss function has minor increase and then saturates till 60 epochs. This can be interpreted by the fact that generator NN is more complex to train since it maps a pure Gaussian noise to a microstructure space and it tends to be trapped in an early local minimum. The discriminator in this designed network was overperforming compared to the generator NN and the generator cannot compete with the discriminator learning progress, leading to vanishing gradients of the generator learnable parameters (θ_{G}). Hence, at this point the generator training frequency was tripled, whereas for every discriminator training step, the generator is trained three times. This leads to a sudden drop in the generator loss function, and consequently an increase in the discriminator loss. This change in training dynamics guides the generator towards another local minimum where it can benefit from updating the θ_{G} gradients. Both networks continued to be trained and their loss functions were closely matched. Upon further training, the generator NN cannot keep up with the discriminator NN training enhancements, where the generator loss diverges and the discriminator loss continues to monotonically decrease. After an additional 60 epochs, the generator training frequency was increased again, reaching six times the initial frequency, and this resulted in another training dynamics change where the losses start to converge. However, the second update in the training dynamics did not result in significant training improvement, where after 20 epochs the losses started to diverge again, and hence the training was halted.

FIG. 7 is a plot showing discriminator and generator loss function variation with GAN training steps (epochs).

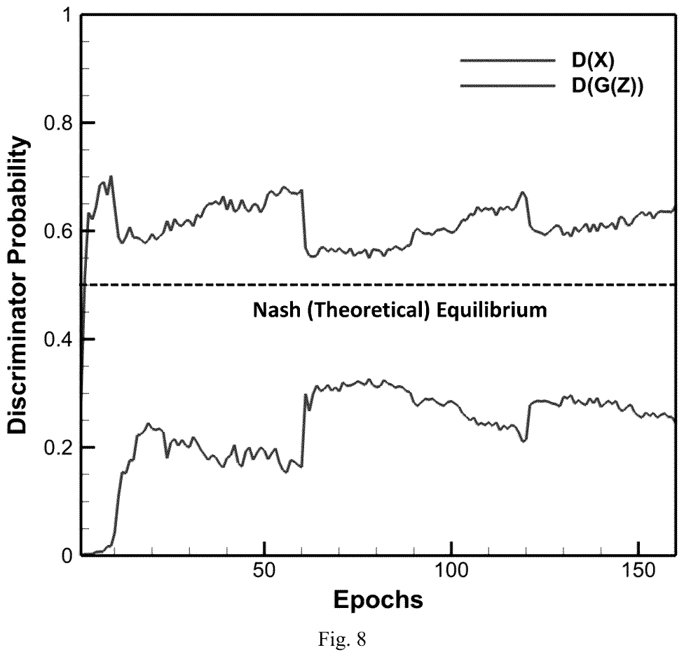

To interpret the loss functions variations and its impact on the generated microstructures convergence, the average discriminator probabilities on real and generated microstructures denoted as D(X), and D(G(Z)) respectively, during GAN training is plotted in FIG. 8. The results show similar trend to the binary cross entropy variations during training, where during the early training stages, the discriminator probabilities were low depicting an under-trained discriminator. It was crucial to correlate the loss functions evaluations with the average discriminator probabilities during training, since unlike traditional regression and classification models, the loss function itself does not give full insights about the evolution of the generated images quality. For example, as shown in FIG. 7 and FIG. 8, similar discriminator losses at different stages during training do not necessarily mean that the discriminator probabilities will be equal. This was attributed to the adversarial nature of the training algorithm and the frequent changes in the discriminator and generator NN local minima during training. The optimum generator state occurs in the interval between 60 and 90 training seps where the discriminator probabilities are the closest to the Nash equilibrium [Goodfellow et al., Commun ACM, 2020]. This equilibrium state is the theoretical convergence of GANs where the discriminator probabilities on real and generated microstructures are equal 0.5. This means that the discriminator cannot distinguish between the two microstructures and theoretical convergence occurs. However, in practice all the GANs model design focuses on converging to the Nash equilibrium as close as possible.

FIG. 8 is a plot showing average discriminator probabilities on real and generated microstructures, denoted as D(X) and D(G(Z)), respectively, with GAN training steps (epochs).

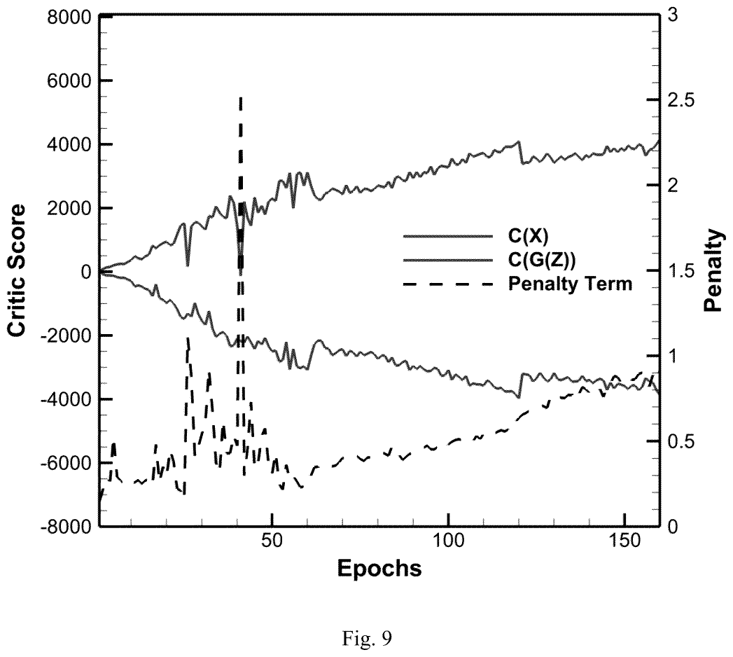

The designed WGAN model presented above was trained similar to GAN training, where the average critic scores on real and generated microstructures, denoted as C(X) and C(G(Z)) respectively, as well as the gradient penalty (GP) term are shown in FIG. 9. Initially the critic scores are zero for both microstructures (note that initially the generated microstructure was just pure noise), thereafter the critic score increases monotonically for the real microstructures and decreases for the generated microstructure. At 40 epochs, the critic score suddenly drops due to the overshooting of the GP term; however, the critic NN rapidly recovers bringing the penalty term within the 1-Lipschitz continuity constraint. This shows the effectiveness of the implemented GP regularization and interpolation algorithms discussed previously. Similar to GAN, at 60 epochs the generator training frequency was updated and caused slight changes to the critic scores. Unlike GAN, WGAN was insensitive to generator training dynamics updates. Upon the frequency changes, the critic scores for the generated images rapidly dropped without few steps of saturation, which is another discrepancy in the behavior of the two tested adversarial networks. The training was halted at 160 epochs where there were no significant changes in the generated image quality and at that point the 1-Lipschitz continuity constraint was diverging which will make the Wasserstein distance approximation invalid.

FIG. 9 is a plot showing average critic scores on real and generated microstructures, denoted as C(X) and C(G(Z)), respectively, as well as the GP term, with WGAN training steps (epochs).

Evaluating the generative capability of GAN/WGAN involved assessing its diversity and realism. This evaluation was facilitated by calculating the Inception Score (IS) [Salimans et al., Adv Neural Inf Process Syst, 2016]. The determination of this metric leveraged a pre-trained Inception v3 model [Szegedy et al., Proceedings of the IEEE Conference on Computer Vision and Pattern Recognition, 2016], a deep CNN model trained on the ImageNet dataset [Deng et al., IEEE, 2009] for image classification. The IS was computed as follows:

IS= [symbol] Equation 5

where KL is the Kullback-Leibler divergence between the conditional and marginal distributions denoted as P(y|G(Z)), and P(y) respectively, and y is the Inception model predicted class label. In this metric the variability across the microstructures was measured through P(y), where high variability across the microstructures results in P(y) following a uniform distribution, indicating a high entropy in the generated pool of images, meanwhile the realism of the microstructure was evaluated through P(y|G(Z)), where a microstructure with enough main features resulted in P(y|G(Z)) following a delta distribution (i.e., Dirac delta function), indicating a low entropy within the individual microstructure. The superposition of the calculated probabilities was represented in the exponential of the averaged KL across all the generated images, and a high IS implied that both diversity and realism were maintained. P(y|G(Z)) was determined as the predicted output of the Inception model, while P(y) is computed through averaging the conditional distribution over all the generated images.

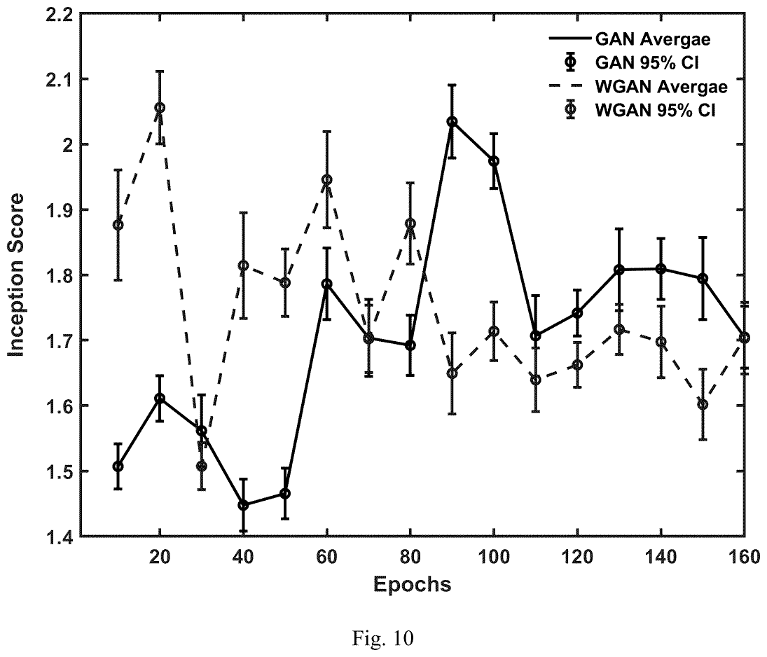

The evolution of IS during GAN/WGAN training within 95% confidence interval (CI) is shown in FIG. 10. For reliable IS computation, 5,000 images were generated at each selected training step. The results show that initially GAN was having low IS and improves with training, while it reaches the peak IS within the optimum generator interval depicted in FIG. 7 and FIG. 8, thereafter it drops as the discriminator and generator diverges. On the other hand, WGAN shows high IS in the early stages of training and it rapidly drops as training proceeds. Another IS peak was observed in WGAN after the increase in the generator frequency and then dropped as the critic and generator diverged. The anomalous IS behavior of WGAN highlights the limitation of depending on this metric in assessing the image generation quality. Even though there is high IS at the early WGAN training stages, the generated images were dominated by the Z vector (i.e., noise), and the generator distribution was far from the actual microstructure distribution. However, high IS values at the late training stages were more reliable since it guarantees generation diversity, realism and quality. The reason that WGAN showed a false positive IS at the early training stages was due to the nature of the critic output predictions, where usually WGAN does not suffer from vanishing gradients and the training parameters were having more likelihood to be updated rather than saturating. Hence, WGAN was able to reach more defined and diverse microstructures at the early stages even though its generation quality is far from the actual microstructures, while GAN output was mostly noise during the early training stages. Based on the discussions provided, evaluating the loss function, discriminator/critic predicted output and the IS were all required to reliably assess the generative networks performance.

FIG. 10 is a plot showing inception score (IS) variation at 95% confidence interval (CI) with GAN/WGAN training steps (epochs).

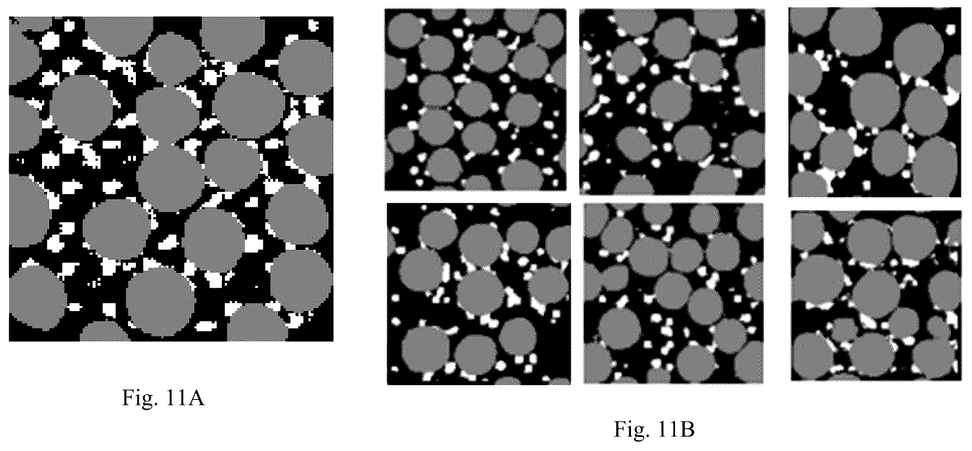

Based on the results of GAN and WGAN evaluation, the final output microstructures were generated at 90 epochs and 80 epochs for GAN and WGAN respectively. FIG. 11A and FIG. 11B show the generated microstructure in grayscale obtained from GAN's generator showing well-defined microstructure with the three main phases that were studied. FIG. 11A shows the non-periodic microstructure in high resolution where CP was dropped in the generator layers during GAN training, while FIG. 11B shows a sample of generated microstructures satisfying geometric PBC, obtained from the trained generator with CP, as discussed herein. The periodic SRVEs ensure the invoking of the ergodic hypothesis, where there was a continuity of the fibers along the edges of the SRVEs. The results indicate that implementation of the CP algorithm described in Eq. 3, within the generator layers, indeed allowed the model to learn the microstructure features while maintaining periodicity along the edges. GAN and WGAN produced microstructures of similar qualities, however since the IS showed higher diversity and realism in the GAN generated microstructures compared to WGAN; therefore, the former was used in the computation of homogenized mechanical properties and the analysis of time-dependent responses discussed herein.

FIG. 11A and FIG. 11B are a series of images showing generated microstructures using GAN for (FIG. 11A) non-periodic structure, (FIG. 111B) sample of periodic structure.

To couple the vanilla regression variability quantification results with the GAN generated microstructures, postprocessing was applied to a pool of generated structures to consider only the microstructures that satisfy the C/SiNC and SiC/SiNC V_{f} and porosity range. Additionally, since the generated microstructures are in 2D format, postprocessing was applied to expand the matrix and fiber phases to 3D, hence forming a unidirectional CMC SRVE. Even though the studied CMCs were in woven configuration at the mesoscale, the micromechanics simulations in this work focused on the intra-tow SRVEs where constitutive models to capture the fundamental deformation mechanisms were usually applied as shown by Liu et al. [Liu et al., J Aerosp Eng, 2011]. Regarding porosity distribution in the expanded SRVE, each porosity pixel value of the generated microstructure image was expanded with a specified thickness depending on the overall SRVE size, and regular spacing was maintained between porosity along the fiber direction. This assumption was based on observations from the micrographs and vanilla regression segmentation results that show dominance of porosity along the fiber direction. The methodology results in a 3D SRVE which takes into account the stochastic distributions of the intra-tow fiber and porosity volume fractions. FIG. 11A and FIG. 11B show the in-plane SRVEs sections comprising the three phases, fiber, matrix, and porosity. Further model enhancement can be made through training GAN/WGAN on actual microstructure images, since this removes the need for implementing output constraints based on regression predictions. Additionally, this method facilitates the inclusion of complex features like fiber packing. However, the detailed study provides a modular framework which can operate on different sources of microstructure images as well as different composite material systems.

Micromechanics analysis: Iterative HFGMC formulation: Micromechanics methods such as the generalized method of cells (GMC) and the multiscale GMC (MSGMC) employ a first order subcell displacement field; as a result, subcell stress and thermal gradients across the fiber/matrix interface and stress concentrations due to defects and geometric inhomogeneity cannot be captured [Aboudi et al., Micromechanics of Composite Materials, 2013]. The HFGMC micromechanics theory employs a second order subcell displacement field accounting for normal-shear coupling and resulting in linearly varying stress, strain, and temperature fields at the subcell level [Bansal & Pindera, 2004]. However, HFGMC is inherently a strain-controlled solver, therefore, a novel iterative numerical algorithm was developed to modify an in-house computationally efficient HFGMC solver [Balusu et al., Comput Mater Sci, 2021] to a stress-controlled solver, to enable creep and creep-fatigue simulations. The time-dependent response was analyzed using the modified solver and a time-hardening creep law. HFGMC is based on finite volume discretization where the material was represented by a triply periodic SRVE and discretized into cuboid-shaped volumes called subcells, where each subcell represents a material phase (matrix, fiber and porosity). Each subcell was assigned an index α, β, γ, where each index is in range of one to the total number of subcells in the global orthogonal directions y₁, y₂, and y₃ directions, denoted as N_{α}, N_{β}, and N_{γ} respectively. Analogous to finite element analysis, HFGMC was solved using an assembled system of algebraic equations and can be represented as:

KŪ=F Equation 6
where K is the structural stiffness matrix containing information on the geometry and the mechanical properties within the individual subcells, Ū is the structural surface-averaged displacements vector, and F is the structural force vector containing information on the thermomechanical properties of each subcell, as well as the applied far-field strain field (ε̅ᵢⱼ). K is formulated by assembling the local stiffness matrix (k^{(α,β,γ)}), which is an 18×18 symmetric matrix. Similarly, F is formulated through assembling the local 18×1 force vector (f^{(α,β,γ)}). Due to the applied displacement and traction continuity at the subcell surfaces, the assembly results in nine unknown surface-averaged displacements for each subcell [Balusu et al., Comput Mater Sci, 2021].

The effective composite elastic stiffness (C*) was determined using Eq. 7, where C^{(α,β,γ)} is the subcell stiffness matrix, and A^{M(α,β,γ)} is the mechanical strain concentration matrix which represents the mapping between ε̅ᵢⱼ and the local subcell strains

$${ε}_{i j}^{( α , β , γ )}$$

[Aboudi et al., Micromechanics of Composite Materials, 2013; Aboudi et al., Practical Micromechanics of Composite Materials, 2021]. H₁, H₂, and H₃ are the total SRVE dimensions along y₁, y₂, and y₃ directions, and h_{α}, h_{β}, and h_{γ} correspond to the mesh size along the subcell local coordinates. In order to compute the A^{M(α,β,γ)} components, first, a unit far-field strain ε̅₁₁ was applied, while setting the other strain components to zero. Then the system of equations (Eq. 6) was solved to compute the corresponding local subcell strains

$${ε}_{i j}^{( α , β , γ )} ,$$

which represent the first column of A^{M(α,β,γ)}. Similarly, unit far-field strains were applied to the other normal and shear directions sequentially to compute the full A^{M(α,β,γ)} components.

$${C}^{*} = \frac{1}{{H}_{1} {H}_{2} {H}_{3}} {\sum }_{α = 1}^{{N}_{α}} {\sum }_{β = 1}^{{N}_{β}} {\sum }_{γ = 1}^{{N}_{γ}} {h}_{α} {h}_{β} {h}_{γ} {C}^{( α , β , γ )} {A}^{M ( α , β , γ )} \qquad Equation 7$$

The HFGMC solver was modified to solve a stress-controlled problem to model creep instead of modeling strain-controlled problems such as quasistatic uniaxial and stress relaxation tests. First, C* was computed using Eq. 7, and then the incremental far-field strain (Δε^{app}) that is equivalent to the far-field applied stress (σ^{app}) is computed as follows:

$$Δ {ε}^{app} = S ( {σ}^{a p p} - {σ}_{C}^{t} ) \qquad Equation 8$$

where S is the effective compliance matrix of the composite,

$${σ}_{C}^{t}$$

is the homogenized far-field stress at time t. Thereafter, the incremental far-field strain was used to compute the inelastic creep strain

$$( {ε}_{i j}^{cr} )$$

and the Cauchy stress of each phase (σᵢⱼ). The structural force vector (F) was modified to include the inelastic deformation as follows:

$$Equation 9.1$$

$${F}_{1}^{( α , β , γ ) , 1} = {\sum }_{j = 1}^{3} ( {C}_{1 j}^{( α , β , γ ) +} - {C}_{1 j}^{( α , β , γ )} ) ( Δ {ε}_{j}^{e , ( α , β , γ ) +} - Δ {ε}_{j}^{e , ( α , β , γ )} )$$

$$Equation 9.2$$

$${F}_{2}^{( α , β , γ ) , 1} = 2 ( {C}_{66}^{( α , β , γ ) +} - {C}_{66}^{( α , β , γ )} ) ( Δ {ε}_{6}^{e , ( α , β , γ ) +} - Δ {ε}_{6}^{e , ( α , β , γ )} )$$

$$Equation 9.3$$

$${F}_{3}^{( α , β , γ ) , 1} = 2 ( {C}_{55}^{( α , β , γ ) +} - {C}_{55}^{( α , β , γ )} ) ( Δ {ε}_{5}^{e , ( α , β , γ ) +} - Δ {ε}_{5}^{e , ( α , β , γ )} )$$

$$Δ {ε}_{i}^{e , ( α , β , γ ) ( \pm )} = Δ {ε}_{i}^{( α , β , γ ) ( \pm )} - Δ {ε}_{i}^{c r , ( α , β , γ ) ( \pm )} \qquad Equation 9.4$$

where

$${F}_{1}^{( α , β , γ ) , 1} , {F}_{2}^{( α , β , γ ) , 1} , and {F}_{3}^{( α , β , γ ) , 1} )$$

represent the subcell structural force vector components at the first subcell surface along y1, y2, and y3 directions, respectively. C^{(α,β,γ)+} denotes the stiffness matrix of the neighboring subcell. Δε^{(α,β,γ)} and Δε^{(α,β,γ)+} are the total incremental strains for the subcell and its neighboring subcell, respectively. Δε^{cr,(α,β,γ)} and Δε^{cr,(α,β,γ)+} refer to the creep incremental strains, while Δε^{e,(α,β,γ)} and Δε^{e(α,β,γ)+} refer to the elastic incremental strains for the subcell and its neighboring subcell, respectively. The notation (±) was used to indicate that Eq. 9.4 was applied to both the current subcell and its neighboring subcell. Voight notation was utilized for representing both the stiffness and strain tensors. The structural force vector components along the remaining two surfaces were defined similarly, considering the corresponding normal and shear strain components at the subcell level.

Thereafter, an iterative algorithm was used to get the incremental surface-averaged displacements as follows:

KΔŪ⁽¹⁾−ΔFⁱⁿ=R Equation 10.1

KΔŪ⁽²⁾=R;R>Tol Equation 10.2

ΔŪ=ΔŪ⁽¹⁾+ΔŪ⁽²⁾ Equation 10.3
where ΔŪ⁽¹⁾ is the initial incremental surface-averaged displacements, equating to trial displacements at the start of the simulation and to the previous step surface-averaged displacements at t≠0. ΔFⁱⁿ is the assembled incremental structural force vector that accounts for inelastic effects. R is the residual vector, and Tol is the iteration equilibrium tolerance vector. ΔŪ⁽²⁾ and ΔŪ are the incremental iteration step and updated surface averaged displacements, respectively.

After equilibrium convergence, the homogenized far-field stress at time t+1

$$( {σ}_{C}^{t + 1} )$$

was computed as follows:

$${σ}_{C}^{t + 1} = \frac{1}{{H}_{1} {H}_{2} {H}_{3}} {\sum }_{α = 1}^{{N}_{α}} {\sum }_{β = 1}^{{N}_{β}} {\sum }_{γ = 1}^{{N}_{γ}} {h}_{α} {h}_{β} {h}_{γ} {σ}^{( α , β , γ ) t + 1} \qquad Equation 11$$

where σ^{(α,β,γ)t+1} is the subcell Cauchy stress at time t+1. Finally, the incremental far-field applied stress Aa is computed as follows:

$$‖ Δσ ‖ = ‖ {σ}^{a p p} - {σ}_{C}^{t + 1} ‖ \qquad Equation 12.1$$

$${Δε}^{a p p} = S ( {σ}^{a p p} - {σ}_{C}^{t + 1} ) ; ‖ Δσ ‖ > {Tol}_{s t r e s s} \qquad Equation 12.2$$

where σ^{app} is the applied stress and Δε^{app} is the corresponding applied strain increment. The computed value of |Δσ| was compared against Tolₛₜᵣₑₛₛ for applied stress convergence check. The iterations were repeated till both equilibrium and stress convergence were satisfied, and hence this algorithm implicitly transforms the HFGMC solver to a stress-controlled regime. It should be noted that Eq. 6 can be reformulated to add an applied traction term in case an explicit stress-controlled solver is needed, this can be achieved through dropping the traction continuity condition at the SRVE boundaries, and reformulation of K and F is required.

The inelastic deformation was included in the reformulated HFGMC using a 3D orthotopic viscoplastic model developed by Khafagy et al. [Khafagy et al., Ceram Int, 2021], where its derivation depends on the Hill's orthotropic plastic potential f [Hill, Proc R Soc Lond A Math Phys Sci, 1948], and the Norton-Bailey creep power law with Arrhenius temperature dependence [Shimizu & Zhang, Proceedings American Society for Testing Materials, 1921]. The effective creep strain

$$( {ε}_{e}^{cr} )$$

for each microstructure phase (matrix/fiber) was given by:

$${ε}_{e}^{cr} = A {σ}_{e}^{n} {t}^{m} exp ( \frac{- Q}{k T} ) \qquad Equation 13$$

where A, n, and m are positive scalar model fitting parameters, t is the simulation time, Q is the creep activation energy, k is the Boltzmann's constant, T is the simulation temperature, and σₑ is the equivalent von Mises stress. The inelastic strain rate tensor

$$( {\dot{ε}}_{i j}^{cr} )$$

for each phase is obtained as follows:

$${\dot{ε}}_{i j}^{cr} = \dot{λ} \frac{\partial f}{\partial {σ}_{i j}} \qquad Equation 14.1$$

$$\dot{λ} = \sqrt{3} {\dot{ε}}_{e}^{cr} \qquad Equation 14.2$$

$${\dot{ε}}_{ij}^{cr} = \frac{3}{2} A {σ}_{e}^{n - 1} m {t}^{m - 1} d e v ( {σ}_{i j} ) exp ( \frac{- Q}{k T} ) \qquad Equation 14.3$$

where λ is the plastic multiplier, and dev(σᵢⱼ) is the deviatoric stress tensor. σᵢⱼ for each phase is then given by:

$${σ}_{ij} = {C}_{ijkl} ( {ε}_{kl} - {ε}_{kl}^{cr} ) \qquad Equation 15$$

where Cᵢⱼₖₗ is the stiffness matrix, and εₖₗ is the total mechanical strain of each phase.

Homogenized CMC mechanical properties: The developed GAN was used to generate 100 SRVEs, with orthogonal discretization of 128×128×10, and were implemented in micromechanics simulations using the HFGMC solver discussed previously. The domain size of the SRVE was 25 μm and that of the subcell is approximately 0.2 μm, which were determined after rigorous testing for convergence while maintaining computational feasibility. The homogenized elastic properties of C/SiNC and SiC/SiNC CMCs were quantified, where the effects of porosity on the longitudinal and transverse Young's modulus, denoted as E₁ and E₂ respectively, as well as the in-plane and out-of-plane shear modulus, denoted as G₂₃ and G₁₂, were investigated. The elastic material properties for the T300 C fiber, SiNC matrix and Hi-Nicalon™ fibers (SiC fibers) were obtained from literature as shown in Tables 1 & 2, v₂₃ and v₁₂ are the in-plane and out-of-plane Poisson's ratio respectively, E and v are the isotropic Young's modulus, and Poisson's ratio respectively.

TABLE 1
T300 C fiber elastic properties [Daniel et al.,
Engineering Mechanics of Composite Materials, 2006].

| E₁ (GPa) | E₂ (GPa) | ν₂₃ | ν₁₂ | G₁₂ (GPa) |
|---|---|---|---|---|
| 231 | 22 | 0.35 | 0.3 | 15 |

TABLE 2
SiNC matrix and Hi-Nicalon ™ fiber elastic properties
[Khafagy et al., Ceram Int, 2021].

| | E (GPa) | ν |
|---|---|---|
| SiNC matrix | 420 | 0.14 |
| Hi-Nicalon ™ fiber | 200 | 0.22 |

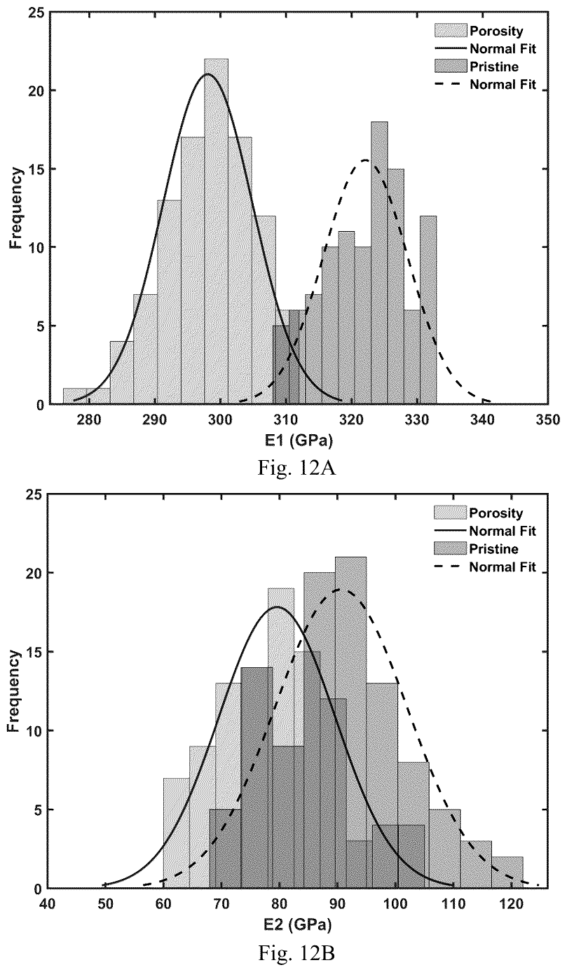

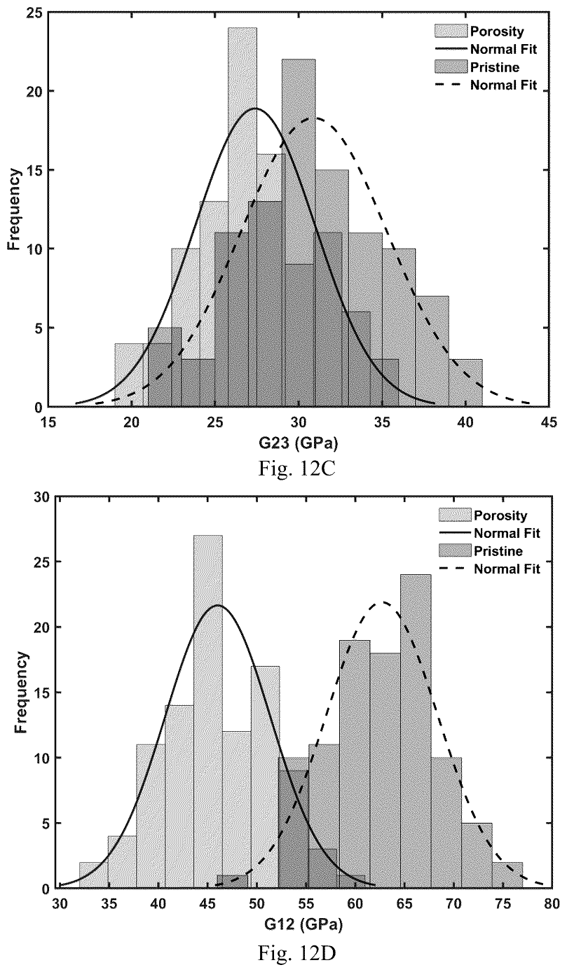

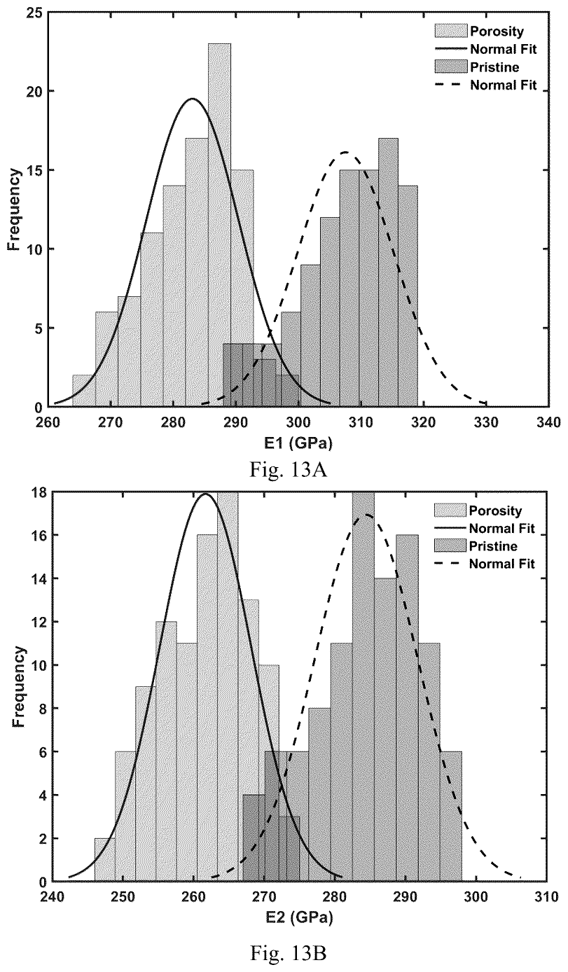

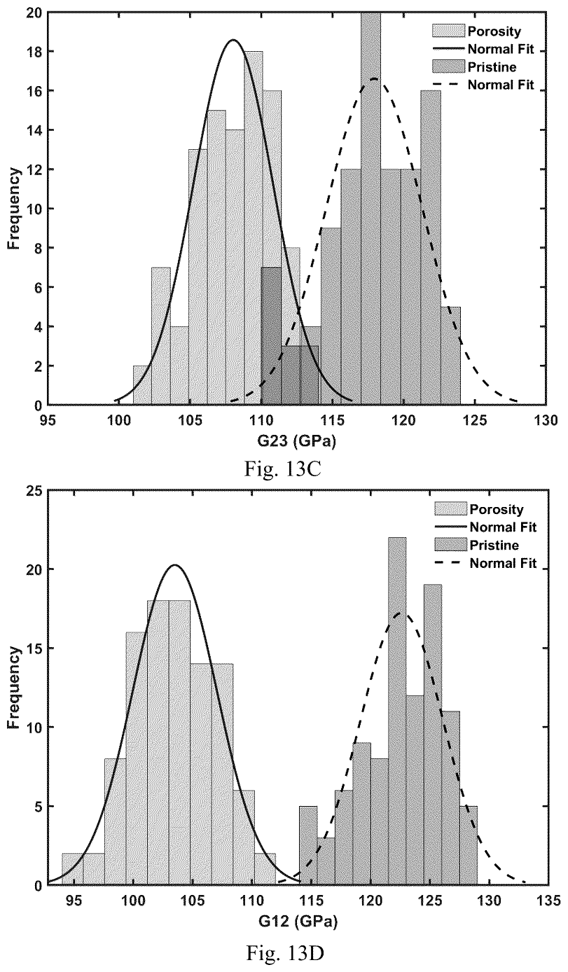

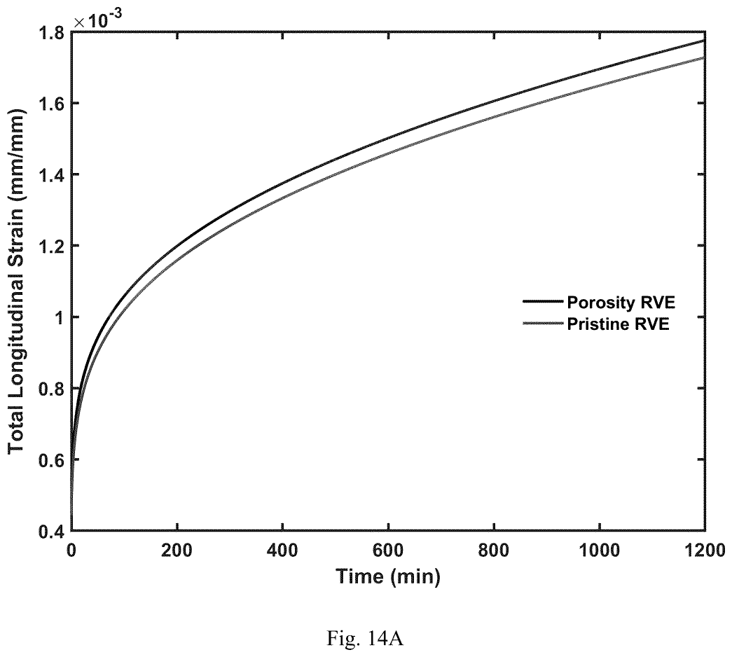

A parametric study on the effect of porosity on the homogenized elastic properties was conducted. The porosity phase was removed from the GAN generated SRVEs, which initially had three phases, to create baseline microstructures (porosity-free SRVEs) for comparison. SRVEs with various percentages of porosity were generated based on the statistical analysis presented herein, with minimum and maximum porosity percentages of 1.63% and 6.79%, respectively. FIG. 12A through FIG. 12D show the distribution of the elastic homogenized properties for baseline and porosity C/SiNC SRVEs. Significant reductions in the homogenized material properties were observed in the presence of porosity. The average longitudinal Young's modulus for the baseline SRVEs is 322 GPa and porosity results in 7.46% reduction. The average transverse Young's modulus is 90 GPa and its value reduces by 12.17% with porosity. Similarly, for the baseline SRVEs, the average in-plane and out-of-plane shear moduli were 30 GPa and 62 GPa respectively; the presence of porosity results in 11.38% and 26.6% reductions in these values, respectively. FIG. 13A through FIG. 13D shows the distribution of the elastic homogenized properties for baseline and porosity SiC/SiNC SRVEs. The average baseline longitudinal and transverse Young's modulus were 307 GPa and 284 GPa respectively, while porosity reduces the values by 8% for both moduli. The average baseline in-plane and out-of-plane shear moduli were 118 GPa and 122 GPa respectively, while porosity reduces the moduli values by 8.4% and 15.6% respectively. The results show that the transverse and out-of-plane properties were the most susceptible to degradation by porosity. These observations were consistent with the fact that the matrix carries most of the load, and the presence of porosity in the matrix phase significantly impairs the homogenized properties. The reductions were less significant in SiC/SiNC CMC due to the assumption of isotropy in the Hi-Nicalon™ fibers. These studies highlight the importance of accurately capturing the microstructural features for reliable estimation of CMC response.

FIG. 12A through FIG. 12D are a set of plots showing homogenized elastic properties for C fiber/SiNC matrix CMC for baseline (pristine) and porosity SRVEs; FIG. 12A is a plot showing longitudinal Young's modulus; FIG. 12B is a plot showing transverse Young's modulus; FIG. 12C is a plot showing in-plane shear modulus; FIG. 12D is a plot showing out-of-plane shear modulus.

FIG. 13A through FIG. 13D are a set of plots showing homogenized elastic properties for SiC fiber/SiNC matrix CMC for baseline (pristine) and porosity SRVEs; FIG. 13A is a plot showing longitudinal Young's modulus; FIG. 13B is a plot showing transverse Young's modulus; FIG. 13C is a plot showing in-plane shear modulus; FIG. 13D is a plot showing out-of-plane shear modulus.

SiC/SiNC time-dependent deformation: The time-dependent response of SiC/SiNC was investigated using the new iterative HFGMC solver for stress-controlled simulations coupled with the time-hardening viscoplastic model discussed herein. The creep model parameters (Eq. 14.3) for each constituent were obtained from literature and shown in Table 3. For computational feasibility, the SRVE which corresponds to the average elastic properties computed herein was selected and resized to 64×64×10. This corresponds to V_{f} of 51.66% and porosity of 2.64%. Consequently, for the same domain size mentioned previously, the SRVE subcell size was increased to approximately 0.4 m while ensuring the convergence of the inelastic response. The SRVE was subjected to in-plane creep conditions with stress free boundary conditions applied in all other directions. A parametric study was conducted to study the effect of porosity on the inelastic deformation. The creep simulations were conducted at 1200° C. with an applied stress of 134.4 MPa and total time of 20 hrs. The applied stress level represents 40% of the ultimate tensile strength (UTS) of the SiC/SiNC CMC, where the UTS at 1200° C. was computed through in-house uniaxial quasistatic tests with strain rate of 10⁻⁵/s.

TABLE 3
SiNC matrix and Hi-Nicalon ™ fiber creep model parameters
[Rugg et al., J Eur Ceram Soc, 1999].

| | A (min^{-m} Pa⁻ⁿ) | m | n | Q/k (K) |
|---|---|---|---|---|
| SiNC matrix | 2.33 × 10⁻¹⁷ | 0.49 | 1.9 | 9,607 |
| Hi-Nicalon ™ | 1.49 × 10⁻⁷ | 0.48 | 1.42 | 32,042 |
| fiber | | | | |

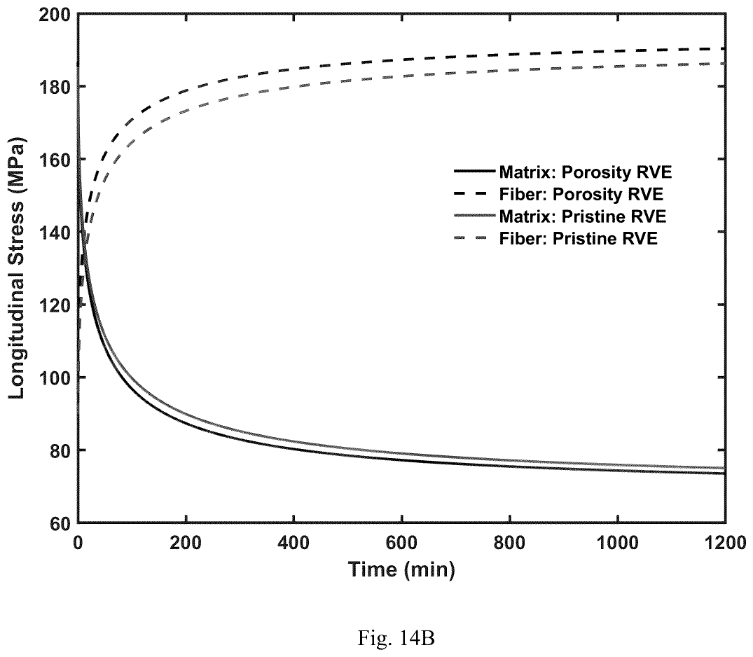

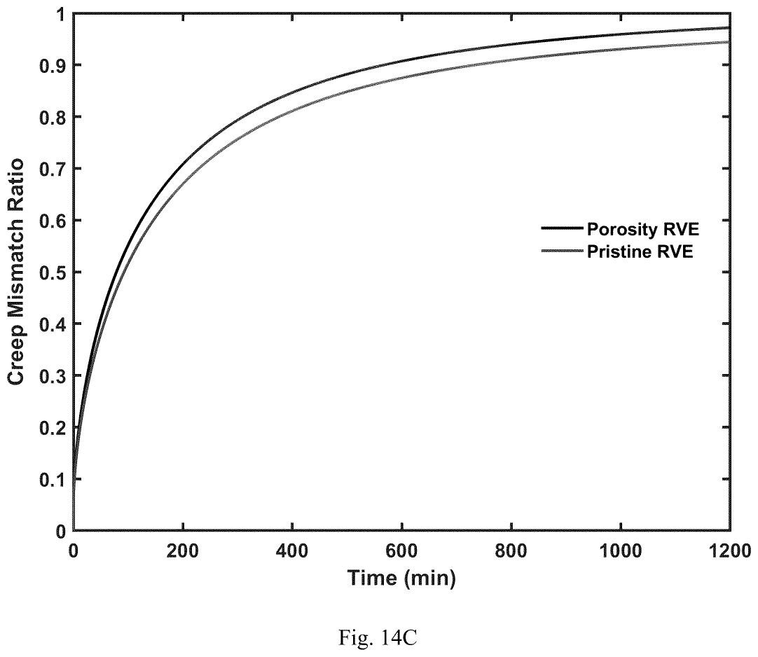

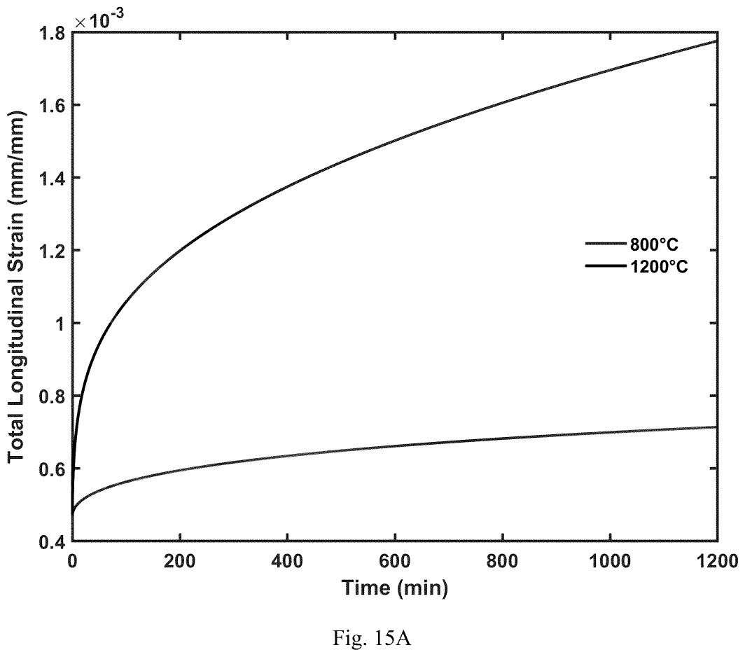

The simulations can capture the primary (Coble creep) and secondary (Nabarro-Herring creep) creep stages [Almansour & Morscher, J Eur Ceram Soc, 2020] as depicted in FIG. 14A. The Coble creep in Hi-Nicalon™ fiber was dominated by viscoelastic deformation of C at the grain boundaries (GBs), leading to GB sliding [Bodet et al., J Mater Sci, 1995; Sauder & Lamon, Journal of the American Ceramic Society, 2007]. Meanwhile, Nabarro-Herring creep was driven by impurities diffusion along the GBs which resulted in further GB sliding and lattice bulk diffusion [Sauder & Lamon, Journal of the American Ceramic Society, 2007; Lamon, International Materials Reviews, 2020]. As shown in FIG. 14B, load sharing occurred between the matrix and fiber as a result of the inelastic creep deformation, where the SiNC matrix relaxes, and sheds load to the fibers. In particular, this load sharing mechanism occurred due to the mismatch of the equivalent creep rates between the matrix and fiber, denoted as

$${\dot{ε}}_{e}^{cr / M} , and {\dot{ε}}_{e}^{cr / F}$$

respectively, where a creep mismatch ratio (CMR) coefficient was defined as

$$\frac{{\dot{ε}}_{e}^{c r / F}}{{\dot{ε}}_{e}^{c r / M}}$$

[Rugg et al., J Eur Ceram Soc, 1999]. In SiC/SiNC, the creep rate was higher in the matrix, resulting in CMR≤1 as shown in FIG. 14C. The constituents' longitudinal stresses rapidly change during the primary creep stage, and then during the secondary creep stage which was characterized by linear increase in the creep strain; the rate of increase reduces as CMR approaches saturation (CMR=1). Porosity inclusion reduces the matrix stress as shown in FIG. 14B due to the reduction in matrix stiffness as discussed previously. Hence, the matrix experiences viscoelastic and viscoplastic deformation at a lower rate and increases the CMR as shown in FIG. 14C. Additionally due to the reduced matrix stiffness, the matrix sheds more load to the fiber in order to maintain the same applied composite stress level. Since the increase in the fiber stress was more than the drop in the matrix stress with porosity inclusion, the total longitudinal strain was increased as shown in FIG. 14A.

FIG. 14A through FIG. 14C are a set of plots showing the time-dependent deformation response of SiC/SiNC at 1200° C.; FIG. 14A is a plot showing total longitudinal strain; FIG. 14B is a plot showing constituent longitudinal stress; FIG. 14C is a plot showing creep mismatch ratio for baseline (pristine) and porosity SRVE.

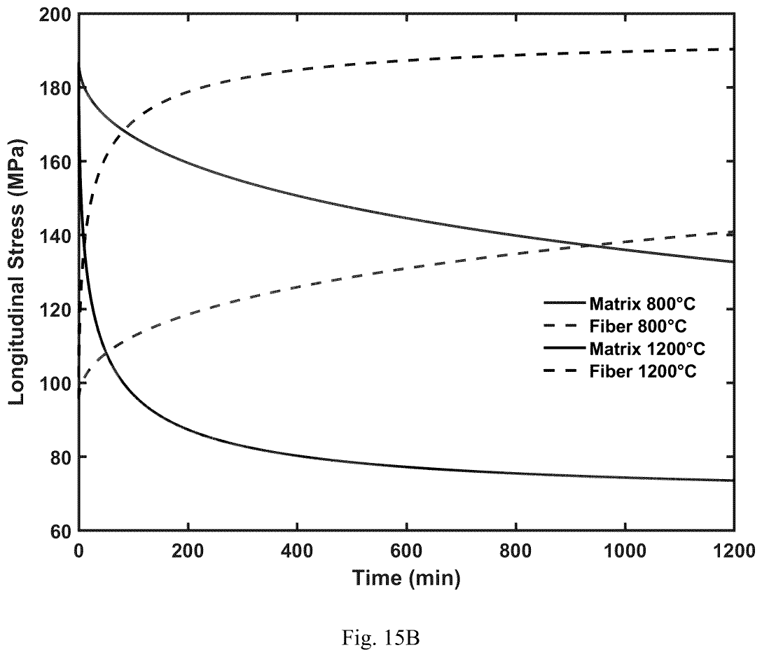

Finally, the impact of temperature on the creep response was studied for the SRVEs with porosity. SRVE at 800° C. was simulated in the same 1200° C. setup, and the UTS at 800° C. was also determined through in-house uniaxial quasistatic tests. The selected temperatures represent the intermediate and high temperature deformation regimes of the SiC/SiNC CMC [Lara-Curzio, Compos Part A Appl Sci Manuf, 1999; Artz, 2022]. FIG. 15A shows significant decrease in the creep response at intermediate temperature in both the primary and secondary creep stages. Consequently, the load sharing between the matrix and fiber occurred at a lower rate and needed further creep hold time for saturation as shown in FIG. 15B. Since creep is a thermally activated process, this reduction in creep response was expected based on the viscoplastic creep model. The results presented show that the generated SRVEs in conjunction with the high-fidelity micromechanics model were consistent with literature [Bhatt & Kiser, J Eur Ceram Soc, 2021; Khafagy et al., Ceram Int, 2021; Rugg et al., J Eur Ceram Soc, 1999; Khafagy & Chattopadhyay, J Compos Mater, 2023]. However, oxidation of the constituents at intermediate and high temperatures introduced additional complexities in the creep response of CMCs [Halbig et al., Journal of the American Ceramic Society, 2008; Ruggles-Wrenn & Sharma, Applied Composite Materials, 2011; Schichtel & Chattopadhyay, J Eur Ceram Soc, 2023].

FIG. 15A and FIG. 15B are a set of plots showing the time-dependent deformation response of SiC/SiNC at 800° C. and 1200° C. for the porosity SRVEs; FIG. 15A is a plot showing total longitudinal strain; FIG. 15B is a plot showing constituent longitudinal stress.

A DL framework was developed for conducting comprehensive microstructural analysis of C/SiNC and SiC/SiNC CMCs. Vanilla regression network was used to segment the microstructure phases and defects and quantify their variability in terms of physical descriptors (i.e., constituents volume fractions). The CMC microstructure main phases were efficiently characterized through CAMs, meanwhile the physical descriptors predictions agree with CMCs literature. A detailed design of the generative microstructure networks was presented, including the proposed architectures of GAN and WGAN, the implementation of a CP algorithm, and the optimization strategies for training, all evaluated for their performance in generating high-fidelity periodic SRVEs. The vanilla regression predictions were then used to filter the generated SRVEs to conform with the constituents and defects volume fractions. Validation of SRVEs was performed using HFGMC micromechanics simulations. First, the homogenized elastic properties were computed for baseline SRVEs, and then the effect of intra-tow porosity inclusion was discussed. The transverse and out-of-plane elastic properties were the most susceptible properties to degradation in C/SiNC due to the distribution of porosity near the fiber/matrix interface, while the porosity effect was relatively diminished in SiC/SiNC due to the Hi-Nicalon™ fiber load carrying capability. Additionally, HFGMC was modified through a numerical iterative algorithm to solve for the time-dependent response of SiC/SiNC subjected to intermediate and high temperature levels. The results show that the DL-generated SRVEs in conjunction with time-hardening constitutive model can capture the primary (Coble) and secondary (Nabarro-Herring) creep stages. The effect of porosity and temperature on the constituent load sharing capabilities was investigated, and the results correlate the increase in total creep strain and fiber stress to porosity inclusion. Additionally, at intermediate temperature, the model predicted significant decrease in the inelastic response and constituent load sharing as expected, owing to the reduction in the creep thermally activated mechanisms.

### Example 2: Stochastic Microstructure Reconstruction and Localized Creep Response of Ceramic Matrix Composites

This example investigates the microstructural variability of SiC-based ceramic matrix composites (CMCs) for stochastic microstructure reconstruction and high-fidelity micromechanics simulation. The study focuses on SiC/BN/SiNC CMC tow microstructures comprising Hi-Nicalon™ SiC fibers with a boron nitride (BN) interphase coating embedded in a SiNC matrix. A statistical-based module was developed to characterize microstructural variability from scanning electron microscopy (SEM) images in terms of physical and spatial descriptors, including constituent and defect volume fractions, fiber diameter, BN interphase thickness, and fiber nearest-neighbor spacing and orientation statistics. Analysis of fiber nearest-neighbor orientation angles and distances, together with Dirichlet tessellation, provided insight into the stochastic nature of localized fiber clustering within the tow. A Voronoi-based fiber placement algorithm incorporating Lloyd's relaxation, microstructure-informed centroid perturbations, and angular coordinate-based periodic boundary conditions was employed to generate SRVEs reproducing the quantified quasi-hexagonal fiber packing. A distance-dependent exponential decay model was applied to reproduce the experimentally observed pore clustering near fiber surfaces. The generated quasi-hexagonal SRVEs were validated against actual SEM micrographs and randomly generated SRVEs using two-point correlation analysis and visual comparison of microstructural cross-sections. The validated SRVEs were subsequently integrated into an iterative HFGMC micromechanical framework to evaluate the localized coupled creep-damage response of the CMC microstructure, clarifying the role of realistic fiber clustering and pore placement in matrix microcrack nucleation, constituent load sharing, and creep strain distribution under longitudinal creep loading.

FIG. 22 is an image showing a Dirichlet tessellation overlaid on an exemplary SEM micrograph of a SiC/BN/SiNC composite microstructure.

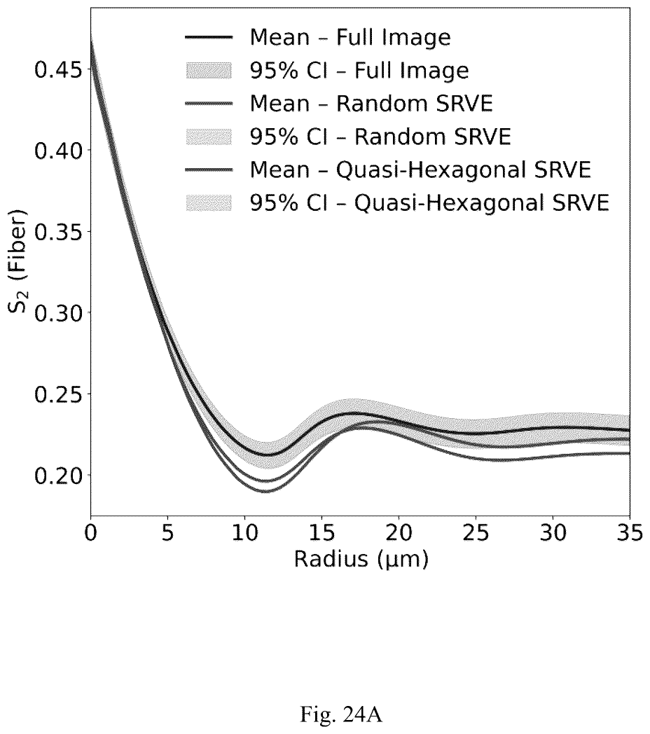

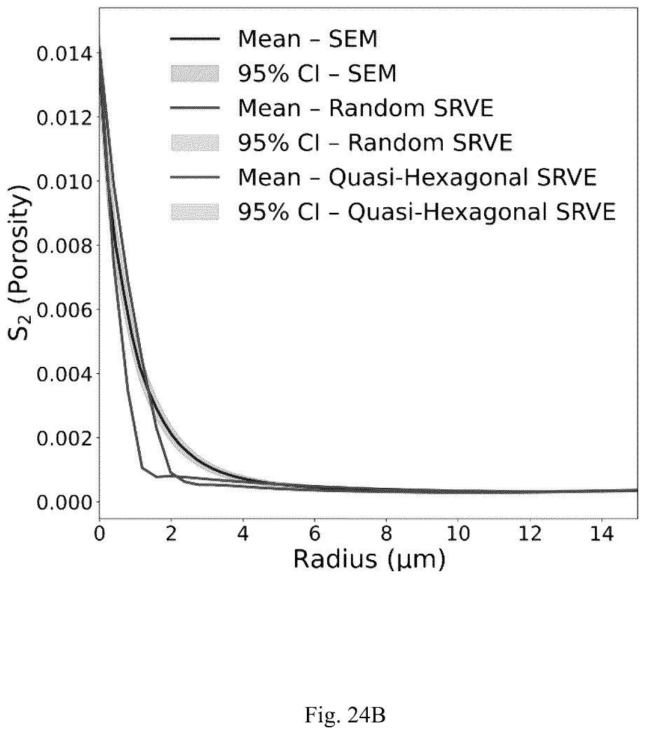

FIG. 23A through FIG. 23C are a set of images showing cross-sections of (FIG. 23A) an exemplary SiC/BN/SiNC microstructure with fibers, pores, and BN interphase with examples of quasi-hexagonal packing outlined, (FIG. 23B) an exemplary simulated microstructures generated using the quasi-hexagonal method with quasi-hexagonal packing examples outlined, and (FIG. 23C) exemplary simulated microstructures generated using the random method.

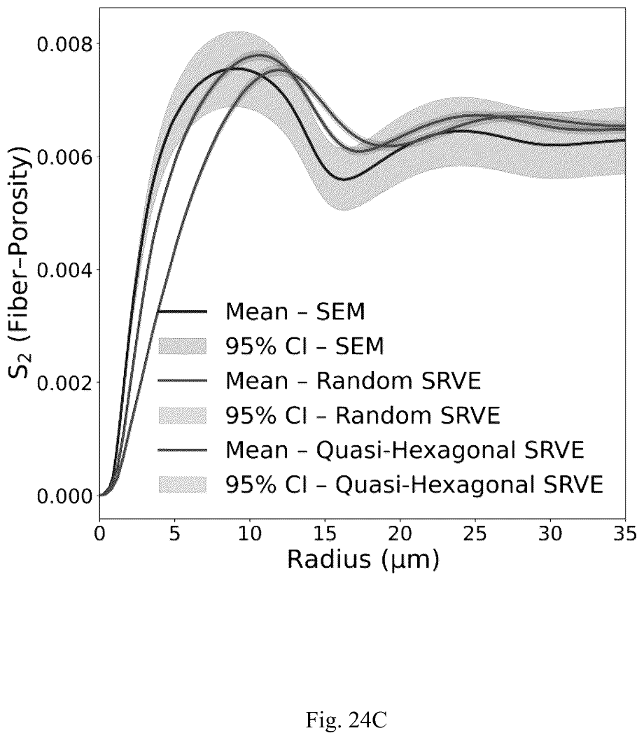

FIG. 24A through FIG. 24C are a set of plots showing radially averaged two-point correlation comparisons with 95% confidence intervals between a full microstructure and generated SRVEs: (FIG. 24A) fiber-fiber autocorrelation, (FIG. 24B) porosity-porosity autocorrelation, and (FIG. 24C) fiber-porosity cross-correlation.

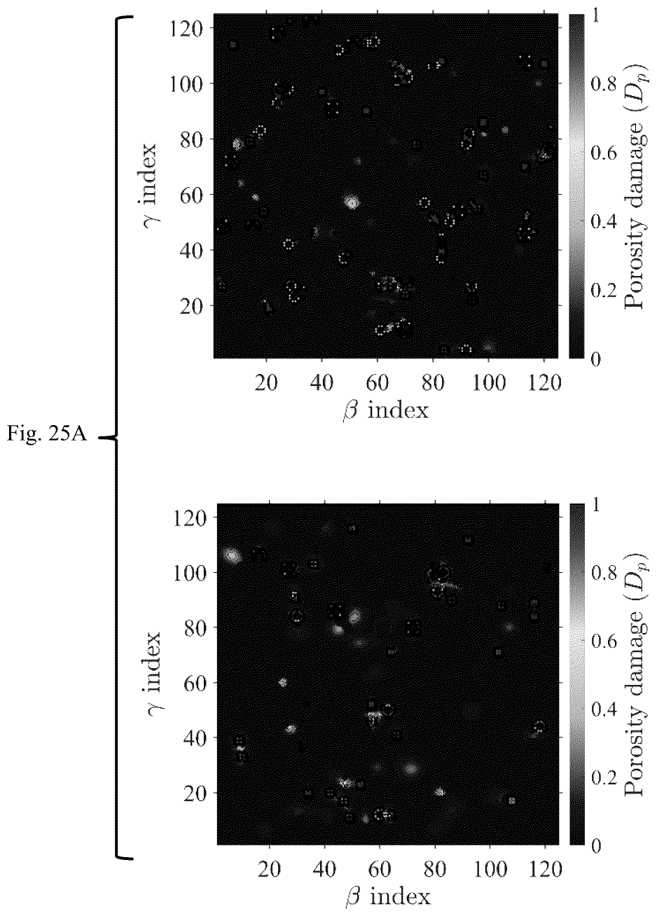

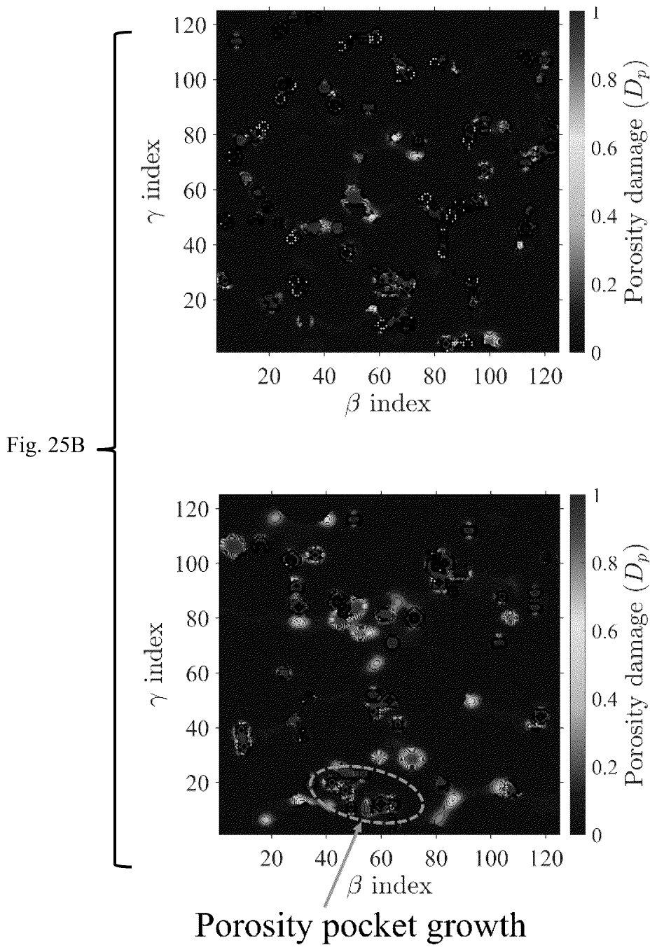

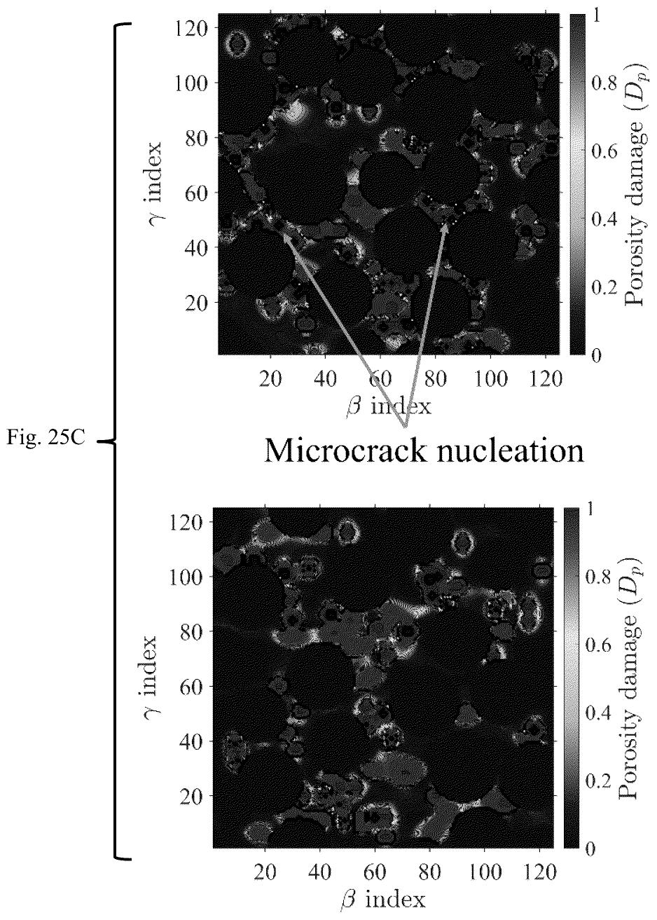

FIG. 25A through FIG. 25C are a set of images showing cross-sections of porosity damage contours for exemplary quasi-hexagonal (top) and random SRVEs (bottom) under longitudinal creep loading, shown after (FIG. 25A) 15 minutes, (FIG. 25B) 45 minutes, and (FIG. 25C) 240 minutes.

Statistical-based microstructure generation: The SRVEs generated using the statistical-based module described above were validated by assessing their ability to capture the properties of the full microstructure using a two-point correlation (S₂) analysis of fiber, porosity, and fiber-porosity relative distributions, as shown in FIG. 24A through FIG. 24C. S₂, which represents the probability that a line of length r placed on a microstructure image has both ends located in the same phase (autocorrelation) or in two different specified phases (cross-correlation), characterizes pair distributions and provides information on morphology, spacing, and anisotropy. The radially averaged S₂ curves of the SEM images and SRVEs are presented in FIG. 24A through FIG. 24C. The quasi-hexagonal SRVEs exhibit better agreement with the SEM short-range fiber autocorrelation up to approximately 17 μm than the random SRVEs, which is expected given their more accurate nearest-neighbor orientation statistics. For microstructures lacking long-range order, S₂ approaches VF² as r increases; thus, small differences in fiber volume fraction can amplify discrepancies in S2 at larger distances. This explains the reduced accuracy beyond approximately 17 μm; however, such differences are insignificant, as they primarily reflect the squared volume fraction rather than true pair correlations. FIG. 24B shows the porosity autocorrelation: the hard-core model exhibits an abrupt drop with increasing r, whereas the porosity distribution model in the quasi-hexagonal SRVEs produces a more gradual decay, more realistically capturing pore-pore correlations. The impact of the porosity model is even more pronounced in FIG. 24C, where the fiber-porosity cross-correlation is reproduced significantly better than with the hard-core model.

The physical and statistical assessments presented in this example demonstrate that the quasi-hexagonal SRVE generation method more effectively captures the spatial and morphological characteristics of the PIP SiC/BN/SiNC CMCs compared to the traditional hard-core approach, making it a reliable model for micromechanics analysis and simulations. A visual comparison between the actual microstructure, quasi-hexagonal SRVE, and random SRVE is presented in FIG. 23A through FIG. 23C. The cross sections highlight the similarities between the pore distribution in the SiC/BN/SiNC microstructure and the quasi-hexagonal SRVEs. When compared to the pore dispersion in the random SRVEs, it is clear that the quasi-hexagonal method is far more effective at capturing the true porosity distribution in the microstructure. As discussed above, a microstructure exhibiting complete spatial randomness had approximately 29.8% quasi-hexagonal Voronoi cells, whereas the observed microstructure demonstrated 39.4% quasi-hexagonal Voronoi cells. While this represents a significant increase compared to complete spatial randomness, it remains insufficient to achieve a perfectly quasi-hexagonal fiber arrangement. In other words, quasi-hexagonal Voronoi cells do not necessarily result in quasi-hexagonal fiber packing. Further, given that the SRVE size is relatively small compared to the overall microstructure, the likelihood of achieving quasi-hexagonal fiber packing consequently drops. However, on average, quasi-hexagonal fiber packing is significantly more likely to occur in the actual microstructure and the quasi-hexagonal generated SRVEs compared to the randomly generated SRVEs. Examples of these quasi-hexagonal patterns are also highlighted in FIG. 23A through FIG. 23C.

Time-dependent creep-damage response using statistical-based module SRVEs: The micromechanics simulation system was applied to the statistical-based module SRVEs to compute the time-dependent creep-damage response. To investigate the localized coupled creep-damage response more closely, cross-sections in the transverse plane of the quasi-hexagonal and random SRVEs were analyzed. The porosity damage contours at different time snapshots are shown in FIG. 25A through FIG. 25C. The porosity damage parameter increases around the pores due to localized deformation. As the matrix relaxes and porosity damage becomes the dominant degradation mechanism, new pores nucleate between fibers as the nearest-neighbor distance decreases, while existing pores grow and coalesce. In the random SRVE, porosity pockets form within the matrix due to the more dispersed pore distribution. By contrast, the quasi-hexagonal SRVE exhibits pronounced pore growth near the fibers, ultimately leading to matrix microcrack nucleation. The locations of these microcracks align with the as-received SEM-characterized cracks shown in FIG. 22. However, after 4 hours of loading, the localized deformation and porosity growth begin to saturate as a result of continued matrix relaxation. The porosity growth observed in the quasi-hexagonal SRVE is consistent with cavitation in polycrystalline brittle materials under creep. Initially, quasi-equilibrium voids exhibit symmetric geometry; during creep, voids grow along grain boundaries and coalesce into crack-like voids that can propagate and cause fracture. Similarly, fibers in the quasi-hexagonal SRVEs induce an effect analogous to grain boundaries: quasi-equilibrium pores in the amorphous matrix grow, their growth direction is constrained by nearby fibers, and microcrack-like defects ultimately form in the fiber vicinity. The resulting defects could propagate if a residual strength test were conducted. Experimentally, fiber breakage or degradation was expected under prolonged hold times and can be captured in simulations if fiber damage or oxidation models are incorporated.

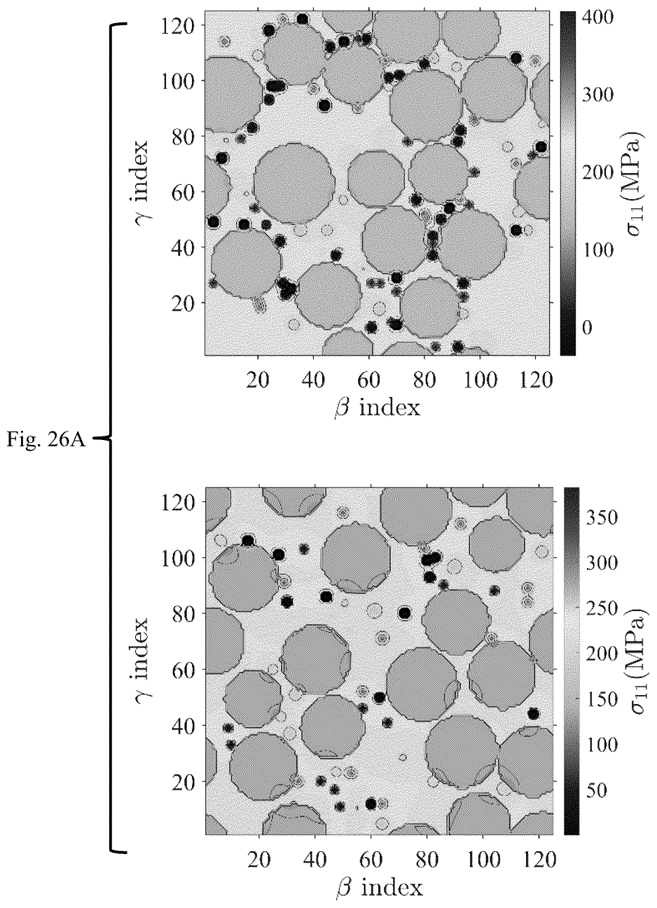

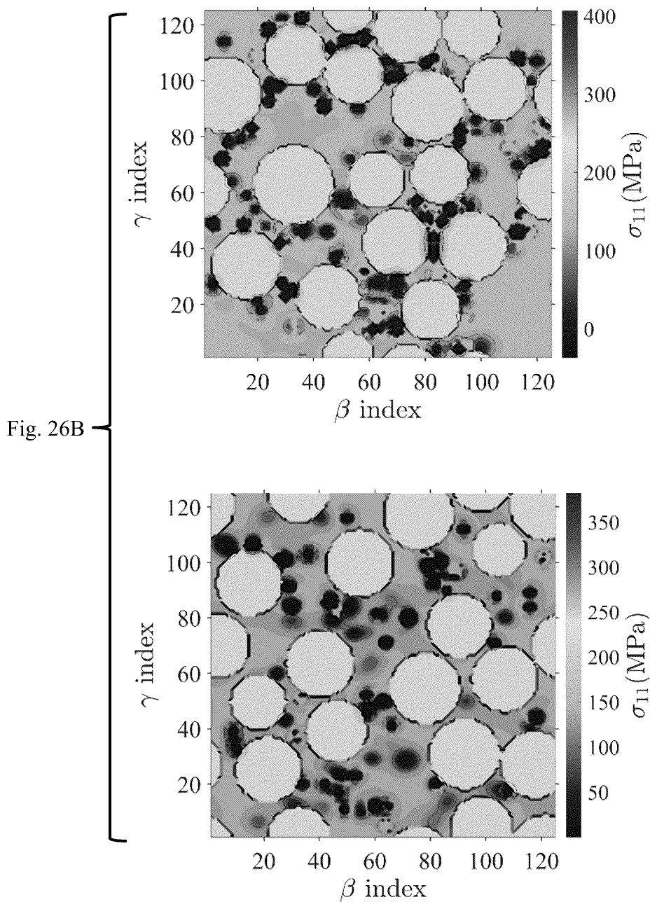

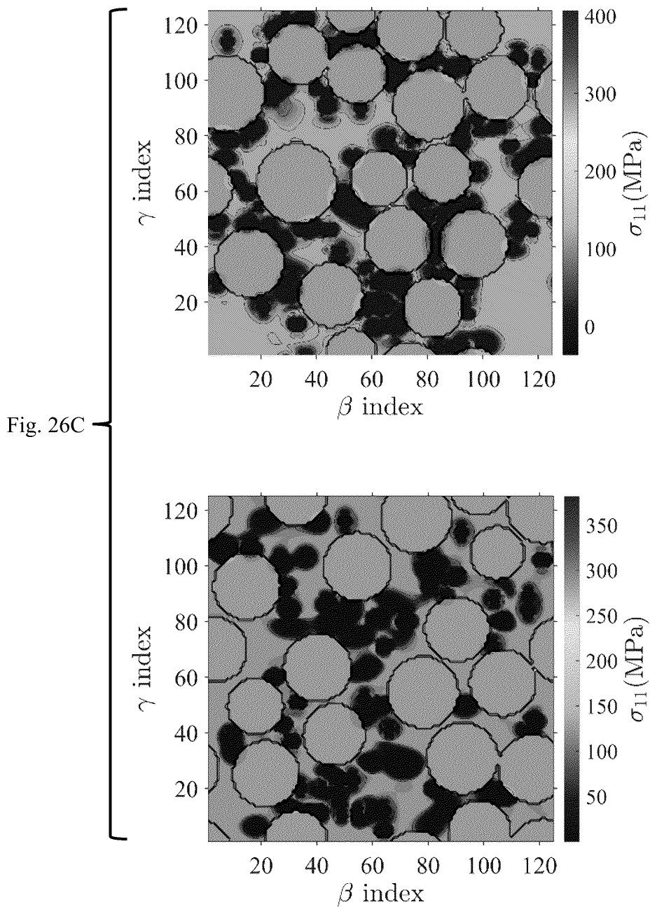

FIG. 26A through FIG. 26C are a set of images showing cross-sections of longitudinal Cauchy stress contours for exemplary quasi-hexagonal (top) and random SRVEs (bottom) under longitudinal creep loading, shown after (FIG. 26A) 1 minute, (FIG. 26B) 45 minutes, and (FIG. 26C) 240 minutes.

The localized longitudinal stress contours are presented in FIG. 26A through FIG. 26C. Both SRVEs exhibited fiber-matrix load sharing due to the creep mismatch ratio. At the end of the load ramp-up stage, the matrix carried most of the load because of its higher initial stiffness in this material system. As the matrix relaxed and degraded through early microcrack propagation and porosity growth, the fibers progressively carried a greater share of the load throughout the remainder of the creep test. Initially, stress concentrations developed in the vicinity of pores; however, as the matrix transferred load to the fibers, the microstructural hotspots shifted to the fiber-matrix interface. These hotspots served as potential sites of fiber breakage and failure.

The quasi-hexagonal SRVE exhibited higher stress concentrations than the random SRVEs due to the combined influence of fiber clustering and pore placement. The Dirichlet tessellation analysis, as shown in FIG. 22, demonstrated stronger clustering in the quasi-hexagonal configuration relative to complete spatial randomness. While the tessellation analysis did not directly provide inter-fiber distances, the higher fraction of quasi-hexagonal Voronoi cells implied more frequent occurrences of locally small spacing between neighboring fibers. Under predominantly longitudinal loading conditions, regions of locally reduced matrix exhibited elevated effective stresses relative to areas with greater fiber separation. Additionally, pores in the quasi-hexagonal SRVEs tended to occur near the fiber-matrix interface, producing steeper local stress gradients in the adjacent matrix and along the neighboring fiber surfaces. Because the fibers crept much less than the matrix, matrix relaxation shifted the load toward the fibers over time, amplifying local stress elevations particularly where clustering and pore proximity coincide. Consequently, the quasi-hexagonal SRVE developed a more uneven distribution of load between the matrix and fibers compared to the fully random SRVEs, leading to higher localized stresses near fiber surfaces and an expected reduction in creep life and residual strength.

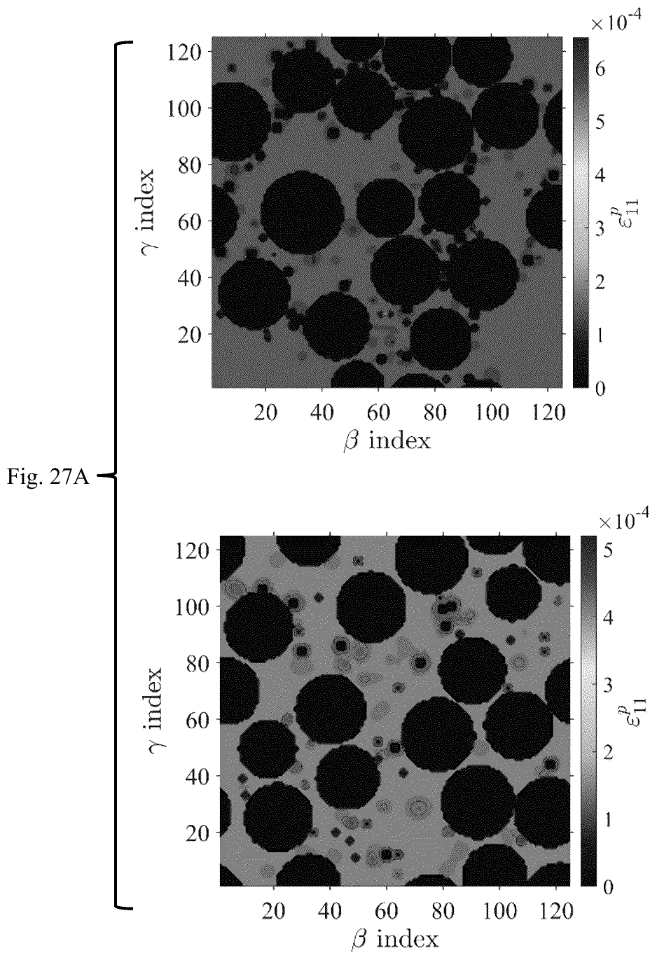

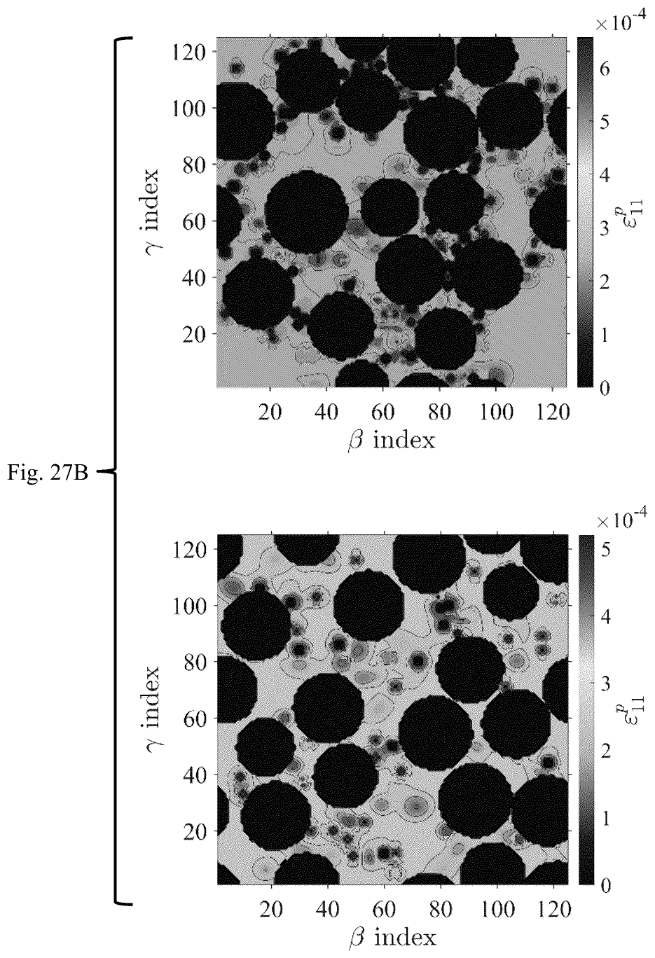

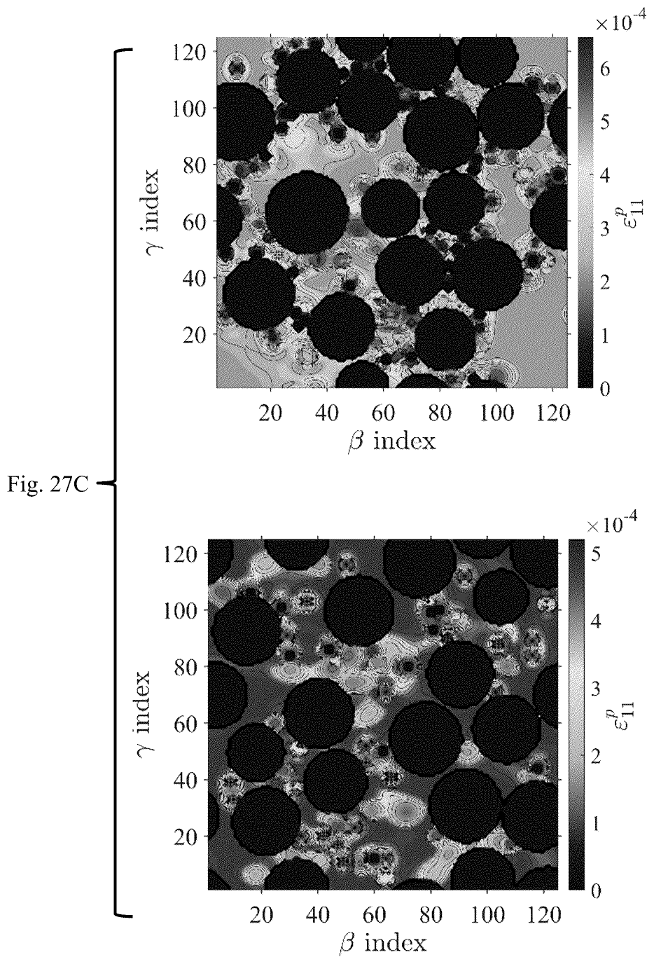

FIG. 27A through FIG. 27C are a set of images showing cross-sections of longitudinal creep strain contours for exemplary quasi-hexagonal (top) and random SRVEs (bottom) under longitudinal creep loading, shown after (FIG. 27A) 15 minutes, (FIG. 27B) 45 minutes, and (FIG. 27C) 240 minutes.

The longitudinal creep strain contours are shown in FIG. 27A through FIG. 27C and were consistent with the stress contours. The inelastic strain is dominated by matrix creep; however, the random SRVE exhibited larger strain gradients due to its porosity distribution, as porosity growth disrupts the matrix relaxation process. This study emphasizes the importance of constructing SRVEs that realistically capture microstructural features when investigating complex time-dependent mechanisms of composites in service environments. The localized response was analyzed to clarify the role of fiber orientation and pore location in the nucleation of matrix microcracks and the initiation of fiber breakage. Incorporating such microstructures into multiphysics multiscale models is expected to improve the accuracy of global composite response predictions while also capturing localized damage, which is critical for virtual damage assessment and the development of digital twins.

A statistical-based module was developed for computational microstructure characterization and stochastic reconstruction of SiC/BN/SiNC CMC tow microstructures fabricated via the PIP process. An image-processing algorithm was implemented to extract physical descriptors, including fiber diameter and volume fraction, porosity, and BN interphase thickness, as well as spatial descriptors comprising intra-tow nearest-neighbor spacing and orientation. A stochastic generation algorithm combining Dirichlet tessellations, Lloyd's relaxation, and microstructure-inspired perturbations was employed to replicate fiber morphology and quasi-hexagonal clustering, and a distance-dependent porosity distribution model was formulated to place pores in preferential locations consistent with SEM observations. The quasi-hexagonal SRVEs reproduced the SEM-derived physical and spatial descriptor distributions, with fiber autocorrelation captured effectively up to approximately 17 μm, and porosity autocorrelation and fiber-porosity cross-correlation confirmed that the proposed model captures pore distributions more accurately than the random hard-core baseline. High-fidelity micromechanics simulations demonstrated that the localized coupled creep-damage response exhibited a pronounced dependence on spatial features, specifically the degree of fiber clustering and the as-received porosity distribution. The quasi-hexagonal SRVE developed regions of elevated stress concentration driving porosity growth and matrix microcrack nucleation near pre-existing pores, whereas the random SRVE exhibited porosity pocket growth within the matrix. These findings highlight the critical importance of implementing microstructure-inspired SRVEs in micromechanics simulations for accurate prediction of time-dependent damage mechanisms under service conditions.

### Example 3: Microstructural Descriptors-Aware Diffusion-Based Model for Stochastic Reconstruction of Composite Microstructures

A deep learning (DL)-based microstructure characterization and reconstruction (MCR) framework was developed to generate an ensemble of stochastic representative volume elements (SRVEs) that captures the intrinsic microstructural variability of unidirectional fiber tows. The framework was demonstrated on carbon fiber reinforced polymer (CFRP) tow microstructures and was based on a novel conditional discrete denoising diffusion probabilistic model, referred to herein as a conditional discrete diffusion model. FIG. 18 is a schematic of an exemplary software-implemented system and method for micromechanics simulation based on stochastic representative volume element generation.

As summarized in FIG. 18, the workflow integrated quantitative microstructural characterization from scanning electron microscopy (SEM) images, including categorical segmentation and uncertainty-aware descriptor extraction, with a discrete diffusion-based generative formulation, enabling descriptor-conditioned reconstruction of the fiber, pore, and matrix phases. The microstructural descriptors were grouped into physical and spatial categories: the physical descriptors corresponded to constituent and manufacturing-induced defect volume fractions, whereas the spatial descriptors were probability distributions that quantify in-plane fiber packing and clustering. These descriptors were processed through a multilayer perceptron (MLP) to generate a conditional embedding, which was enforced through multi-head cross-attention blocks within a U-Net backbone. The descriptor-based embedding guided the diffusion model toward a subset of the microstructural space consistent with the observed variability in fiber and defect morphology and volume fractions, as well as in fiber-related spatial distributions and higher-order point statistics, thereby accelerating training convergence and more accurately capturing microstructural variability relative to descriptor-guidance-free diffusion models. Geometric periodicity was enforced during post-training diffusion model sampling by applying circular padding after each Markov denoising step, constraining the generated realizations to a periodic subspace and facilitating direct integration into high-fidelity micromechanics solvers that assume periodic boundary conditions, such as the high-fidelity generalized method of cells (HFGMC). HFGMC was then used to compute the probability distribution of the homogenized elastic properties across the SRVE ensemble, enabling stochastic bottom-up multiscale modeling.

The main contributions of this work can be summarized as follows: (i) establishment of a DL-based MCR framework featuring modular microstructure reconstruction that captures constituent and manufacturing-induced defect variability; (ii) development of a discrete diffusion-based generative methodology for multiphase composite microstructures; (iii) incorporation of microstructural descriptor-aware conditioning to preserve physical and statistical consistency under limited experimental data availability; and (iv) quantification of the probability distribution of effective composite properties for bottom-up hierarchical multiscale modeling, with a possible extension to probabilistic semi-concurrent approaches upon incorporation of nonlinear constitutive models.

Conditional discrete diffusion model: A conditional discrete diffusion model was trained on 400 segmented SEM micrographs of 65 μm×65 μm sub-regions, resized to 384×384 pixels to match the down-sampling and up-sampling factors of the U-Net backbone. The dataset was augmented sevenfold using rotations of 90°, 180°, and 270°, horizontal and vertical flips, and a combined 900 rotation with horizontal flip, enhancing statistical diversity and reducing potential bias in the descriptor distributions. Each augmented image was subsequently paired with its corresponding 17-dimensional conditional descriptor vector in a one-to-one supervised mapping. This explicit pairing enabled the model to learn an implicit relationship between the physical and spatial features and the underlying microstructure, thereby improving generation quality and enabling accurate quantification of aleatoric uncertainty with limited training data.

The diffusion process starts with one-hot encoded segmented microstructures x₀∈{0,1}^{3×384×384}, where the three channels represent the matrix, fiber, and pore phases. Unlike continuous diffusion models that corrupt data using additive Gaussian noise, the forward process here was defined by a categorical transition kernel that randomly replaces pixel labels according to a time-dependent noising probability (i.e., a Markov corruption process). A cosine-based noise schedule at

$${α}_{t} = {cos}^{2} ( \frac{π t}{2 T} ) ,$$

commonly used in image generation due to its strong empirical performance, governs the gradual corruption of categorical labels through probabilistic class replacement rather than additive Gaussian noise. At each timestep t, a binary mask is sampled with replacement probability \sqrt{1−αₜ} (i.e., each pixel is independently selected for replacement with that probability), and the selected pixel labels are replaced with uniformly random categories (i.e., uniform categorical noise), yielding the noisy state xₜ. The reverse process learns the categorical transition distribution p_{θ}(xₜ₋₁|xₜ,c), which iteratively denoises the corrupted categorical state toward the original segmentation conditioned on the microstructural descriptor vector c. Here, θ denotes the learnable parameters of an architecture-agnostic deep network used for diffusion model training.

FIG. 28A is a diagram showing an exemplary U-Net backbone architecture used in the conditional discrete diffusion model. FIG. 28B is a diagram of an exemplary residual block.

The disclosed model was implemented using a U-Net backbone with four down-sampling and four up-sampling stages connected through residual blocks and skip connections, augmented with multi-head cross-attention blocks, as shown in FIG. 28A and FIG. 28B. Owing to its modular encoder-decoder structure, the U-Net readily accommodated timestep embeddings and microstructural conditioning through embedding injections within residual and attention blocks. Temporal information was encoded using sinusoidal timestep embedding γ(t)∈ [symbol] , which was projected through an MLP and used to modulate the residual blocks. The conditional input vector consisted of compact physical and spatial microstructural descriptors. Specifically, the conditioning variables include scalar quantities comprising fiber volume fraction and porosity, along with parameterized distributions of the spatial descriptors. Because the spatial descriptors were computed over fiber pairs within each image and yield variable-length vectors, each distribution was summarized by its mean, standard deviation, and quartiles at the 25^{th}, 50^{th}, and 75^{th} percentiles. Consequently, each microstructure was represented by a fixed-length 17-dimensional conditioning vector. This statistics-based vector was normalized using dataset-level mean and standard deviation and then projected through an MLP to obtain a compact conditional embedding. The timestep and conditional embeddings were summed and used to modulate the residual blocks, while conditioning was additionally enforced through multi-head cross-attention blocks within the U-Net.

The model objective function combines a variational lower bound (VLB) term with an auxiliary categorical cross-entropy (CE) term, as follows:

[symbol]

=λ_{CE} [symbol] Equation 16

λ_{CE} controls the relative contribution of the CE and VLB components and is set to 0.05 to provide a trade-off between optimization stability and accurate recovery of microstructural features. Given a noised sample xₜ at diffusion step t and conditioning c, the network outputs logits ŷ=logits_{θ}(xₜ,t,c). The logit for pixel i and class k is denoted by ŷ_{i,k}. The one-hot ground-truth label is y_{i,k}∈{0,1} with

$${Σ}_{k = 1}^{K} {y}_{i , k} = 1 .$$

The CE loss was then expressed as:

$${ℒ}_{C E} = - \frac{1}{N} {\sum }_{i = 1}^{N} {\sum }_{k = 1}^{K} {y}_{l , k} log ( {softmax ( {\hat{y}}_{l , :} )}_{k} ) \qquad Equation 17$$

where N is the total number of pixels in a batch and K=3 corresponds to the matrix, fiber, and pore phases. The VLB quantified the Kullback-Leibler (KL) divergence between the true reverse posteriors of the forward diffusion process and the model reverse transitions across timesteps. It additionally includes a KL term that matches the terminal forward distribution q(x_{T}|x₀) to the prior p(x_{T}) and a final-step negative log-likelihood term, formulated as follows:

$${ℒ}_{V L B} = {𝔼}_{q ( {x}_{0} )} [ {D}_{K L} ( q ( {x}_{T} \vert {x}_{0} ) \vert \vert p ( {x}_{T} ) ) + {\sum }_{t = 2}^{T} {𝔼}_{q ( {x}_{t} \vert {x}_{0} )} [ {D}_{K L} ( q ( {x}_{t - 1} \vert {x}_{t} , {x}_{0} ) \vert \vert {p}_{θ} ( {x}_{t - 1} \vert {x}_{t} ) ) ] - {𝔼}_{q ( {x}_{1} \vert {x}_{0} )} [ log {p}_{θ} ( {x}_{0} \vert {x}_{1} ) ] ] \qquad Equation 18$$

where D_{KL}(·∥·) denotes the KL divergence. The distribution q(x₀) denotes the training data distribution (i.e., the empirical data distribution), and q(x_{1:T}|x₀) denotes the forward diffusion process specified by the predefined categorical Markov transitions q(xₜ|xₜ₋₁). Accordingly, q(xₜ₋₁|xₜ,x₀) was the true reverse posterior induced by the forward diffusion process

Unlike continuous DDPMs, which are commonly trained with a mean squared error objective on predicted Gaussian noise as a practical surrogate for the evidence lower bound, discrete diffusion operates in a categorical pixel space and is naturally trained with likelihood-based objectives derived from the VLB. In this formulation, the VLB term enforced probabilistic consistency of the reverse diffusion transitions and avoids artifacts that can arise when discrete categories are treated as continuous regression targets. Although the VLB already contains a categorical negative log-likelihood component, relying on the VLB objective alone may provide insufficient learning signal for minority phases such as pore regions, which occupy a small global volume fraction in the microstructure. An explicit pixel-wise CE term was therefore included as an auxiliary objective to provide a stronger supervision signal, improve training stability and convergence in the early training stages, and enhance the reconstruction of pore regions over subsequent epochs. Together, these terms balance probabilistic consistency with categorical accuracy.

Unlike GANs and VAEs, where circular padding in convolutional layers during training is generally sufficient to produce periodic outputs, diffusion-based denoising proceeds through iterative probabilistic updates over many timesteps, and boundary regions may not retain sufficient global spatial context to enforce mutual consistency across opposite edges through architectural constraints alone. Enforcing periodicity at the sampling level rather than solely through the network architecture therefore promoted global boundary consistency across successive denoising steps. Circular shifting was applied over a prescribed boundary band to adequately enforce constituent continuity across the edges and to avoid partial or irregular fiber truncation during the mapping from the microstructure space to its periodic subspace. While the disclosed example focuses on periodic SRVEs to enable direct integration with the micromechanics homogenization approach, the overall framework is not restricted to periodic domains; the trained model can also generate nonperiodic SRVEs when periodic sampling is not enforced, which remain suitable for micromechanical analyses using static uniform or kinematic uniform boundary conditions, as well as self-consistent homogenization frameworks.

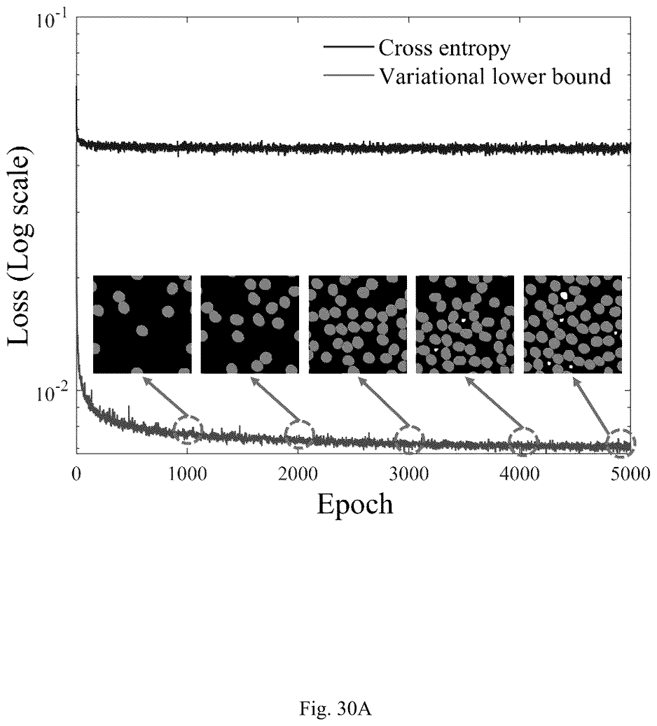

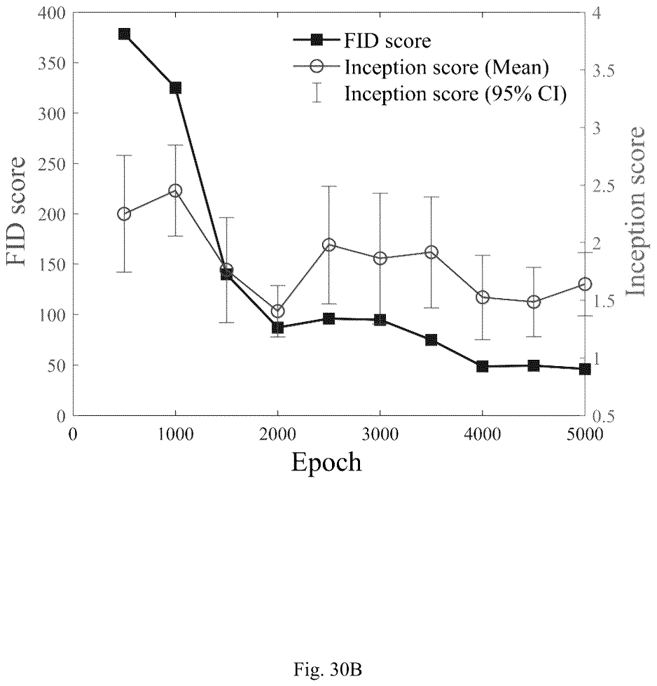

FIG. 30A and FIG. 30B are a set of plots showing exemplary conditional diffusion model training results, including (FIG. 30A) evolution of the variational lower bound and categorical cross-entropy losses together with representative generated samples at selected epochs, and (FIG. 30B) Fréchet inception distance and inception score evolution demonstrating convergence and improved distributional fidelity.

Conditional discrete diffusion model-based stochastic microstructure reconstruction: The conditional discrete diffusion model exhibited stable convergence during training, as shown in FIG. 30A. The VLB loss decreased rapidly within the first 1,000 epochs and then gradually stabilized, whereas the categorical CE term reached convergence early in training and remained approximately constant thereafter. This behavior indicates that, in contrast to formulations that rely solely on the VLB objective, the CE term was primarily beneficial early in training, where it provides a more informative training signal that rapidly establishes consistent phase separability among the categorical classes; once this initial separation was learned, the optimization was predominantly governed by the VLB term, which drives subsequent refinement of the learned discrete diffusion dynamics. Representative generated microstructures sampled at different epochs demonstrated the evolution of physically meaningful fiber and pore distributions as the model learns the categorical transition probabilities. Initially, the model struggled to capture the fiber volume fraction, resulting in microstructures with unrealistically sparse fibers; as training progressed, the model increasingly recovered both the fiber content and its spatial organization. Because porosity represents a relatively low fraction in the studied composite system, early generations contained no pores, and the pore class was effectively treated as stochastic noise. The porosity-conditioning embedding described above began to show a clear effect around 4,000 epochs, where the model, through its attention mechanism, learned to reproduce pore populations with spatial patterns consistent with the conditioning descriptors.

Quantitative evaluation of the generated microstructures was performed using the Fréchet Inception distance (FID) and Inception score (IS), which provide complementary indicators of distributional fidelity and sample diversity. Both metrics were computed using a pre-trained Inception v3 network, a deep convolutional neural network trained on the ImageNet dataset. Specifically, IS evaluates the confidence and diversity of the generated samples through the predicted label distribution produced by the Inception v3 classifier, whereas FID measures the distance between the real and generated data distributions in the Inception v3 feature space by comparing the mean and covariance of the extracted feature embeddings for real and generated samples. Although originally developed for natural images, FID and IS have been increasingly adopted in microstructure generation studies. As illustrated in FIG. 30B, the FID decreased sharply from approximately 340 to below 100 after 2,000 epochs, indicating rapid improvement in the statistical fidelity of generated samples, where lower values indicate closer agreement with SEM micrographs. The FID further decreased and stabilized around 50 through the end of training. Concurrently, the IS values' temporal stability and narrowing confidence interval indicate preserved sample diversity without mode collapse. Stabilization of the VLB trajectory and convergence of FID and IS suggest that the conditional diffusion model achieved distributional consistency and descriptor-conditioned generation within 5,000 epochs. However, these metrics provide only a coarse assessment of image-level realism and cannot reliably quantify generation accuracy for SRVE ensembles required for probabilistic integrated computational materials engineering. This intuition is further supported by comparing the FID and IS scores of the conditional and unconditional diffusion models in the discussion below. Despite clear differences in the resulting microstructural statistics, the two models yield comparable FID and IS values, highlighting that these metrics alone are insufficient for evaluating microstructural images or SRVEs. Accordingly, rigorous validation requires agreement in physical and spatial descriptors, together with point statistics computed over the generated SRVE ensemble.

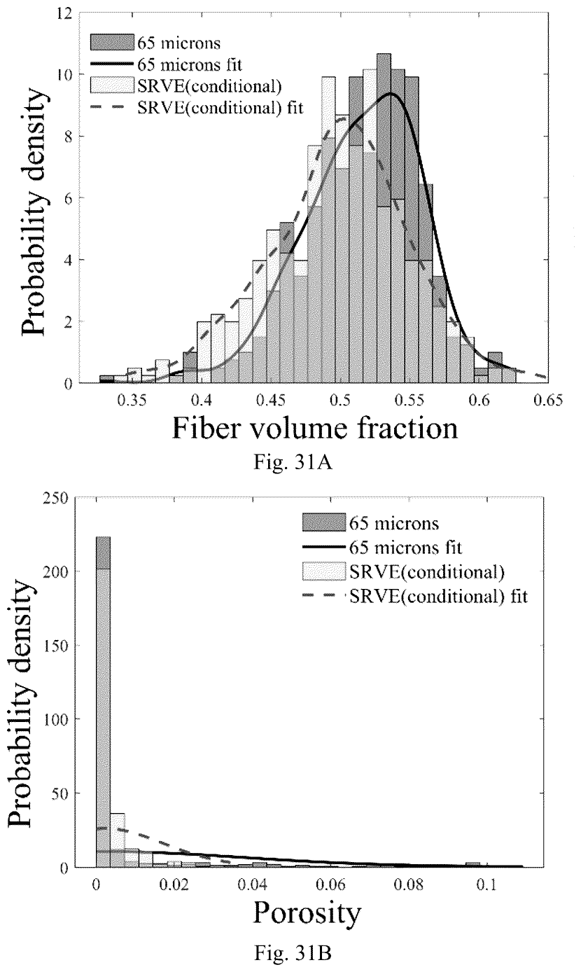

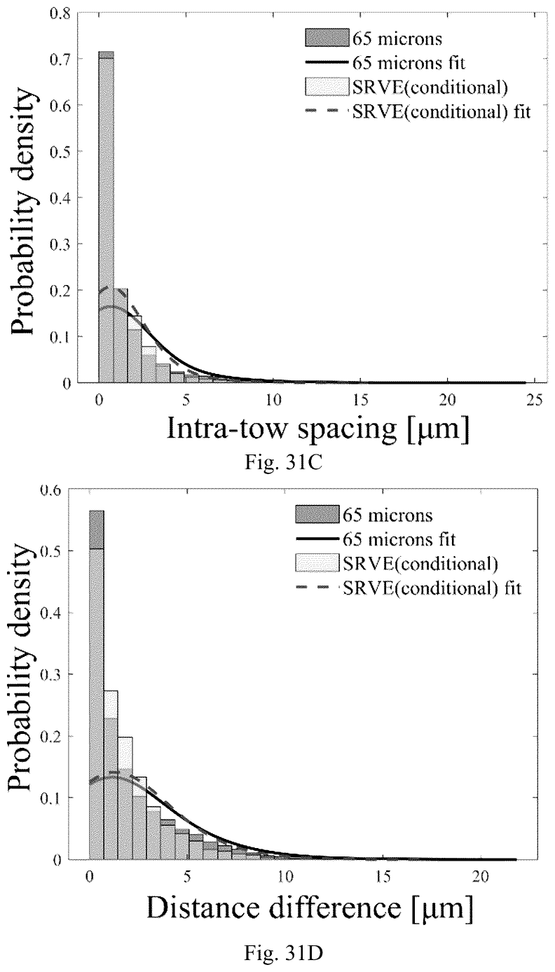

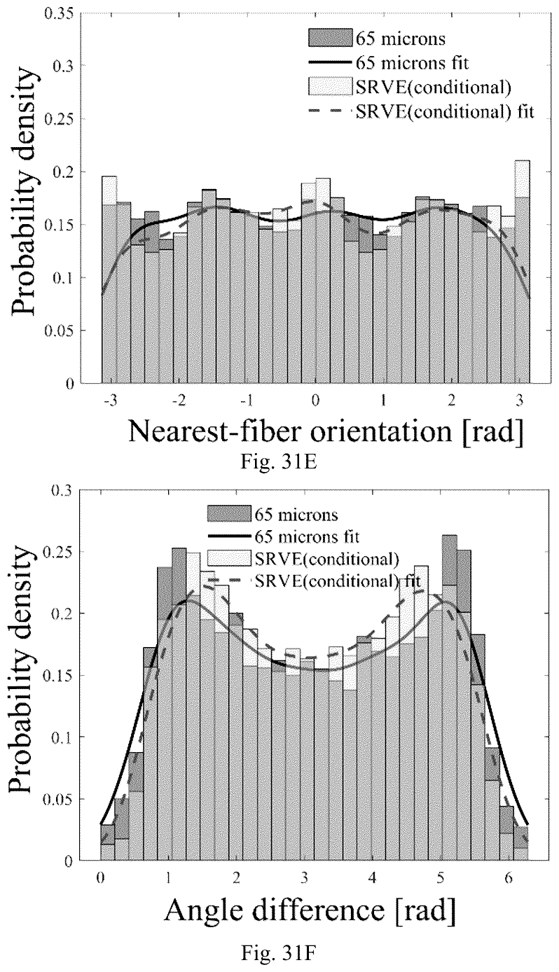

FIG. 31A through FIG. 31F are a set of plots showing probability density distributions of microstructural descriptors for exemplary 65 μm SEM segments and SRVEs generated by a conditional diffusion model: (FIG. 31A) fiber volume fraction, (FIG. 31B) porosity, (FIG. 31C) intra-tow spacing, (FIG. 31D) distance difference, (FIG. 31E) nearest-fiber orientation, and (FIG. 31F) angle difference.

The statistical agreement between the real and reconstructed microstructures was further assessed using microstructural descriptor-based comparisons, as shown in FIG. 31A through FIG. 31F. Overall, the probability density functions computed from the generated SRVEs closely follow those obtained from the original 65 μm SEM images, with deviations remaining within the natural variability observed across experimentally segmented regions extracted from the same field of view. The fiber volume fraction distributions shown in FIG. 31A exhibited a mildly left-skewed shape for both the SEM segments and the generated SRVEs, with mean values of 0.516 and 0.502, respectively. The probability density functions of porosity for both datasets peak near zero, with mean porosities of 0.67% for the SEM segments and 0.31% for the generated SRVEs, as shown in FIG. 31B. Manufacturing-induced porosity in the studied CFRP system was minimal, and learning this rare phase is inherently challenging for a deep generative model when only a limited number of training instances contain pores. Consequently, the diffusion model underestimated pore prevalence; however, given the small magnitude, this discrepancy was not expected to affect the homogenized mechanical properties of interest. Importantly, the proposed conditional model captured porosity more accurately than the unconditional diffusion baseline, reflecting the influence of porosity embedding. Because the model is explicitly conditioned on the target porosity level, sampling can be continued to generate additional SRVE instances, thereby enlarging the ensemble and, if desired, reducing the mean porosity difference relative to the SEM segments. For the current CFRP system, additional sampling was not required. However, this consideration applies to composite systems that exhibit significant manufacturing-induced defects, such as ceramic matrix composites, where the diffusion model may more accurately reproduce porosity distributions given that the training dataset includes a broader range of highly heterogeneous microstructures with varying defect percentages.

The intra-tow spacing and distance difference distributions shown in FIG. 31C and FIG. 31D also showed good agreement between the SEM segments and the generated SRVEs, indicating that the fiber clustering characteristics were preserved. The nearest-fiber orientation and angle-difference descriptors for the SRVEs shown in FIG. 31E and FIG. 31F exhibited distributions consistent with the SEM segments, indicating that the conditional embedding maintained the packing heterogeneity and local fiber orientation observed in the training data. Even though the angle difference descriptor was omitted from the diffusion model conditioning embeddings, it was preserved in the generated SRVEs through the combined influence of the remaining spatial descriptor embeddings and the ability of the model to learn microstructural features directly from the training data in the absence of explicit guidance. For the composite microstructures examined, the conditional embeddings demonstrated greater effectiveness in controlling fiber volume fraction and porosity than in regulating spatial statistics.

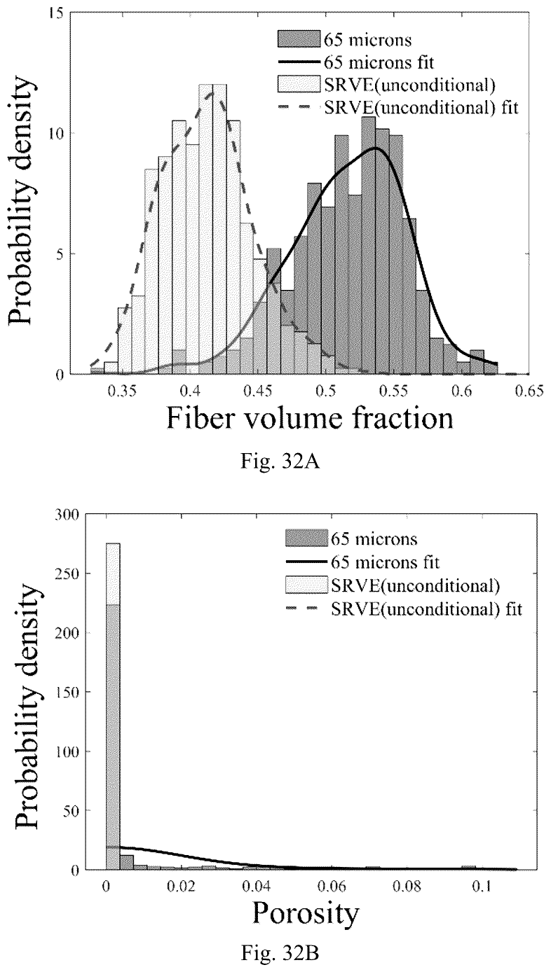

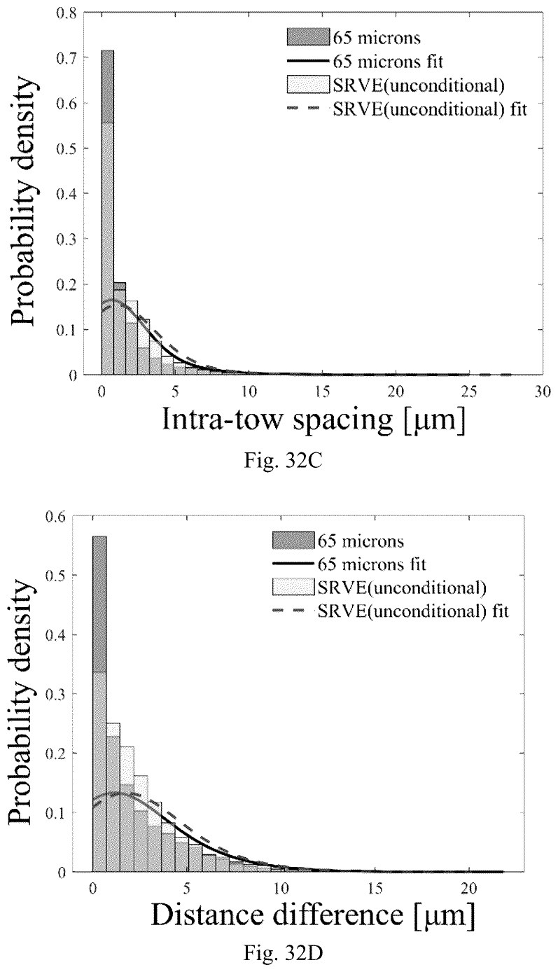

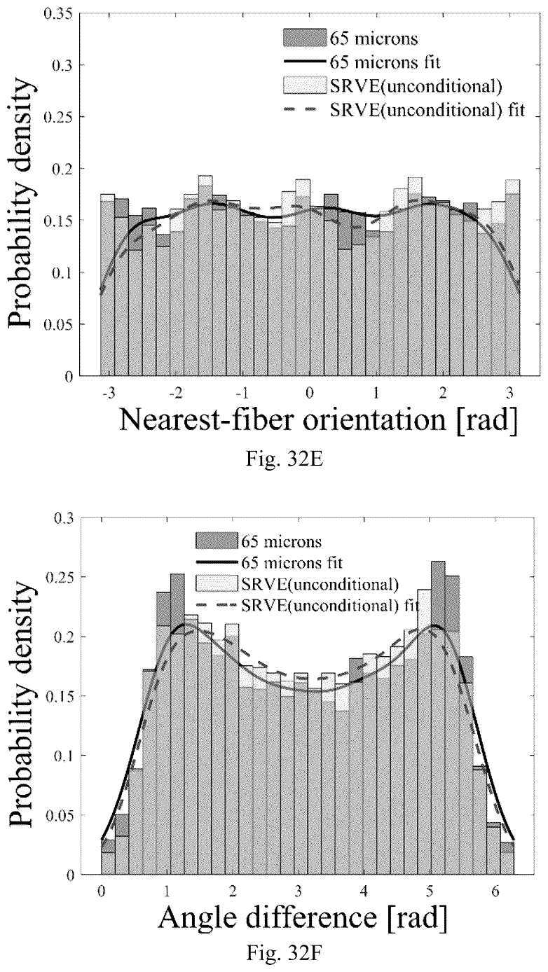

FIG. 32A through FIG. 32F are a set of plots showing probability density distributions of microstructural descriptors for exemplary 65 μm SEM segments and SRVEs generated by an unconditional diffusion model: (FIG. 32A) fiber volume fraction, (FIG. 32B) porosity, (FIG. 32C) intra-tow spacing, (FIG. 32D) distance difference, (FIG. 32E) nearest-fiber orientation, and (FIG. 32F) angle difference.

The performance of the conditional discrete diffusion model was assessed by evaluating the effect of microstructural descriptor embedding on SRVE fidelity, using a state-of-the-art unconditional diffusion model trained on the same SEM images as a baseline. FIG. 32A through FIG. 32F compare the probability density functions of the microstructural descriptors obtained from SEM segments and from the baseline SRVE ensemble. The results show that, without physical descriptor embedding, the unconditional model underestimated constituent volume fractions. The fiber volume fraction exhibited a systematic shift, with a mean value of 0.41, as shown in FIG. 32A. Moreover, pores were not reproduced in the unconditional SRVEs, as shown in FIG. 32B, and the generated microstructures consist exclusively of fiber and matrix phases. This indicated that sparse but physically relevant pore features were unlikely to emerge without explicit conditioning. It should be noted that accurate representation of pore morphology and spatial distribution, even at low volume fractions, remains critical due to its influence on damage initiation and multiscale damage propagation behavior.

On the other hand, omitting spatial descriptor embedding did not lead to a significant change in the spacing- and orientation-related probability density functions of the unconditional SRVEs shown in FIG. 32C through FIG. 32F relative to the SEM segments and the conditional SRVEs. This suggests that, for the investigated microstructures at the given image resolution, the unconditional model generally captures the fiber spatial distribution from the training data. However, this behavior was not guaranteed for all unidirectional composite microstructures and may depend on micrograph resolution. Consequently, embedding volumetric and spatial descriptors provided physics-informed constraints that enhance the robustness and modularity of the microstructure reconstruction framework.

Descriptor embedding constrained the diffusion process to a subset of the composite microstructural space consistent with the aleatoric variability observed in the SEM images. Without these descriptors, the diffusion model can still learn the morphology of the main constituents and generate visually plausible SRVEs; however, the statistical variability of the microstructure was not necessarily retained. Therefore, in this implementation, the descriptors can be viewed as physics-based constraints implicitly embedded in the generative process, analogous to physics-informed neural networks, that improve both SRVE fidelity and uncertainty quantification.

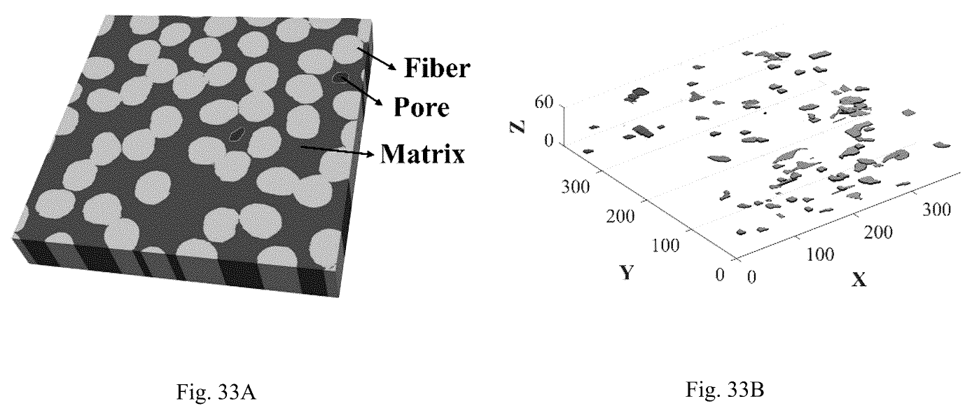

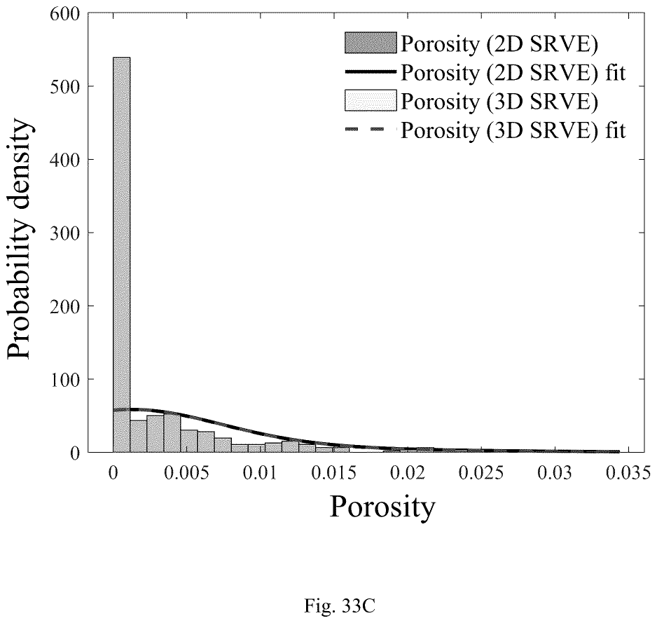

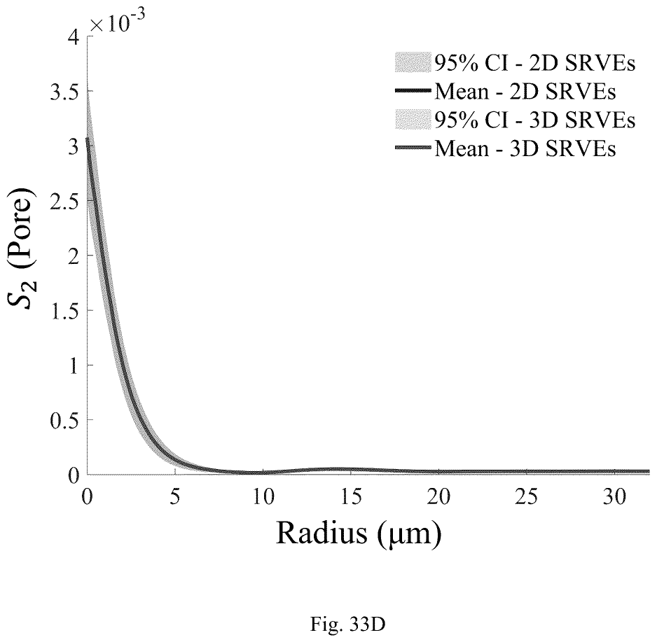

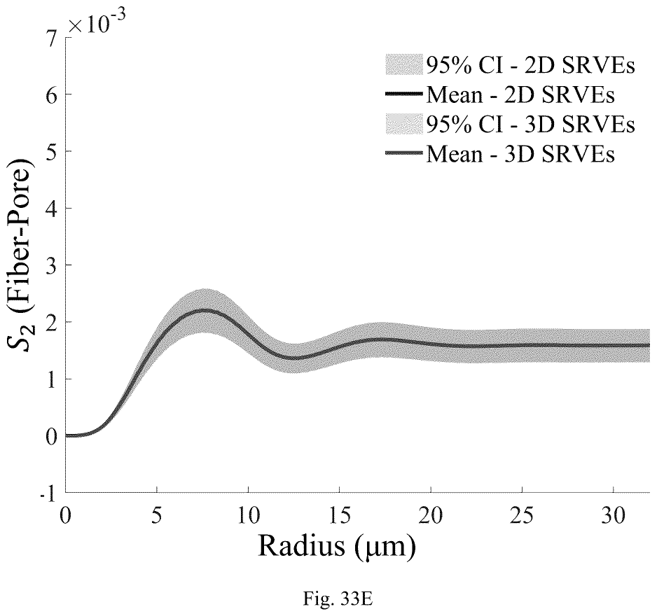

FIG. 33A through FIG. 33E are a set of images and plots showing three-dimensional extension and statistical validation of descriptor-aware SRVEs, including (FIG. 33A) an exemplary 3D SRVE showing fiber, matrix, and pore phases, (FIG. 33B) an isosurface visualization of the pore phase, (FIG. 33C) a comparison of porosity distributions between a 2D SRVE generated by the conditional diffusion model and the corresponding 3D SRVE, (FIG. 33D) pore autocorrelation, and (FIG. 33E) fiber-pore cross-correlation comparing 2D and 3D SRVEs with 95% confidence interval bands.

To enhance the versatility of 2D SRVEs generated by the conditional diffusion model, these representations were extended to three dimensions in order to account for the influence of manufacturing-induced defects on both through-thickness and in-plane homogenized properties. Although porosity was minimal in the studied composite, the microstructure reconstruction framework was intended to be modular and applicable to tow microstructures that may contain higher levels of manufacturing-induced porosity. The 3D extension assumed that the pore distribution was statistically similar in-plane and through-thickness. A pore-shape template was first constructed by extracting all pores from the generated 2D SRVEs. This template represented the set of pore geometries present in the tow microstructure, rather than assuming idealized circular or spherical pores. The extracted pores were assigned a small, variable thickness relative to the fiber size. Fibers were then extruded through the SRVE thickness, and pores were randomly inserted from the template into the 3D domain while avoiding overlap with fibers and previously placed pores. Pore insertion continued until the target porosity matched the overall porosity of the corresponding 2D SRVE. Two-point statistics were re-evaluated to confirm whether the pore autocorrelation and fiber-pore cross-correlation were affected by the 3D extension procedure. A representative 3D SRVE is shown in FIG. 33A, along with a 3D pore isosurface visualization and its probability density function shown in FIG. 33B and FIG. 33C, as well as the two-point statistics for pore and fiber-pore correlations shown in FIG. 33D and FIG. 33E. The 3D SRVEs reproduced the target porosity while preserving pore morphology and the fiber-pore relative distribution through the SRVE thickness, supporting the effectiveness of the 3D extension procedure.

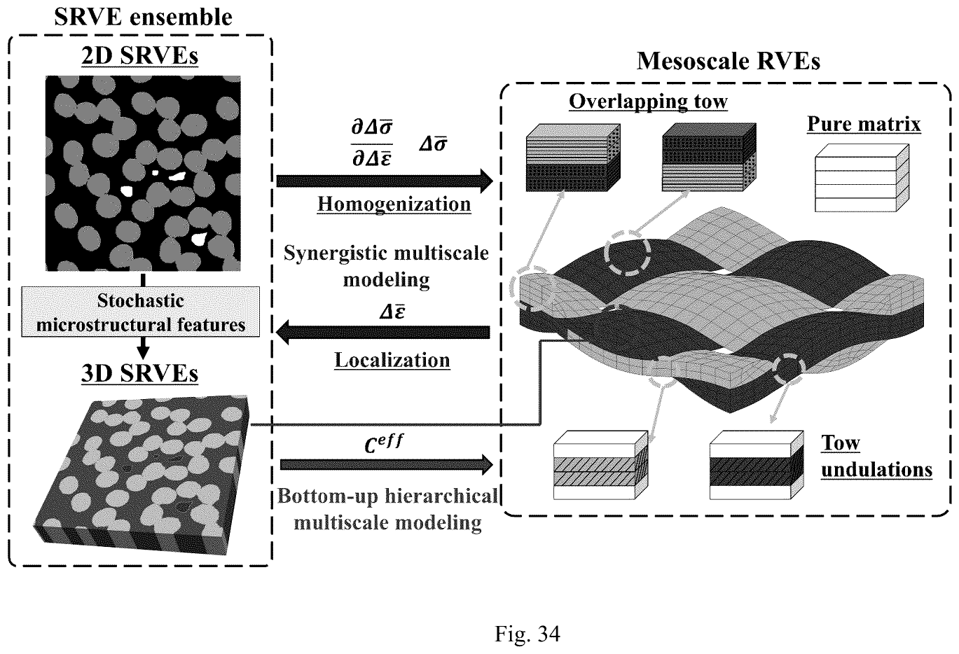

FIG. 34 is a schematic of an exemplary stochastic multiscale modeling framework illustrating propagation of microstructural variability to higher length scales using bottom-up hierarchical and synergistic approaches.

A major challenge in micromechanical analysis of multiphase composites is the accurate prediction of the spatial distribution of local fields, which requires a refined representation of microstructural geometry. Accordingly, refined micromechanical analyses are needed when detailed local fields are of interest, such as stress concentrations near voids and material imperfections. The generated SRVEs, including intrinsic variability and manufacturing-induced defects, are generally intended for high-fidelity micromechanical simulations to investigate constituent-level damage mechanisms and to support subsequent multiscale integration for propagating stochasticity across length scales. Multiscale methods are commonly classified as bottom-up hierarchical, synergistic, and concurrent approaches. In hierarchical methods, homogenization is the classical upscaling technique in which the constitutive model at a higher length scale is assumed and its parameters are computed from the microstructure. Synergistic methods rely on a two-way flow of information between length scales, where localization and homogenization are performed recursively at each load step until convergence, enabling transfer of damage- and inelasticity-related state-dependent variables initiated at the microscale to the mesoscale. In concurrent methods, length scales are directly coupled through handshake and interface coupling schemes. While concurrent approaches retain the highest fidelity, they can be computationally intractable for complex structural component analyses. In this example, the homogenized elastic properties of the generated SRVE ensemble were computed using HFGMC to obtain stochastic effective stiffnesses of fiber tows required for future mesoscale analyses. These homogenized properties can be directly integrated into a hierarchical multiscale framework while retaining variability in tow properties across different configurations and undulation patterns. The SRVE ensemble can also be used within synergistic multiscale methods to incorporate micro- and mesoscale nonlinearities. FIG. 34 provides a schematic illustrating how the SRVEs are used within multiscale methods for woven composites.

A deep learning-based MCR framework was developed for unidirectional CFRP tow microstructures using a novel conditional discrete diffusion model. Microstructural descriptors capturing constituent volume fractions and spatial distribution variability were extracted from segmented SEM micrographs, parameterized, and mapped through an MLP to produce compact conditional embeddings enforced through multi-head cross-attention blocks within a U-Net backbone. The uncertainty-aware descriptors accelerated training convergence and enabled generation of an SRVE ensemble that captures the inherent statistical variability of key microstructural features, as demonstrated by close agreement between the probability density functions of the generated SRVEs and the original SEM segments across all physical and spatial descriptors. In contrast, the unconditional diffusion baseline did not reliably reproduce subtle phases such as manufacturing-induced pores, particularly given their scarcity in the SEM dataset, highlighting the critical role of descriptor embedding in preserving physically relevant minority features. More broadly, the descriptors guided the diffusion process toward a subset of the microstructural space consistent with observed variability in fiber and pore morphology, constituent volume fractions, and fiber-related spatial statistics, with higher-order two-point autocorrelations and cross-correlations further validated across the generated SRVE ensemble, including after 3D extension. Geometric periodicity was imposed during diffusion model sampling through circular padding applied after each denoising step, enabling direct integration with the HFGMC micromechanics solver. The resulting stochastic effective composite properties computed from the SRVE ensemble can be propagated to the mesoscale weave level using bottom-up hierarchical multiscale modeling, as illustrated in FIG. 34.

### REFERENCE LIST

Borkowski L, Chattopadhyay A. Multiscale model of woven ceramic matrix composites considering manufacturing induced damage. Compos Struct 2015; 126:62-71. doi.org/10.1016/J.COMPSTRUCT.2015.02.015.
Skinner T, Chattopadhyay A. Multiscale temperature-dependent ceramic matrix composite damage model with thermal residual stresses and manufacturing-induced damage. Compos Struct 2021; 268:114006. doi.org/10.1016/J.COMPSTRUCT.2021.114006.
Liu K C, Chattopadhyay A, Bednarcyk B, Arnold S M. Efficient Multiscale Modeling Framework for Triaxially Braided Composites using Generalized Method of Cells. J Aerosp Eng 2011; 24:162-9. doi.org/10.1061/(asce)as.1943-5525.0000009.
Bostanabad R, Zhang Y, Li X, Kearney T, Brinson L C, Apley D W, et al. Computational microstructure characterization and reconstruction: Review of the state-of-the-art techniques. Prog Mater Sci 2018; 95:1-41. doi.org/10.1016/j.pmatsci.2018.01.005.
Fullwood D T, Niezgoda S R, Kalidindi S R. Microstructure reconstructions from 2-point statistics using phase-recovery algorithms. Acta Mater 2008; 56:942-8. doi.org/10.1016/j.actamat.2007.10.044.
Kench S, Cooper S J. Generating three-dimensional structures from a two-dimensional slice with generative adversarial network-based dimensionality expansion. Nat Mach Intell 2021; 3:299-305. doi.org/10.1038/s42256-021-00322-1.
Gommes C J, Jiao Y, Torquato S. Microstructural degeneracy associated with a two-point correlation function and its information content. Phys Rev E Stat Nonlin Soft Matter Phys 2012; 85. doi.org/10.1103/PhysRevE.85.051140.
Cang R, Li H, Yao H, Jiao Y, Ren Y. Improving direct physical properties prediction of heterogeneous materials from imaging data via convolutional neural network and a morphology-aware generative model. Comput Mater Sci 2018; 150:212-21. doi.org/10.1016/j.commatsci.2018.03.074.
Khafagy K H, Datta S, Chattopadhyay A. Multiscale characterization and representation of variability in ceramic matrix composites. J Compos Mater 2021; 55:2431-41. doi.org/10.1177/0021998320978445.
Badran A, Marshall D, Legault Z, Makovetsky R, Provencher B, Piche N, et al. Automated segmentation of computed tomography images of fiber-reinforced composites by deep learning. J Mater Sci 2020; 55:16273-89. doi.org/10.1007/s10853-020-05148-7.
Holm E A, Cohn R, Gao N, Kitahara A R, Matson T P, Lei B, et al. Overview: Computer Vision and Machine Learning for Microstructural Characterization and Analysis. Metall Mater Trans A Phys Metall Mater Sci 2020; 51:5985-99. doi.org/10.1007/s11661-020-06008-4.
Jung J, Na J, Park H K, Park J M, Kim G, Lee S, et al. Super-resolving material microstructure image via deep learning for microstructure characterization and mechanical behavior analysis. NPJ Comput Mater 2021; 7. doi.org/10.1038/s41524-021-00568-8.
Yang Z, Li X, Brinson L C, Choudhary A N, Chen W, Agrawal A. Microstructural materials design via deep adversarial learning methodology. Journal of Mechanical Design 2018; 140. doi.org/10.1115/1.4041371.
Hsu T, Epting W K, Kim H, Abernathy H W, Hackett G A, Rollett A D, et al. Microstructure Generation via Generative Adversarial Network for Heterogeneous, Topologically Complex 3D Materials. JOM 2021; 73:90-102. doi.org/10.1007/S11837-020-04484-Y.
Gratia P, Zimmermann I, Schouwink P, Yum J H, Audinot J N, Sivula K, et al. The Many Faces of Mixed Ion Perovskites: Unraveling and Understanding the Crystallization Process. ACS Energy Lett 2017; 2:2686-93. doi.org/10.1021/acsenergylett.7b00981.
Hsu T, Epting W K, Mahbub R, Nuhfer N T, Bhattacharya S, Lei Y, et al. Mesoscale characterization of local property distributions in heterogeneous electrodes. J Power Sources 2018; 386:1-9. doi.org/10.1016/J.JPOWSOUR.2018.03.025.
Gayon-Lombardo A, Mosser L, Brandon N P, Cooper S J. Pores for thought: generative adversarial networks for stochastic reconstruction of 3D multi-phase electrode microstructures with periodic boundaries. NPJ Comput Mater 2020; 6. doi.org/10.1038/s41524-020-0340-7.
Krizhevsky A, Sutskever I, Hinton G E. ImageNet Classification with Deep Convolutional Neural Networks. Adv Neural Inf Process Syst 2012; 25.
Ioffe S, Szegedy C. Batch Normalization: Accelerating Deep Network Training by Reducing Internal Covariate Shift. 32nd International Conference on Machine Learning, PMLR; 2015.
Chong P, Ruff L, Kloft M, Binder A. Simple and Effective Prevention of Mode Collapse in Deep One-Class Classification. Proceedings of the International Joint Conference on Neural Networks 2020. doi.org/10.1109/IJCNN48605.2020.9207209.
Dubey A K, Jain V. Comparative Study of Convolution Neural Network's Relu and Leaky-Relu Activation Functions. Applications of Computing, Automation and Wireless Systems in Electrical Engineering: Proceedings of MARC, vol. 553, Springer Verlag; 2019, p. 873-80. doi.org/10.1007/978-981-13-6772-4_76.
Borkowski L, Skinner T, Chattopadhyay A. Woven ceramic matrix composite surrogate model based on physics-informed recurrent neural network. Compos Struct 2023; 305. doi.org/10.1016/j.compstruct.2022.116455.
Kingma DiederikP, Ba J. Adam: A Method for Stochastic Optimization. ArXiv Preprint ArXiv:14126980 2014.
TensorFlow. API Documentation 2023. tensorflow.org/api_docs.
Salakhutdinov R, Hinton G. Deep Boltzmann Machines. Artificial intelligence and statistics, PMLR; 2009.
Pu Y, Gan Z, Henao R, Yuan X, Li C, Stevens A, et al. Variational Autoencoder for Deep Learning of Images, Labels and Captions. Adv Neural Inf Process Syst 2016; 29.
Goodfellow I J, Pouget-Abadie J, Mirza M, Xu B, Warde-Farley D, Ozair S, et al. Generative Adversarial Nets. Adv Neural Inf Process Syst 2014; 27.
Arjovsky M, Chintala S, Bottou L. Wasserstein Generative Adversarial Networks. International conference on machine learning, PMLR; 2017, p. 214-23.
Gulrajani I, Ahmed F, Arjovsky M, Dumoulin V, Courville A C. Improved Training of Wasserstein GANs. Adv Neural Inf Process Syst 2017; 30.
Li X, Yang Z, Brinson L C, Choudhary A, Agrawal A, Chen W. A deep adversarial learning methodology for designing microstructural material systems. International Design Engineering Technical Conferences and Computers and Information in Engineering Conference, American Society of Mechanical Engineers; 2018.
Bhatt R T, Kiser J D. Creep behavior and failure mechanisms of CVI and PIP SiC/SiC composites at temperatures to 1650° C. in air. J Eur Ceram Soc 2021; 41:6196-206. doi.org/10.1016/j.jeurceramsoc.2021.05.059.
Halbig M C, McGuffin-Cawley J D, Eckel A J, Brewer D N. Oxidation kinetics and stress effects for the oxidation of continuous carbon fibers within a microcracked C/SiC ceramic matrix composite. Journal of the American Ceramic Society 2008; 91:519-26. doi.org/10.1111/j.1551-2916.2007.02170.x.
Dang X, Zhao D, Fan X, Ma X, Chen X, Xue J, et al. In-plane thermal expansion behavior of M55J carbon fiber reinforced SiC matrix composite. J Eur Ceram Soc 2024; 44:119-29. doi.org/10.1016/J.JEURCERAMSOC.2023.08.044.
Parthasarathy T A, Cox B, Sudre O, Przybyla C, Cinibulk M K. Modeling environmentally induced property degradation of SiC/B N/SiC ceramic matrix composites. Journal of the American Ceramic Society 2018; 101:973-97. doi.org/10.1111/jace.15325.
Drugan W J, Willis J R. A micromechanics-based nonlocal constitutive equation and estimates of representative volume element size for elastic composites. J Mech Phys Solids 1996; 44:497-524. doi.org/10.1016/0022-5096(96)00007-5.
Heinrich C, Aldridge M, Wineman A S, Kieffer J, Waas A M, Shahwan K. The influence of the representative volume element (RVE) size on the homogenized response of cured fiber composites. Model Simul Mat Sci Eng 2012; 20:075007. doi.org/10.1088/0965-0393/20/7/075007.
Sanei S H R, Fertig R S. Uncorrelated volume element for stochastic modeling of microstructures based on local fiber volume fraction variation. Compos Sci Technol 2015; 117:191-8. doi.org/10.1016/j.compscitech.2015.06.010.
Goodfellow I, Pouget-Abadie J, Mirza M, Xu B, Warde-Farley D, Ozair S, et al. Generative adversarial networks. Commun ACM 2020; 63:139-44. doi.org/10.1145/3422622.
Salimans T, Goodfellow I, Zaremba W, Cheung V, Radford A, Chen X. Improved Techniques for Training GANs. Adv Neural Inf Process Syst 2016; 29.
Szegedy C, Vanhoucke V, Ioffe S. Rethinking the inception architecture for computer vision. Proceedings of the IEEE conference on computer vision and pattern recognition, 2016.
Deng J, Dong W, Socher R, Li L, Li K-, Fei-Fei L. Imagenet: A large-scale hierarchical image database. IEEE conference on computer vision and pattern recognition, IEEE; 2009, p. 248-55.
Aboudi J, Arnold S M, Bednarcyk B A. Micromechanics of Composite Materials: A Generalized Multiscale Analysis Approach 2013; 1:984.
Bansal Y, Pindera M-J. Testing the Predictive Capability of the High-Fidelity Generalized Method of Cells Using an Efficient Reformulation. 2004.
Balusu K, Skinner T, Chattopadhyay A. An efficient implementation of the high-fidelity generalized method of cells for complex microstructures. Comput Mater Sci 2021; 186. doi.org/10.1016/j.commatsci.2020.110004.
Aboudi J, Arnold S, Bednarcyk B. Practical micromechanics of composite materials. 2021.
Khafagy K H, Sorini C, Skinner T, Chattopadhyay A. Modeling creep behavior in ceramic matrix composites. Ceram Int 2021; 47:12651-60. doi.org/10.1016/j.ceramint.2021.01.125.
Hill R. A theory of the yielding and plastic flow of anisotropic metals. Proc R Soc Lond A Math Phys Sci 1948; 193:281-97. doi.org/10.1098/RSPA.1948.0045.
Shimizu N, Zhang W. A Study of Elastic Viscous Deformation. Proceedings American Soc for a Testing Materials 1921; 21:1162-71. doi.org/10.1299/JSMEC.42.825.
Daniel I, Ishai O, Daniel I, Daniel I. Engineering mechanics of composite materials. 2006.
Rugg K L, Tressler R E, Bakis C E, Lamon J. Creep of SiC—SiC microcomposites. J Eur Ceram Soc 1999; 19:2285-96. doi.org/10.1016/S0955-2219(99)00118-1.
Almansour A S, Morscher G N. Tensile creep behavior of SiCf/SiC ceramic matrix minicomposites. J Eur Ceram Soc 2020; 40:5132-46. doi.org/10.1016/j.jeurceramsoc.2020.07.012.
Bodet R, Bourrat X, Lamon J, Naslain R. Tensile creep behaviour of a silicon carbide-based fibre with a low oxygen content. J Mater Sci 1995; 30:661-77. doi.org/10.1007/BF00356326.
Sauder C, Lamon J. Tensile Creep Behavior of SiC-Based Fibers With a Low Oxygen Content. Journal of the American Ceramic Society 2007; 90:1146-56. doi.org/10.1111/J.1551-2916.2007.01535.X.
Lamon J. Review: creep of fibre-reinforced ceramic matrix composites. International Materials Reviews 2020; 65:28-62. doi.org/10.1080/09506608.2018.1564182.
Lara-Curzio E. Analysis of oxidation-assisted stress-rupture of continuous fiber-reinforced ceramic matrix composites at intermediate temperatures. Compos Part A Appl Sci Manuf 1999; 30:549-54. doi.org/10.1016/S1359-835X(98)00148-1.
Artz T. Modeling Lifetime Performance of Ceramic Matrix Composites with Reduced Order Homogenization Multiscale Methods 2022.
Khafagy K H, Chattopadhyay A. High-fidelity micromechanical modeling of the effects of defects on damage and creep behavior in single tow ceramic matrix composite. J Compos Mater 2023; 57:377-92. doi.org/10.1177/00219983221145915.
Ruggles-Wrenn M B, Sharma V. Effects of steam environment on fatigue behavior of two SiC/[SiC+Si 3N4] ceramic composites at 1300° C. Applied Composite Materials 2011; 18:385-96. doi.org/10.1007/s10443-010-9163-x.
Schichtel J J, Chattopadhyay A. Modeling the two-way coupling of stress, diffusion, and oxidation in heterogeneous CMC microstructures. J Eur Ceram Soc 2023; 43:261-72. doi.org/10.1016/j.jeurceramsoc.2022.09.046.
Lee, K. H., & Yun, G. J. (2024). Microstructure reconstruction using diffusion-based generative models. Mechanics of Advanced Materials and Structures, 31(18), 4443-4461.
Lyu, X., & Ren, X. (2024). Microstructure reconstruction of 2D/3D random materials via diffusion-based deep generative models. Scientific Reports, 14(1), 5041.
Lee, K. H., Lim, H. J., & Yun, G. J. (2024). A data-driven framework for designing microstructure of multifunctional composites with deep-learned diffusion-based generative models. Engineering Applications of Artificial Intelligence, 129, 107590.
Sohl-Dickstein, J., Weiss, E., Maheswaranathan, N., & Ganguli, S. (2015). Deep unsupervised learning using nonequilibrium thermodynamics. International Conference on Machine Learning, 2256-2265.
Ho, J., Jain, A., & Abbeel, P. (2020). Denoising diffusion probabilistic models. Advances in Neural Information Processing Systems, 33, 6840-6851.
Dhariwal, P., & Nichol, A. (2021). Diffusion models beat GANs on image synthesis. Advances in Neural Information Processing Systems, 34, 8780-8794.
Düreth, C., Seibert, P., Rücker, D., Handford, S., Kastner, M., & Gude, M. (2023). Conditional diffusion-based microstructure reconstruction. Materials Today Communications, 35, 105608.
Azqadan, E., Jahed, H., & Arami, A. (2023). Predictive microstructure image generation using denoising diffusion probabilistic models. Acta Materialia, 261, 119406.
Zhang, Y., Seibert, P., Otto, A., Raßloff, A., Ambati, M., & Kastner, M. (2024). DA-VEGAN: Differentiably Augmenting VAE-GAN for microstructure reconstruction from extremely small data sets. Computational Materials Science, 232, 112661.
Lyu, X., & Ren, X. (2025). Variational autoencoders guided conditional diffusion generative model for material microstructure reconstruction and inverse design. Materials Today Communications, 113087.
Hsu, T., Epting, W. K., Mahbub, R., Nuhfer, N. T., Bhattacharya, S., Lei, Y., et al. (2018). Mesoscale characterization of local property distributions in heterogeneous electrodes. Journal of Power Sources, 386, 1-9.
Wang, L., Chan, Y. C., Ahmed, F., Liu, Z., Zhu, P., & Chen, W. (2020). Deep generative modeling for mechanistic-based learning and design of metamaterial systems. Computer Methods in Applied Mechanics and Engineering, 372, 113377.
Prifling, B., Roding, M., Townsend, P., Neumann, M., & Schmidt, V. (2021). Large-scale statistical learning for mass transport prediction in porous materials using 90,000 artificially generated microstructures. Frontiers in Materials, 8, 786502.
Austin, J., Johnson, D. D., Ho, J., Tarlow, D., & Van Den Berg, R. (2021). Structured denoising diffusion models in discrete state-spaces. Advances in neural information processing systems, 34, 17981-17993.
Green, P. J., & Sibson, R. (1978). Computing Dirichlet tessellations in the plane. The Computer Journal, 21(2), 168-173.
Ripley, B. D. (1977). Modelling spatial patterns. Journal of the Royal Statistical Society: Series B (Methodological), 39(2), 172-192.
Xiao, X. (2010). Over-relaxation Lloyd method for computing centroidal Voronoi tessellations (Master's thesis). University of South Carolina. ProQuest Dissertations & Theses. (Publication No. 1475757)
Hamza, Mohamed H., and A. Chattopadhyay. “Multi deep learning-based stochastic microstructure reconstruction and high-fidelity micromechanics simulation of time-dependent ceramic matrix composite response.” Composite Structures 345 (2024): 118360.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

What is claimed is:

1. A micromechanics simulation method, comprising the steps of:
collecting one or more images of at least one composite material;
providing, to a first neural network, an input comprising the one or more images;
segmenting one or more microstructures in the one or more images;
quantifying one or more physical descriptors of one or more segmented microstructures;
passing an output comprising the one or more segmented microstructures and one or more quantified physical descriptors to a second neural network; and
generating one or more stochastic representative volume elements (SRVEs) based on the one or more segmented microstructures and one or more quantified physical descriptors with the second neural network.

2. The method of claim 1, further comprising the steps of:
providing, to the first neural network, an input comprising one or more generated SRVEs;
comparing the one or more generated SRVEs with the one or more quantified physical descriptors; and
predicting one or more physical descriptors for the one or more generated SRVEs.

3. The method of claim 1, further comprising the steps of:
characterizing one or more features of the one or more segmented microstructures with the first neural network;
passing an output comprising the one or more characterized features to the second neural network; and
generating the one or more SRVEs further based on the one or more characterized features.

4. The method of claim 3, wherein the one or more features of the segmented microstructures are selected from the group consisting of one or more phases, one or more distributions, and one or more defects.

5. The method of claim 1, further comprising the steps of:
outputting data comprising one or more generated SRVEs to a micromechanics simulation module; and
processing, with the micromechanics simulation module, the one or more generated SRVEs to compute at least one selected from the group consisting of composite homogenized elastic properties, longitudinal properties, transverse properties, in-plane properties, out-of-plane properties, local composite deformation, global composite deformation, time dependent responses, temperature dependent responses, time and temperature dependent responses, matrix and fiber damage, fiber/matrix interphase damage, creep response, and creep-fatigue response.

6. The method of claim 5, further comprising the step of:
before the processing step, applying one or more periodic boundary conditions (PBCs) to the one or more generated SRVEs.

7. The method of claim 1, wherein the at least one composite material comprises at least one of a CMC, a polymer matrix composite (PMC), a fiber-reinforced PMC, and a metal matrix composite (MMC).

8. The method of claim 1, wherein the first neural network comprises a regression neural network, and the second neural network comprises a generative adversarial network.

9. The method of claim 1, wherein the one or more images comprise at least one selected from the group consisting of a scanning electron microscope (SEM) image, a confocal microscope image, micro-X-ray computed tomography (micro-CT), and Energy-dispersive X-ray spectroscopy (EDS).

10. The method of claim 1, wherein the one or more physical descriptors comprise at least one selected from the group consisting of fiber radii, fiber packing, fiber volume fraction, porosity, and fiber/matrix interphase thickness.

11. The method of claim 1, further comprising the step of:
quantifying one or more spatial descriptors of one or more segmented microstructures, wherein the one or more spatial descriptors comprise at least one selected from the group consisting of intra-tow spacing, fiber nearest-neighbor orientation, distance difference, angle difference, two-point correlation and three-point correlation.

12. The method of claim 1, wherein the second neural network comprises a conditional discrete diffusion model configured to generate one or more SRVEs conditioned on a microstructural descriptor vector extracted from the one or more segmented microstructures.

13. The method of claim 12, wherein the microstructural descriptor vector comprises one or more physical descriptors comprising at least one of fiber volume fraction and porosity, and one or more spatial descriptors comprising at least one of intra-tow spacing, distance difference, nearest-fiber orientation, and angle difference, and wherein each spatial descriptor is parameterized by its mean, standard deviation, and quartiles to form a fixed-length conditioning vector.

14. The method of claim 12, wherein the conditional discrete diffusion model comprises a forward process defined by a categorical transition kernel that progressively replaces pixel-wise phase labels with uniformly random categories according to a time-dependent noising schedule, and a learned reverse process that iteratively restores the original categorical state toward a reconstructed segmentation conditioned on the microstructural descriptor vector.

15. The method of claim 12, wherein the conditional discrete diffusion model is implemented using a U-Net backbone comprising one or more down-sampling and up-sampling stages connected through residual blocks and skip connections, wherein timestep embeddings and microstructural descriptor embeddings are injected into the residual blocks and enforced through multi-head cross-attention blocks.

16. The method of claim 12, wherein the conditional discrete diffusion model is trained using an objective function combining a variational lower bound term and an auxiliary categorical cross-entropy term, wherein the cross-entropy term provides an enhanced supervision signal for minority phases such as pores, and wherein the descriptor vector is embedded as a conditioning signal that constrains the generative process toward physically admissible regions of microstructure space while preserving aleatoric variability.

17. The method of claim 1, further comprising the steps of:
extracting and parameterizing one or more microstructural descriptors from the one or more segmented microstructures using a statistical-based module; and
synthesizing one or more SRVEs directly from the extracted descriptors using descriptor-driven stochastic construction routines.

18. The method of claim 17, wherein the statistical-based module performs a Dirichlet tessellation of fiber center coordinates to characterize polygonal cell geometry and quantify the degree of quasi-hexagonal fiber packing, and wherein the resulting tessellation statistics are compared against a Poisson point process representing complete spatial randomness to identify clustering tendencies in the composite microstructure of the composite material.

19. The method of claim 17, wherein the statistical-based module generates one or more SRVEs using a periodic quasi-hexagonal generation algorithm and comprises the steps of:
generating and relaxing seed points via Lloyd's relaxation to achieve a target fraction of six-sided Voronoi cells;
sampling fiber center locations from the relaxed seed points;
applying microstructure-informed centroid perturbations derived from statistical analysis of the one or more images to reproduce experimentally observed fiber clustering; and
enforcing periodic boundary conditions by tracking fiber positions in angular coordinates such that fibers crossing SRVE boundaries are mapped to the opposite edge.

20. The method of claim 17, wherein the statistical-based module places matrix porosity within the generated SRVEs by sampling pore volume fractions from a mixture distribution and applying a distance-dependent placement probability that decays exponentially with increasing pore-to-fiber separation, thereby reproducing the spatial pore clustering near fiber surfaces observed in the one or more images.

21. A micromechanics simulation system comprising:
a computing device comprising one or more processors comprising at least one central processing unit (CPU) and one or more graphics processing units (GPUs) for parallel computing during neural network training and inference, and a non-transitory computer readable medium with instructions stored thereon, which when executed by the processor perform the steps of claim 1.
